(19) United States
(12) Patent Application Publication
(10) Pub. No.: US 2024/0206211 A1
(43) Pub. Date: Jun. 20, 2024

(54) ORGANIC LIGHT EMITTING DEVICE COMPRISING ORGANOMETALLIC COMPOUND AND PLURALITY OF HOST MATERIALS

(71) Applicant: LG Display Co., Ltd., Seoul (KR)

(72) Inventors: Inbum SONG, Seoul (KR); Dohan KIM, Goyang-si (KR); Sungjin PARK, Incheon (KR); Jaemin MOON, Seoul (KR); Seokwoo KANG, Hwaseong-si (KR); Byunggeol KIM, Goyang-si (KR)

(73) Assignee: LG Display Co., Ltd., Seoul (KR)

(21) Appl. No.: 18/513,228

(22) Filed: Nov. 17, 2023

(30) Foreign Application Priority Data
Nov. 25, 2022 (KR) 10-2022-0160623

(51) Int. Cl. H10K 50/12; H10K 50/15; H10K 50/16; H10K 50/17; H10K 85/30; H10K 85/60

(52) U.S. Cl. CPC H10K 50/12; H10K 50/15; H10K 50/16; H10K 50/171; H10K 85/342; H10K 85/633; H10K 85/6572

(57) ABSTRACT

An organic light-emitting device including: a first electrode; a second electrode facing the first electrode; and an organic layer disposed between the first electrode and the second electrode, the organic layer including a light-emissive layer that includes a dopant material including an organometallic compound represented by Chemical Formula 1; and a host material including a compound represented by Chemical Formula 2 and a compound represented by Chemical Formula 3.

### CROSS-REFERENCE TO RELATED APPLICATION

This application claims the benefit of and the priority to Korean Patent Application No. 10-2022-0160623, which is filed on Nov. 25, 2022 in the Korean Intellectual Property Office, and which is hereby incorporated by reference in its entirety.

### BACKGROUND

### 1. Technical Field

The present disclosure relates to an organic light-emitting device including an organometallic compound and a plurality of host materials.

### 2. Description of Related Art

Display devices are ubiquitous, and interest in such devices is increasing. One of the display devices is an organic light-emitting display device including an organic light-emitting diode (OLED) which is rapidly developing.

In the organic light-emitting diode, when electric charges are injected into a light-emissive layer formed or disposed between a positive electrode and a negative electrode, an electron and a hole may be recombined with each other in the light-emissive layer to form an exciton. The energy of the exciton may be converted to light that will be emitted by the organic light-emitting diode. Compared to conventional display devices, the organic light-emitting diode may operate at a lower voltage, consume relatively little power, render excellent colors, and may be used in a variety of ways when the organic light-emitting diode includes a flexible substrate. Further, a size of the organic light-emitting diode may be adjustable.

The organic light-emitting diode (OLED) may have superior viewing angle and contrast ratio compared to a liquid crystal display (LCD), and may be lightweight and ultra-thin because the OLED may not require a backlight. The organic light-emitting diode may include a plurality of organic layers between a negative electrode (electron injection electrode; cathode) and a positive electrode (hole injection electrode; anode). The plurality of organic layers may include a hole injection layer, a hole transport layer, a hole transport auxiliary layer, an electron blocking layer, and a light-emissive layer, an electron transport layer, etc.

In this organic light-emitting diode structure, when a voltage is applied across the two electrodes, electrons and holes are injected from the negative and positive electrodes, respectively, into the light-emissive layer. Excitons are generated in the light-emissive layer and then fall to a ground state to emit light.

Organic materials used in the organic light-emitting diode may be largely classified into light-emitting materials and charge-transporting materials. The light-emitting material may be an important factor determining luminous efficiency of the organic light-emitting diode. The luminescent material may have high quantum efficiency, excellent electron and hole mobility, and may exist uniformly and stably in the light-emissive layer. The light-emitting materials may be classified into light-emitting materials emitting blue, red, and green colors based on colors of the light. A color-generating material may include a host and dopants to increase the color purity and luminous efficiency through energy transfer.

When the fluorescent material is used, singlets, which make up about 25% of excitons generated in the light-emissive layer, are used to emit light, while most of triplets, which make up 75% of the excitons generated in the light-emissive layer, are dissipated as heat. However, when the phosphorescent material is used, both singlets and triplets may emit light.

Conventionally, an organometallic compound is used as the phosphorescent material used in the organic light-emitting diode. There is still a technical need to improve performance of an organic light-emitting diode by deriving high-efficiency phosphorescent dopant materials and applying a host material of optimal or desired photophysical properties to improve diode efficiency and lifetime, compared to a conventional organic light-emitting diode.

### SUMMARY

Accordingly, an object of the present disclosure is to provide an organic light-emitting diode in which an organic light-emissive layer contains an organometallic compound and a plurality of host materials capable of lowering operation voltage, and improving efficiency, and lifespan.

Objects of the present disclosure are not limited to the above-mentioned objects. Other objects and advantages of the present disclosure that are not mentioned may be understood based on following descriptions, and may be more clearly understood based on aspects of the present disclosure. Further, it will be easily understood that the objects and advantages of the present disclosure may be realized using means shown in the claims and combinations thereof.

To achieve these and other advantages and in accordance with objects of the disclosure, as embodied and broadly described herein, an organic light-emitting device may include: a first electrode; a second electrode facing the first electrode; and an organic layer disposed between the first electrode and the second electrode, the organic layer including a light-emissive layer that includes: a dopant material including an organometallic compound represented by Chemical Formula 1; and a host material including a compound represented by Chemical Formula 2 and a compound represented by Chemical Formula 3:

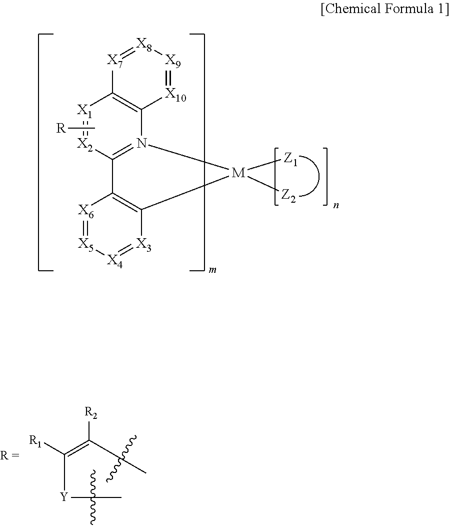

wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
in R, each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C3-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO, and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ may be optionally fused with each other to form a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,

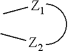

represents a bidentate ligand,
m is an integer of 1, 2 or 3, n is an integer of 0, 1 or 2, and m+n is an oxidation number of the metal (M),

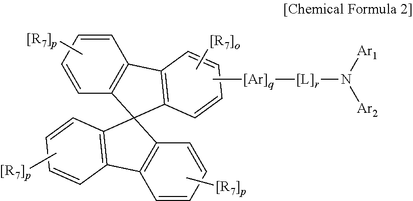

wherein in the Chemical Formula 2,
Ar independently represents a substituted or unsubstituted aromatic ring group selected from the group consisting of benzene, naphthalene, phenanthrene, fluorene, spirobifluorene, dibenzofuran and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, a linker L represents one selected from the group consisting of a substituted or unsubstituted C6-C30 arylene group, a substituted or unsubstituted C3-C30 heteroarylene group, and a substituted or unsubstituted C7-C20 arylalkylene group,

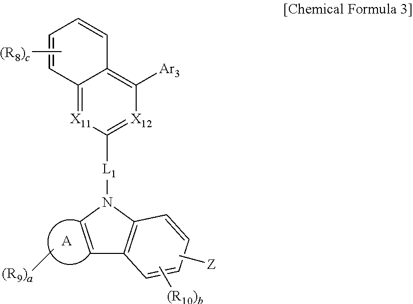

wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ may be optionally substituted with at least one of deuterium and a halogen atom,
Z represents one selected from the group consisting of the following structures:

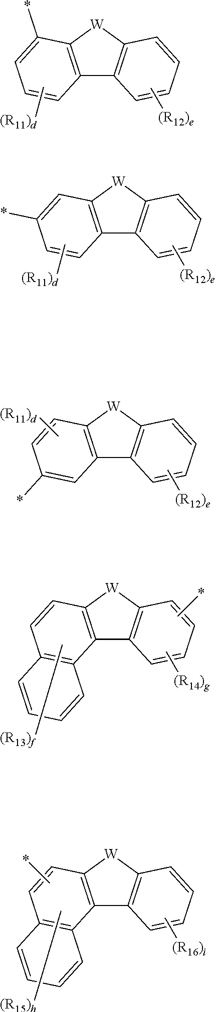

W represents one selected from the group consisting of O, S, NR₁₇, CR₁₇R₁₈ and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

According to another aspect of the present disclosure, an organic light-emitting device may include: a first electrode; a second electrode facing the first electrode; a first light-emitting stack; and a second light-emitting stack, wherein the first and second light-emitting stacks are disposed between the first electrode and the second electrode, wherein each of the first light-emitting stack and the second light-emitting stack includes at least one light-emissive layer including a red phosphorescent light-emissive layer that includes: a dopant material including an organometallic compound represented by Chemical Formula 1; and a host material including a compound represented by Chemical Formula 2 and a compound represented by Chemical Formula 3:

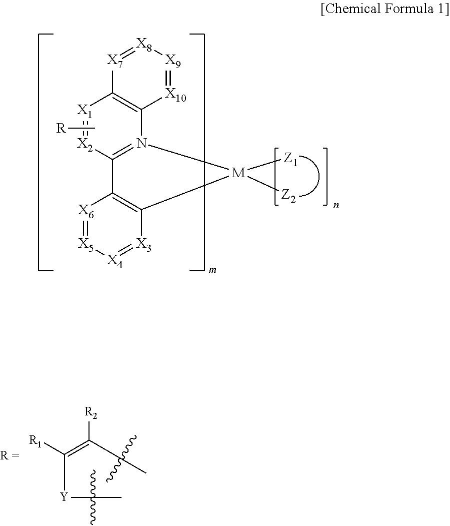

wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
in R, each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C5-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO, and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ are optionally fused with each other to form a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,

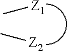

represents a bidentate ligand,
m is an integer of 1, 2 or 3, n is an integer of 0, 1 or 2, and m+n is an oxidation number of the metal (M),

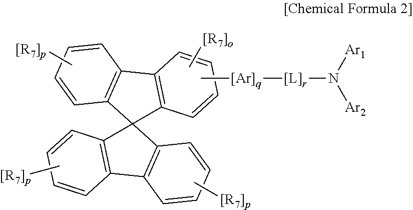

wherein in the Chemical Formula 2,
Ar independently represents a substituted or unsubstituted aromatic ring group selected from the group consisting of benzene, naphthalene, phenanthrene, fluorene, spirobifluorene, dibenzofuran, and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, a linker L represents one selected from the group consisting of a substituted or unsubstituted C6-C30 arylene group, a substituted or unsubstituted C3-C30 heteroarylene group, and a substituted or unsubstituted C7-C20 arylalkylene group,

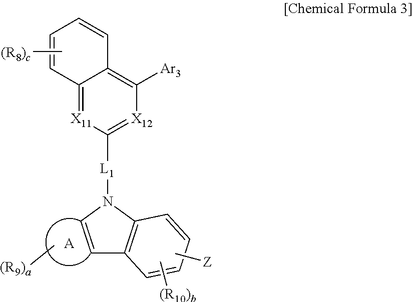

wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ is optionally substituted with at least one of deuterium and a halogen atom,
Z represents one selected from the group consisting of the following structures:

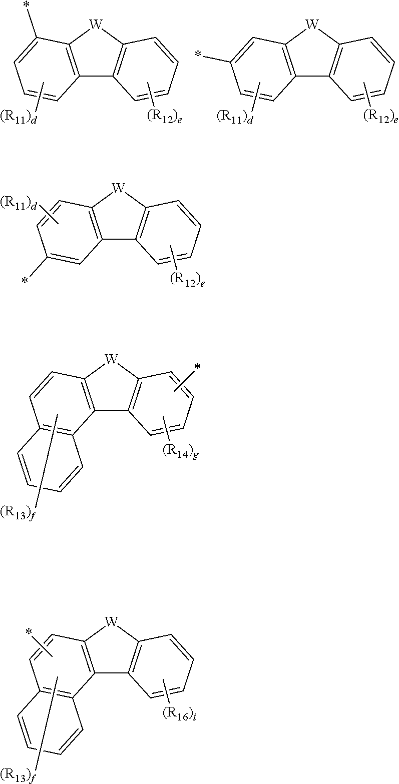

W represents one selected from the group consisting of O, S, NR₁₇, CR₁₇R₁₈ and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

According to another aspect of the present disclosure, an organic light-emitting device may include: a first electrode; a second electrode facing the first electrode; a first light-emitting stack; a second light-emitting stack; and a third light-emitting stack, wherein the first, second, and third light-emitting stacks are disposed between the first electrode and the second electrode, wherein each of the first light-emitting stack, the second light-emitting stack, and the third light-emitting stack includes at least one red phosphorescent light-emissive layer that includes: a dopant material including an organometallic compound represented by Chemical Formula 1; and a host material including a compound represented by Chemical Formula 2 and a compound represented by Chemical Formula 3:

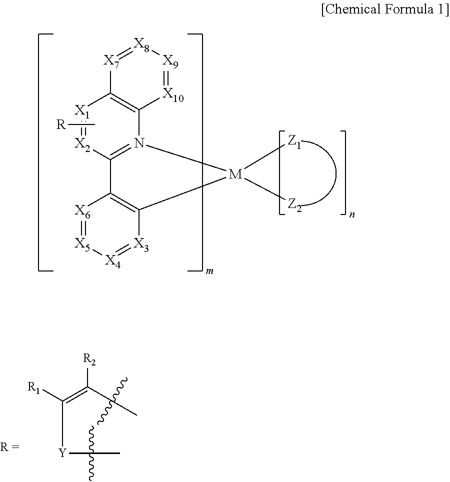

wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C3-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO, and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ optionally fused with each other to form a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,

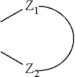

represents a bidentate ligand,
m is an integer of 1, 2 or 3, n is an integer of 0, 1 or 2, and m+n is an oxidation number of the metal (M),

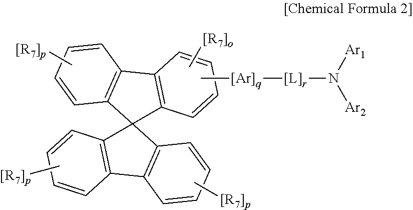

wherein in the Chemical Formula 2,
Ar independently represents a substituted or unsubstituted aromatic ring group selected from the group consisting of benzene, naphthalene, phenanthrene, fluorene, spirobifluorene, dibenzofuran, and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, a linker L represents one selected from the group consisting of a substituted or unsubstituted C6-C30 arylene group, a substituted or unsubstituted C3-C30 heteroarylene group, and a substituted or unsubstituted C7-C20 arylalkylene group,

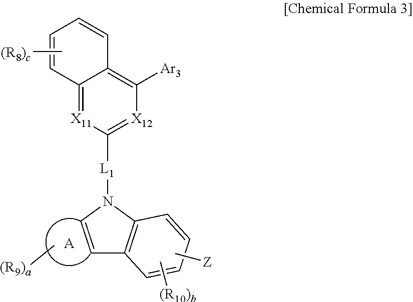

wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ is optionally substituted with at least one of deuterium and a halogen atom,
Z represents one selected from the group consisting of following structures:

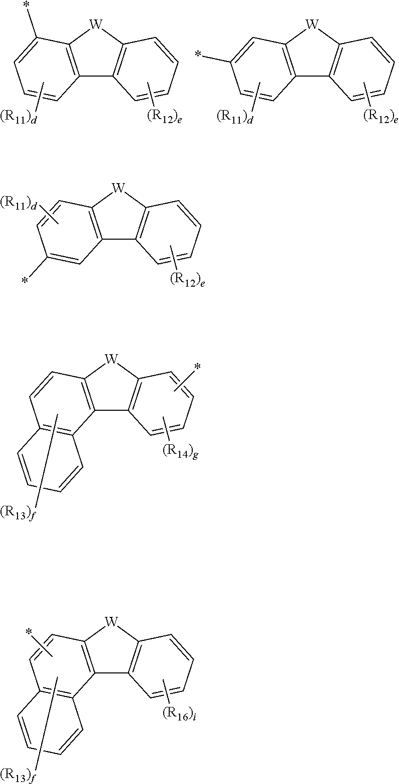

W represents one selected from the group consisting of O, S, NR₁₇, CR₁₇R₁₈ and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

In the organic light-emitting device according to the present disclosure, the organometallic compound represented by the Chemical Formula 1 may be used as a phosphorescent dopant, and the compound represented by the Chemical Formula 2 and the compound represented by the Chemical Formula 3 are mixed with each other to produce a mixture which may be used as a phosphorescent host. Thus, the operation voltage of the organic light-emitting device may be lowered and the efficiency, and lifetime characteristics thereof may be improved.

Effects of the present disclosure are not limited to the above-mentioned effects, and other effects as not mentioned will be clearly understood by those skilled in the art from following descriptions.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a schematic cross-sectional view illustrating an organic light-emitting diode according to an example embodiment of the present disclosure.

FIG. 2 is a schematic cross-sectional view illustrating an organic light-emitting diode having a tandem structure including two light-emitting stacks according to an example embodiment of the present disclosure.

FIG. 3 is a cross-sectional view schematically illustrating an organic light-emitting diode having a tandem structure having three light-emitting stacks according to an example embodiment of the present disclosure.

FIG. 4 is a cross-sectional view schematically illustrating an organic light-emitting display device including an organic light-emitting diode according to an example embodiment of the present disclosure.

### DETAILED DESCRIPTION

Reference will now be made in detail to some of the examples and embodiments of the disclosure illustrated in the accompanying drawings. Wherever possible, the same reference numbers will be used throughout the drawings to refer to the same or like parts.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and may be embodied in various different forms. Thus, these example embodiments are set forth only to make the present disclosure sufficiently complete, and to assist those skilled in the art to fully understand the scope of the present disclosure. The protected scope of the present disclosure is defined by claims and their equivalents.

For convenience of description, a scale in which each of elements is illustrated in the accompanying drawings may differ from an actual scale. Thus, the illustrated elements are not limited to the specific scale in which they are illustrated in the drawings. The same reference numbers in different drawings represent the same or similar elements, which may perform similar functionality. Further, where the detailed description of the relevant known steps and elements may obscure an important point of the present disclosure, a detailed description of such known steps and elements may be omitted. Furthermore, in the following detailed description of the present disclosure, numerous specific details are set forth in order to provide a sufficiently thorough understanding of the present disclosure. However, it will be understood that the present disclosure may be practiced without these specific details. In other instances, known methods, procedures, components, and circuits have not been described in detail so as not to unnecessarily obscure aspects of the present disclosure.

Although example embodiments of the present disclosure are described in detail with reference to the accompanying drawings, the present disclosure is not limited thereto and may be embodied in many different forms without departing from the technical concept of the present disclosure. Therefore, example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The same or similar elements are designated by the same reference numerals throughout the specification unless otherwise specified.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In the present specification, where the terms “comprise,” “have,” “include,” and the like are used, one or more other elements may be added unless the term, such as “only,” is used. As used herein, the term “and/or” includes a single associated listed item and any and all of the combinations of two or more of the associated listed items. An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

In construing an element or numerical value, the element or the numerical value is to be construed as including an error or tolerance range even where no explicit description of such an error or tolerance range is provided.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present. In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used.

Further, as used herein, when a layer, film, region, plate, or the like may be disposed “on” or “on a top” of another layer, film, region, plate, or the like, the former may directly contact the latter or another layer, film, region, plate, or the like may be disposed between the former and the latter. As used herein, when a layer, film, region, plate, or the like is directly disposed “on” or “on a top” of another layer, film, region, plate, or the like, the former directly contacts the latter and another layer, film, region, plate, or the like is not disposed between the former and the latter. Further, as used herein, when a layer, film, region, plate, or the like may be disposed “below” or “under” another layer, film, region, plate, or the like, the former may directly contact the latter or another layer, film, region, plate, or the like may be disposed between the former and the latter. As used herein, when a layer, film, region, plate, or the like is directly disposed “below” or “under” another layer, film, region, plate, or the like, the former directly contacts the latter and another layer, film, region, plate, or the like is not disposed between the former and the latter.

In descriptions of temporal relationships, for example, temporal precedent relationships between two events such as “after”, “subsequent to”, “before”, “next,” etc., another event may occur therebetween unless a more limiting term, “just,” “immediate(ly),” or “direct(ly)” (“directly after”, “directly subsequent”, “directly before”) is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or overall combined with each other, and may be variously inter-operated with each other and driven technically as those skilled in the art can sufficiently understand. The embodiments may be implemented independently of each other and may be implemented together in an co-dependent relationship.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

The terms used in the description below may be general and universal in the relevant art. However, there may be other terms depending on the development and/or change of technology, convention, preference of technicians, etc. Therefore, the terms used in the description below should not be understood as limiting the disclosure, and should be understood as examples of the terms for describing embodiments.

Further, in some example embodiments, a term may be arbitrarily selected by the applicant, and in this case, the detailed meaning thereof will be described in a corresponding description section. Therefore, such terms used in the description below may be understood based on the name of the terms, and the meaning of the terms and the contents throughout the Detailed Description.

As used herein, the term “halo” or “halogen” includes fluorine, chlorine, bromine, and iodine.

The present disclosure may include example embodiments in which some or all hydrogens of each of the organometallic compound represented by the Chemical Formula 1, the compound represented by the Chemical Formula 2, and the compound represented by the Chemical Formula 3 are substituted with deuterium.

As used herein, the term “alkyl group” refers to both linear alkyl radicals and branched alkyl radicals. Unless otherwise specified, the alkyl group contains 1 to 20 carbon atoms, and includes methyl, ethyl, propyl, isopropyl, butyl, isobutyl, tert-butyl, etc. Further, the alkyl group may be optionally substituted.

As used herein, the term “cycloalkyl group” refers to a cyclic alkyl radical. Unless otherwise specified, the cycloalkyl group contains 3 to 20 carbon atoms, and includes cyclopropyl, cyclopentyl, cyclohexyl, and the like. Further, the cycloalkyl group may be optionally substituted.

As used herein, the term “alkenyl group” refers to both linear alkene radicals and branched alkene radicals. Unless otherwise specified, the alkenyl group contains 2 to 20 carbon atoms. Additionally, the alkenyl group may be optionally substituted.

As used herein, the term “alkynyl group” refers to both linear alkyne radicals and branched alkyne radicals. Unless otherwise specified, the alkynyl group contains 2 to 20 carbon atoms. Additionally, the alkynyl group may be optionally substituted.

The terms “aralkyl group” and “arylalkyl group” as used herein are used interchangeably with each other and refer to an alkyl group having an aromatic group as a substituent. Further, the alkylaryl group may be optionally substituted.

The terms “aryl group” and “aromatic group” as used herein are used in the same meaning. The aryl group includes both a monocyclic group and a polycyclic group. The polycyclic group may include a fused ring in which two or more rings are fused with each other such that two carbons are common to two adjacent rings. Unless otherwise specified, the aryl group contains 6 to 60 carbon atoms. Further, the aryl group may be optionally substituted.

The term “heterocyclic group” as used herein means that at least one of carbon atoms constituting an aryl group, a cycloalkyl group, or an aralkyl group (arylalkyl group) is substituted with a heteroatom such as oxygen (O), nitrogen (N), sulfur (S), etc. Further, the heterocyclic group may be optionally substituted.

The term “carbon ring” as used herein may be used as a term including both “cycloalkyl group” as an alicyclic group and “aryl group” an aromatic group unless otherwise specified.

The terms “heteroalkyl group” and “heteroalkenyl group” as used herein mean that at least one of carbon atoms constituting the group is substituted with a heteroatom such as oxygen (O), nitrogen (N), or sulfur (S). In addition, the heteroalkyl group and the heteroalkenyl group may be optionally substituted.

As used herein, the term “substituted” means that a substituent other than hydrogen (H) binds to corresponding carbon. The substituent for the term “substituted”, unless defined otherwise, may include one selected from the group consisting of, for example, deuterium, tritium, a C1-C20 alkyl group unsubstituted or substituted with halogen, a C1-C20 alkoxy group unsubstituted or substituted with halogen, halogen, a carboxy group, an amine group, a C1-C20 alkylamine group, a nitro group, a C1-C20 alkylsilyl group, a C1-C20 alkoxysilyl group, a C3-C30 cycloalkylsilyl group, a C6-C30 arylsilyl group, a C6-C30 aryl group, a C6-C30 arylamine group, a C3-C30 heteroaryl group and a combination thereof. However, the present disclosure is not limited thereto.

Subjects and substituents as defined in the present disclosure may be the same as or different from each other unless otherwise specified.

Hereinafter, example embodiments of the present disclosure will be described in detail with reference to the accompanying drawings. In adding reference numerals to elements of each of the drawings, although the same elements are illustrated in other drawings, like reference numerals may refer to like elements.

Hereinafter, example embodiments of an organometallic compound according to the present disclosure and of an organic light-emitting diode including the same will be described in detail.

Conventionally, an organometallic compound has been used as a dopant of a phosphorescent light-emissive layer. For example, the main ligand(s) structure in the organometallic compound may have a skeletal structure based on, for example, 2-phenylpyridine. However, such a conventional light-emitting dopant has limitations in improving the efficiency and lifetime of the organic light-emitting diode. The present disclosure has been completed by experimentally confirming that when a mixture of a hole transport type host and an electron transport type host as host materials is used together with a dopant material as disclosed herein, the efficiency and lifetime of the organic light-emitting diode may be improved, and an operation voltage thereof may be lowered, thereby improving the characteristics of the organic light-emitting diode.

FIG. 1 is a schematic cross-sectional view illustrating an organic light-emitting diode according to an example embodiment of the present disclosure.

Specifically, referring to FIG. 1 according to an example embodiment of the present disclosure, an organic light-emitting diode 100 including a first electrode 10; a second electrode 120 facing the first electrode 110; and an organic layer 130 disposed between the first electrode 110 and the second electrode 120 may be provided. The organic layer 130 may include a light-emitting layer 160. The light-emitting layer 160 may include a dopant material 160′ and host materials 160″ and 160′″. The dopant material may include an organometallic compound 160′ represented by the following Chemical Formula 1. The host material may include a mixture of two types of host materials: a compound 160″ represented by the following Chemical Formula 2 as the hole transporting host material and a compound 160′″ represented by the following Chemical Formula 3 as the electron transporting host material:

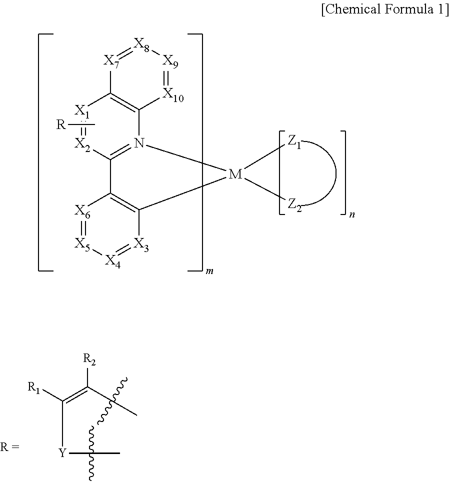

wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C3-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ may be fused with each other to form a ring, wherein the ring may be a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,

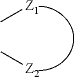

represents a bidentate ligand,
m is an integer of 1, 2 or 3, n is an integer of 0, 1 or 2, and m+n is an oxidation number of the metal (M),

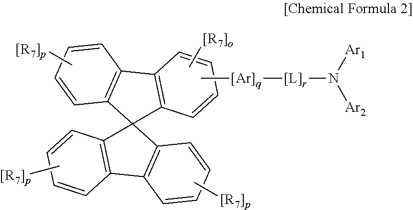

wherein in the Chemical Formula 2,
Ar independently represents a substituted or unsubstituted aromatic ring group selected from the group consisting of benzene, naphthalene, phenanthrene, fluorene, spirobifluorene, dibenzofuran and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, a linker L represents one selected from the group consisting of a substituted or unsubstituted C6-C30 arylene group, a substituted or unsubstituted C3-C30 heteroarylene group, and a substituted or unsubstituted C7-C20 arylalkylene group,

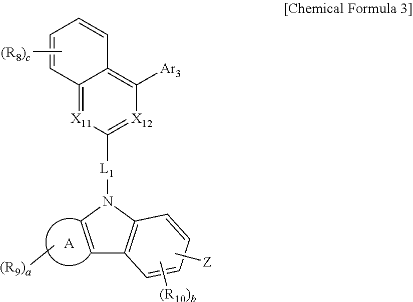

wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ may be substituted with at least one of deuterium and a halogen atom,
Z represents one selected from the group consisting of following structures:

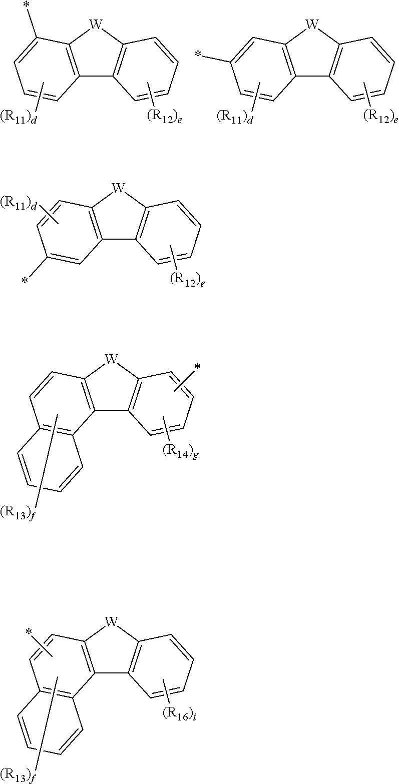

W represents one selected from the group consisting of O, S, NR₁₇, CR₁₇R₁₈ and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

According to an example embodiment of the present disclosure, the organometallic compound represented by the above Chemical Formula 1 may have a heteroleptic or homoleptic structure. For example, the organometallic compound represented by the above Chemical Formula 1 may have a homoleptic structure where n in the Chemical Formula 1 is 0, a heteroleptic structure in which n in the Chemical Formula 1 is 1, or a heteroleptic structure where n in the Chemical Formula 1 is 2. In an example embodiment, n in the Chemical Formula 1 may be 2.

According to an example embodiment of the present disclosure, Y in the Chemical Formula 1 may represent one selected from the group consisting of O, S and CR₃R₄.

According to an example embodiment of the present disclosure, each of R₁ and R₂ in the Chemical formula 1 may be optionally substituted with deuterium and/or halogen.

According to an example embodiment of the present disclosure, each of R₅ and R₆ in the Chemical formula 1 may be optionally substituted with deuterium and/or halogen.

According to an example embodiment of the present disclosure, each of R₈ to R₁₈ and R′ in the Chemical formula 3 may be optionally substituted with one or more of deuterium and/or halogen.

According to an example embodiment of the present disclosure, the organometallic compound represented by the Chemical Formula 1 is one selected from the group consisting of following compound RD-1 to compound RD-20:

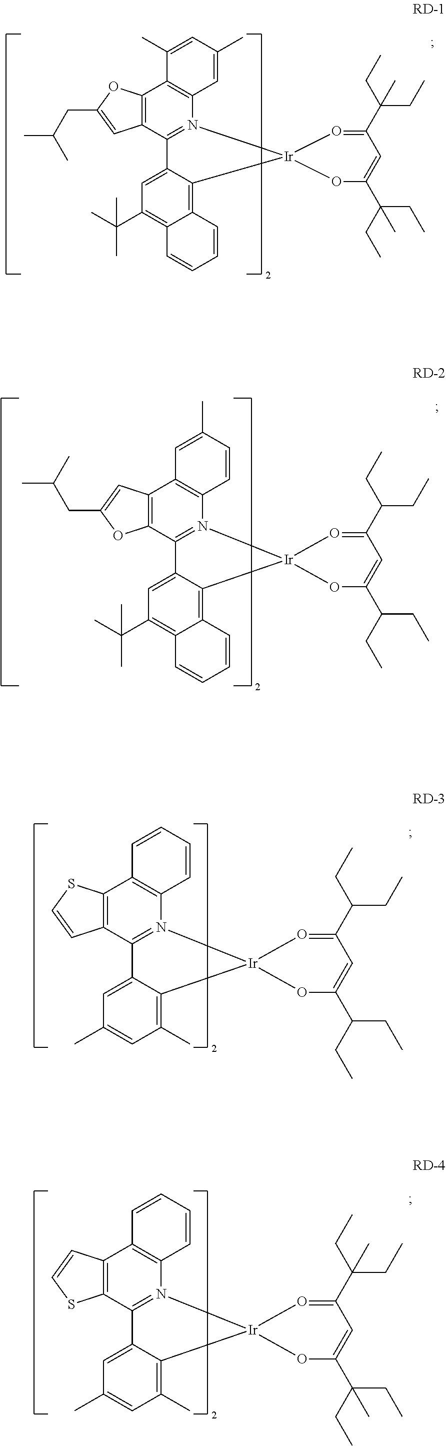

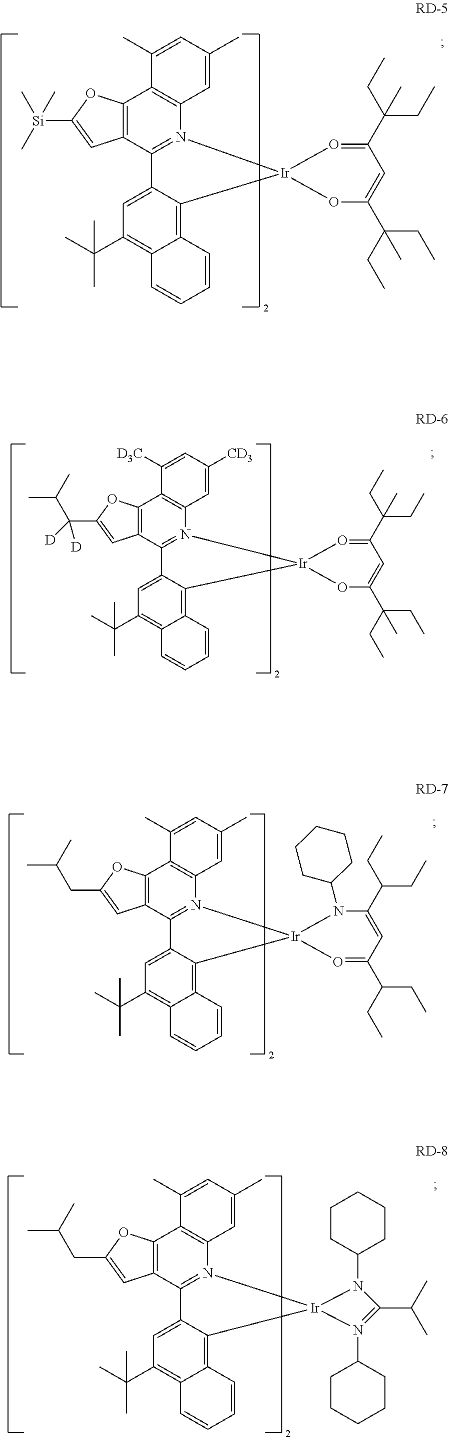

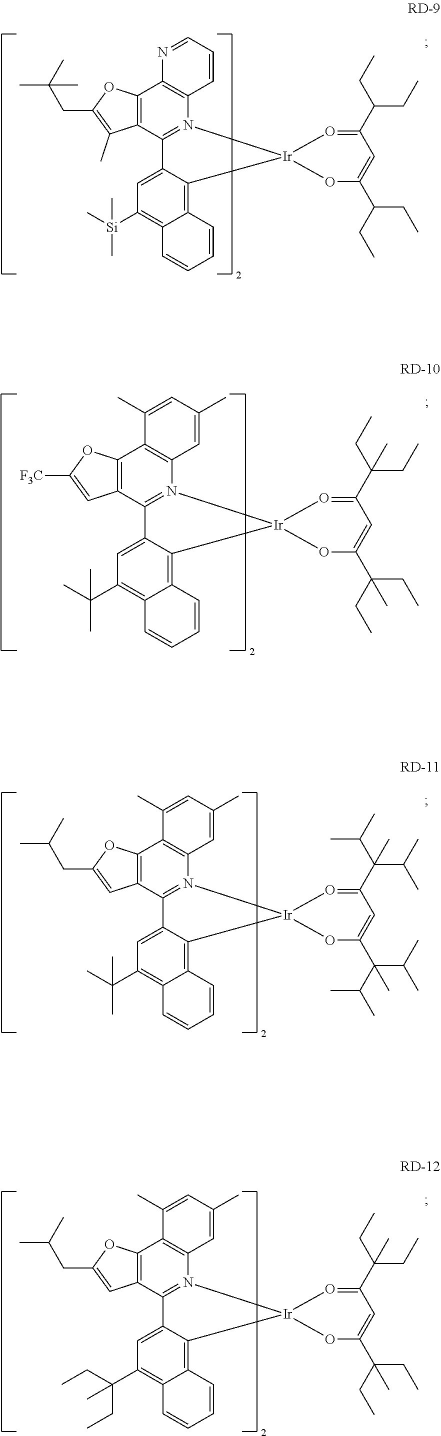

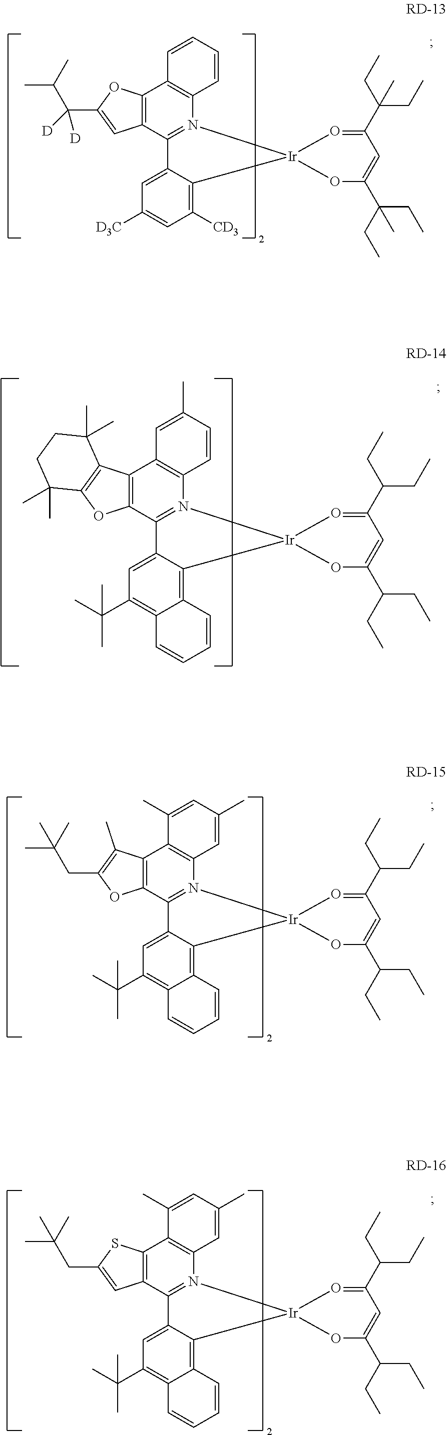

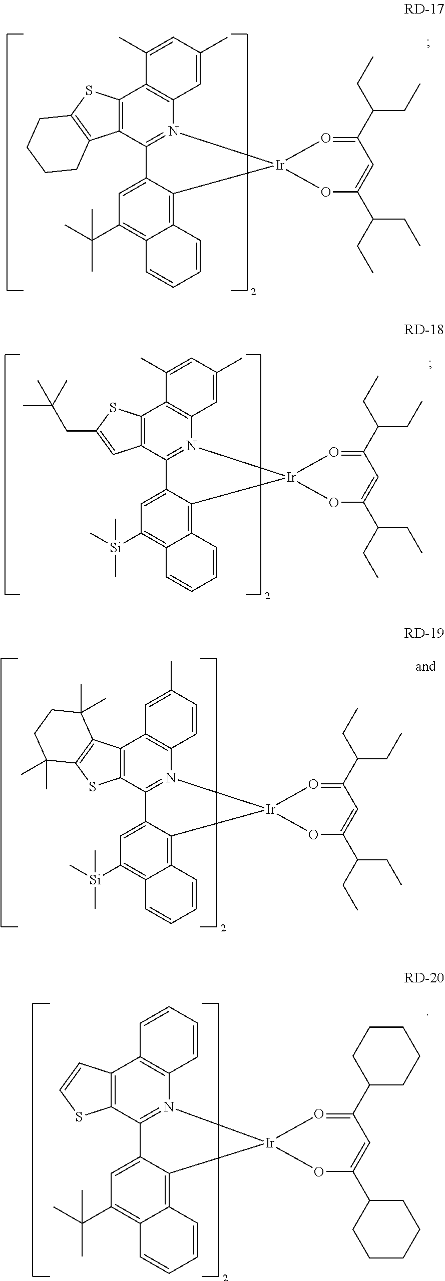

According to an example embodiment of the present disclosure, in the Chemical Formula 2, each of Ar₁ and Ar₂ may independently represent one selected from the group consisting of benzene, naphthalene, phenanthrene, fluorene, dibenzofuran, dibenzothiophene, and spirobifluorene, wherein at least one hydrogen of each of Ar₁ and Ar₂ may be substituted with one or more selected from the group consisting of deuterium, a halogen atom, a C1-C10 alkyl group, a cyano group, and a silyl group.

According to an example embodiment of the present disclosure, the compound represented by the Chemical Formula 2 is one selected from the group consisting of following compound RHH-1 to compound RHH-20:

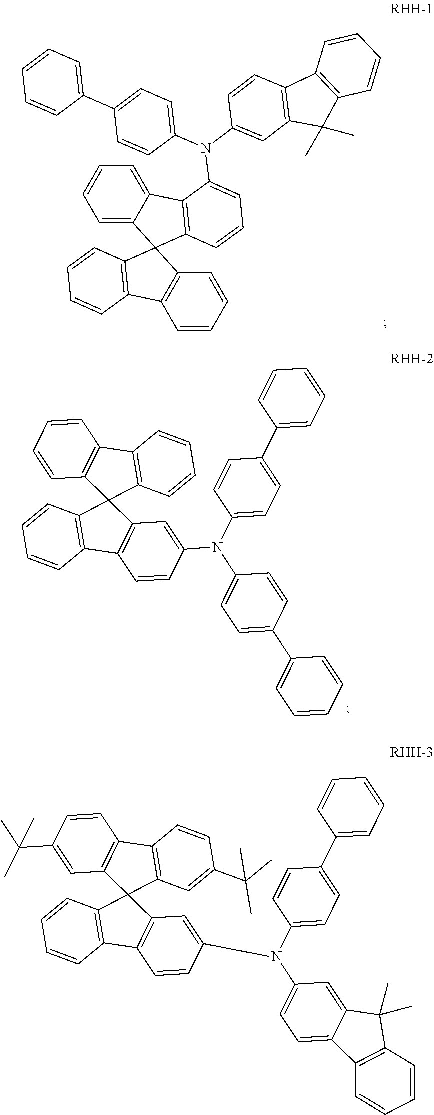 [SMILES: CC1(C)c2ccccc2-c2ccc(N(c3ccc(-c4ccccc4)cc3)c3cccc4c3-c3ccccc3C43c4ccccc4-c4ccccc43)cc21 ; c1ccc(-c2ccc(N(c3ccc(-c4ccccc4)cc3)c3ccc4c(c3)C3(c5ccccc5-c5ccccc53)c3ccccc3-4)cc2)cc1 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1cc(C(C)(C)C)ccc1-2]

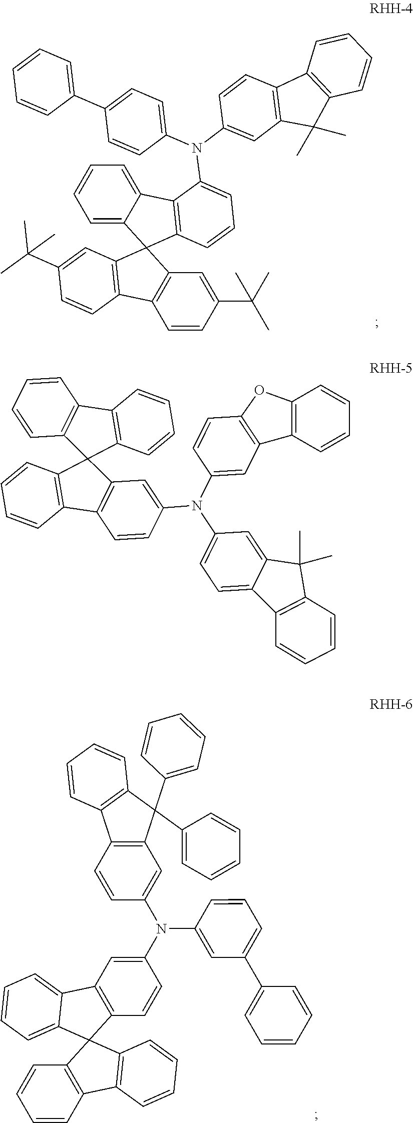 [SMILES: CC(C)(C)c1ccc2c(c1)C1(c3cc(C(C)(C)C)ccc3-2)c2ccccc2-c2c(N(c3ccc(-c4ccccc4)cc3)c3ccc4c(c3)C(C)(C)c3ccccc3-4)cccc21 ; CC1(C)c2ccccc2-c2ccc(N(c3ccc4c(c3)C3(c5ccccc5-c5ccccc53)c3ccccc3-4)c3ccc4oc5ccccc5c4c3)cc21 ; c1ccc(-c2cccc(N(c3ccc4c(c3)-c3ccccc3C43c4ccccc4-c4ccccc43)c3ccc4c(c3)C(c3ccccc3)(c3ccccc3)c3ccccc3-4)c2)cc1]

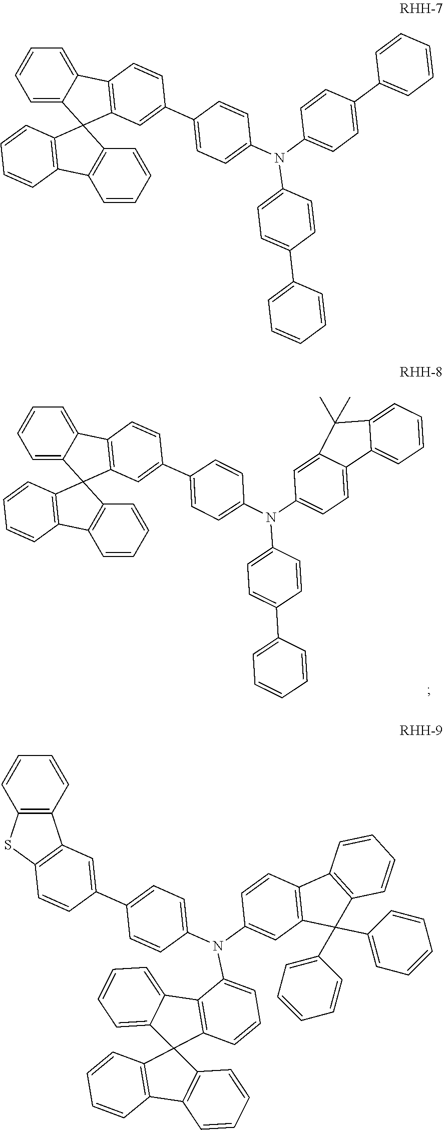 [SMILES: c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21 ; c1ccc(C2(c3ccccc3)c3ccccc3-c3ccc(N(c4ccc(-c5ccc6sc7ccccc7c6c5)cc4)c4cccc5c4-c4ccccc4C54c5ccccc5-c5ccccc54)cc32)cc1]

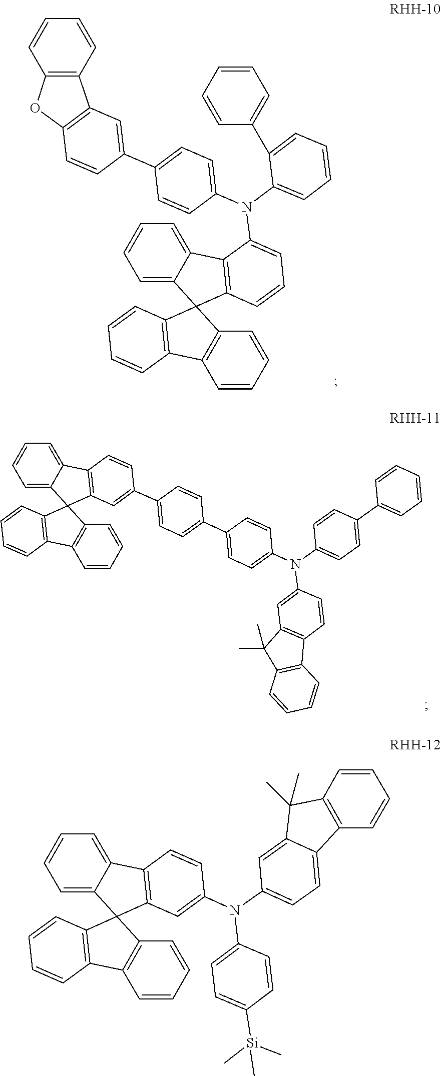 [SMILES: c1ccc(-c2ccccc2N(c2ccc(-c3ccc4oc5ccccc5c4c3)cc2)c2cccc3c2-c2ccccc2C32c3ccccc3-c3ccccc32)cc1 ; CC1(C)c2ccccc2-c2ccc(N(c3ccc(-c4ccccc4)cc3)c3ccc(-c4ccc(-c5ccc6c(c5)C5(c7ccccc7-c7ccccc75)c5ccccc5-6)cc4)cc3)cc21 ; CC1(C)c2ccccc2-c2ccc(N(c3ccc([Si](C)(C)C)cc3)c3ccc4c(c3)C3(c5ccccc5-c5ccccc53)c3ccccc3-4)cc21]

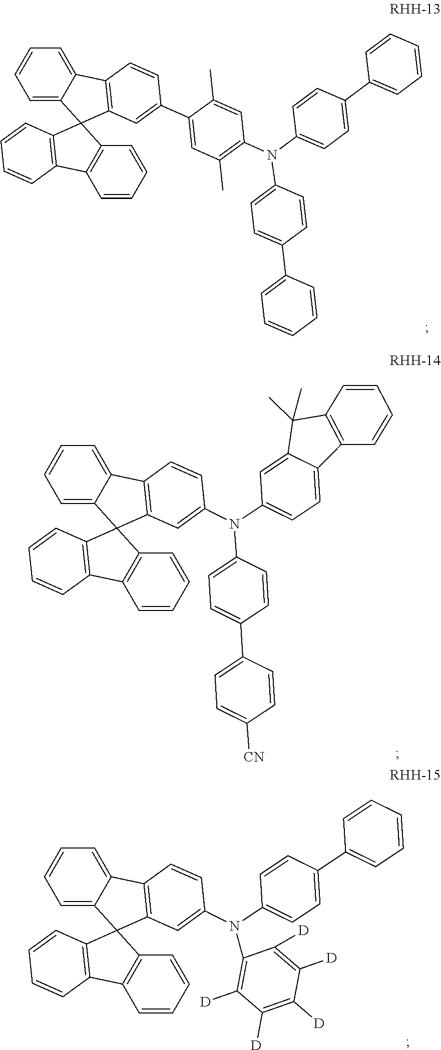 [SMILES: Cc1cc(N(c2ccc(-c3ccccc3)cc2)c2ccc(-c3ccccc3)cc2)c(C)cc1-c1ccc2c(c1)C1(c3ccccc3-c3ccccc31)c1ccccc1-2 ; CC1(C)c2ccccc2-c2ccc(N(c3ccc(-c4ccc(C#N)cc4)cc3)c3ccc4c(c3)C3(c5ccccc5-c5ccccc53)c3ccccc3-4)cc21 ; [2H]c1c([2H])c([2H])c(N(c2ccc(-c3ccccc3)cc2)c2ccc3c(c2)C2(c4ccccc4-c4ccccc42)c2ccccc2-3)c([2H])c1[2H]]

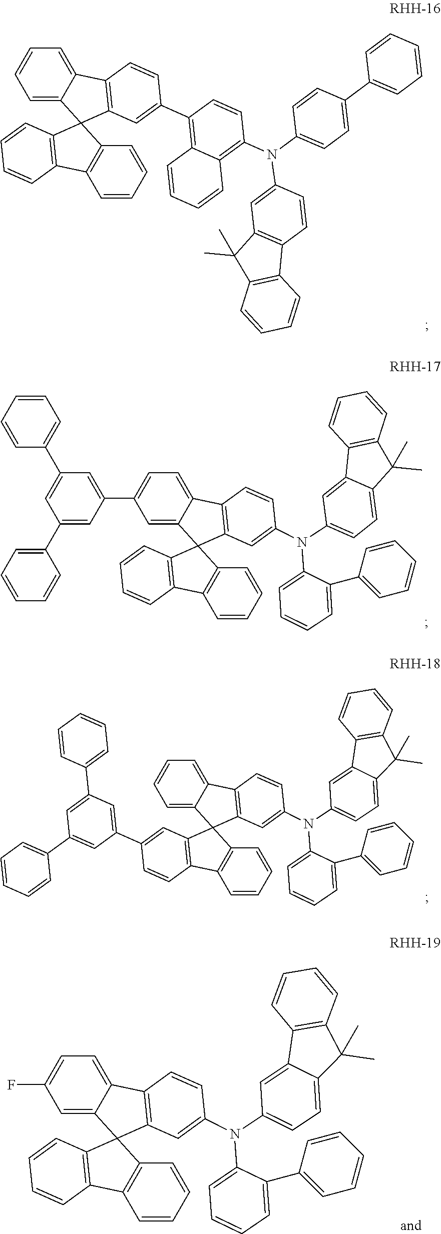 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)c4ccccc34)cc21 ; CC1(C)c2ccccc2-c2cc(N(c3ccc4c(c3)C3(c5ccccc5-c5ccccc53)c3cc(-c5cc(-c6ccccc6)cc(-c6ccccc6)c5)ccc3-4)c3ccccc3-c3ccccc3)ccc21 ; CC1(C)c2ccccc2-c2cc(N(c3ccc4c(c3)C3(c5ccccc5-c5ccc(-c6cc(-c7ccccc7)cc(-c7ccccc7)c6)cc53)c3ccccc3-4)c3ccccc3-c3ccccc3)ccc21 ; CC1(C)c2ccccc2-c2cc(N(c3ccc4c(c3)C3(c5ccccc5-c5ccccc53)c3cc(F)ccc3-4)c3ccccc3-c3ccccc3)ccc21]

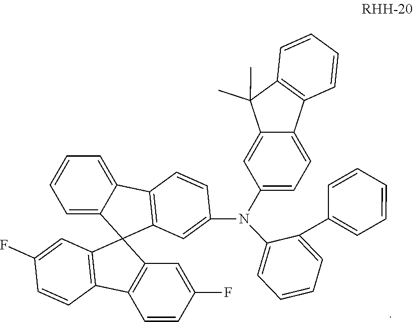 [SMILES: CC1(C)c2ccccc2-c2ccc(N(c3ccc4c(c3)C3(c5ccccc5-4)c4cc(F)ccc4-c4ccc(F)cc43)c3ccccc3-c3ccccc3)cc21]

According to an example embodiment of the present disclosure, in the Chemical Formula 3, each of X₁₁ and X₁₂ may represent N.

According to an example embodiment of the present disclosure, the compound represented by the Chemical Formula 3 is one selected from the group consisting of following compound REH-1 to compound REH-20:

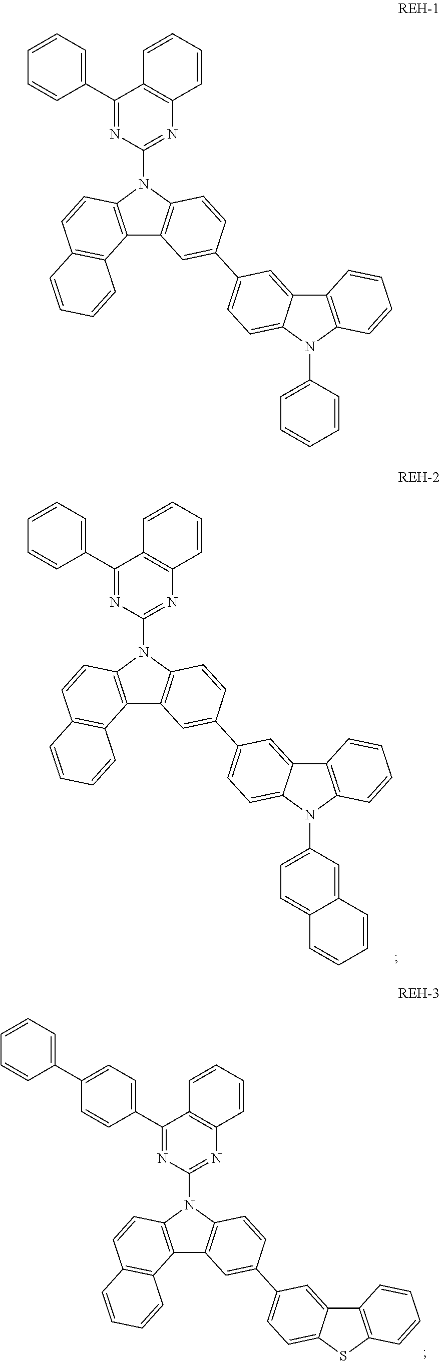 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2nc(-n3c4ccc(-c5ccc6c(c5)c5ccccc5n6-c5ccc6ccccc6c5)cc4c4c5ccccc5ccc43)nc3ccccc23)cc1 ; c1ccc(-c2ccc(-c3nc(-n4c5ccc(-c6ccc7sc8ccccc8c7c6)cc5c5c6ccccc6ccc54)nc4ccccc34)cc2)cc1]

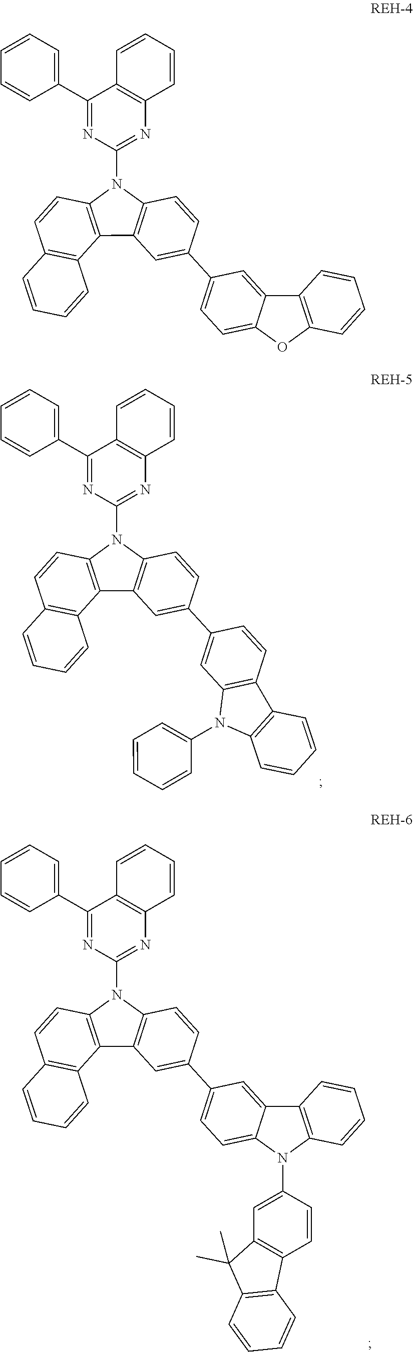 [SMILES: c1ccc(-c2nc(-n3c4ccc(-c5ccc6oc7ccccc7c6c5)cc4c4c5ccccc5ccc43)nc3ccccc23)cc1 ; c1ccc(-c2nc(-n3c4ccc(-c5ccc6c7ccccc7n(-c7ccccc7)c6c5)cc4c4c5ccccc5ccc43)nc3ccccc23)cc1 ; CC1(C)c2ccccc2-c2ccc(-n3c4ccccc4c4cc(-c5ccc6c(c5)c5c7ccccc7ccc5n6-c5nc(-c6ccccc6)c6ccccc6n5)ccc43)cc21]

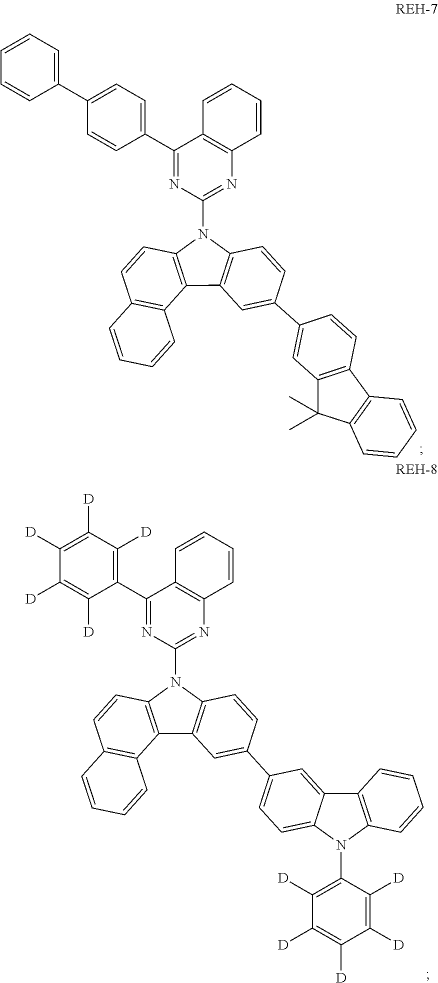 [SMILES: CC1(C)c2ccccc2-c2ccc(-c3ccc4c(c3)c3c5ccccc5ccc3n4-c3nc(-c4ccc(-c5ccccc5)cc4)c4ccccc4n3)cc21 ; [2H]c1c([2H])c([2H])c(-c2nc(-n3c4ccc(-c5ccc6c(c5)c5ccccc5n6-c5c([2H])c([2H])c([2H])c([2H])c5[2H])cc4c4c5ccccc5ccc43)nc3ccccc23)c([2H])c1[2H]]

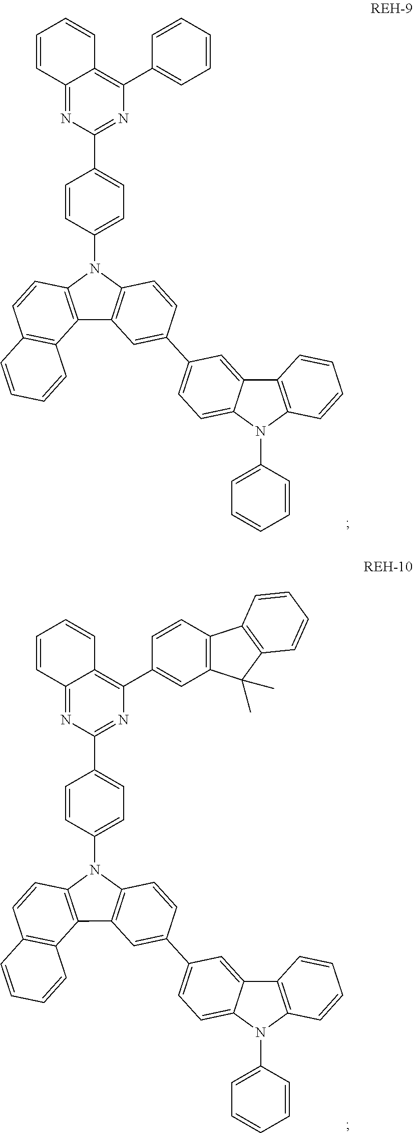 [SMILES: c1ccc(-c2nc(-c3ccc(-n4c5ccc(-c6ccc7c(c6)c6ccccc6n7-c6ccccc6)cc5c5c6ccccc6ccc54)cc3)nc3ccccc23)cc1 ; CC1(C)c2ccccc2-c2ccc(-c3nc(-c4ccc(-n5c6ccc(-c7ccc8c(c7)c7ccccc7n8-c7ccccc7)cc6c6c7ccccc7ccc65)cc4)nc4ccccc34)cc21]

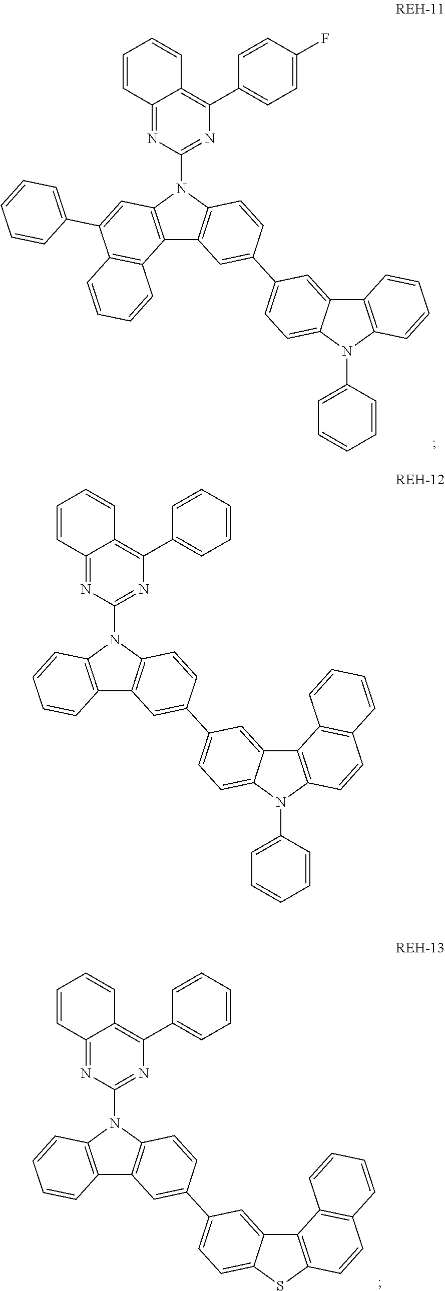 [SMILES: Fc1ccc(-c2nc(-n3c4ccc(-c5ccc6c(c5)c5ccccc5n6-c5ccccc5)cc4c4c5ccccc5c(-c5ccccc5)cc43)nc3ccccc23)cc1 ; c1ccc(-c2nc(-n3c4ccccc4c4cc(-c5ccc6c(c5)c5c7ccccc7ccc5n6-c5ccccc5)ccc43)nc3ccccc23)cc1 ; c1ccc(-c2nc(-n3c4ccccc4c4cc(-c5ccc6sc7ccc8ccccc8c7c6c5)ccc43)nc3ccccc23)cc1]

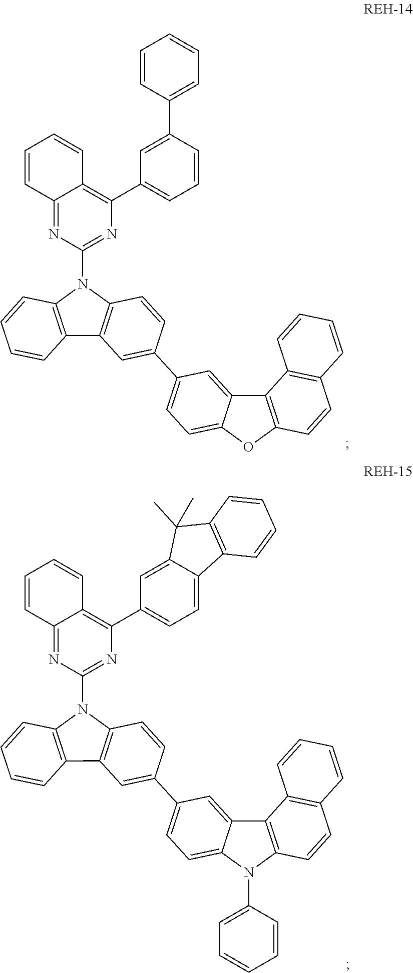 [SMILES: c1ccc(-c2cccc(-c3nc(-n4c5ccccc5c5cc(-c6ccc7oc8ccc9ccccc9c8c7c6)ccc54)nc4ccccc34)c2)cc1 ; CC1(C)c2ccccc2-c2ccc(-c3nc(-n4c5ccccc5c5cc(-c6ccc7c(c6)c6c8ccccc8ccc6n7-c6ccccc6)ccc54)nc4ccccc34)cc21]

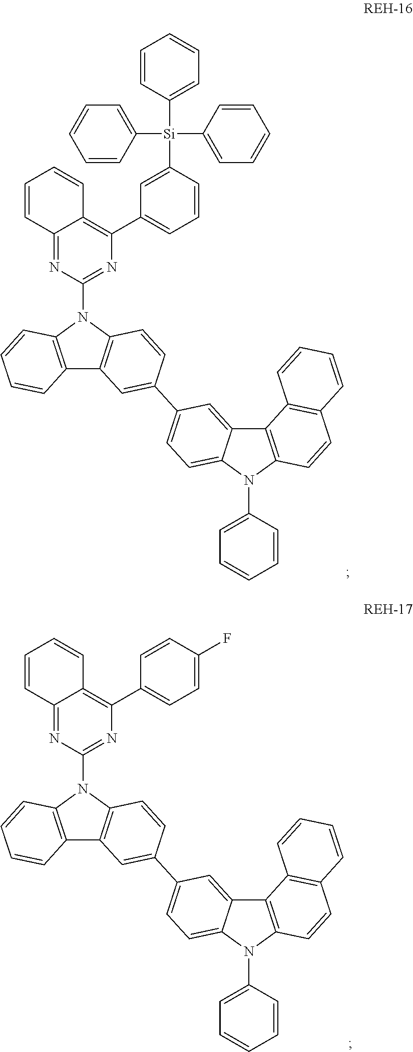 [SMILES: c1ccc(-n2c3ccc(-c4ccc5c(c4)c4ccccc4n5-c4nc(-c5cccc([Si](c6ccccc6)(c6ccccc6)c6ccccc6)c5)c5ccccc5n4)cc3c3c4ccccc4ccc32)cc1 ; Fc1ccc(-c2nc(-n3c4ccccc4c4cc(-c5ccc6c(c5)c5c7ccccc7ccc5n6-c5ccccc5)ccc43)nc3ccccc23)cc1]

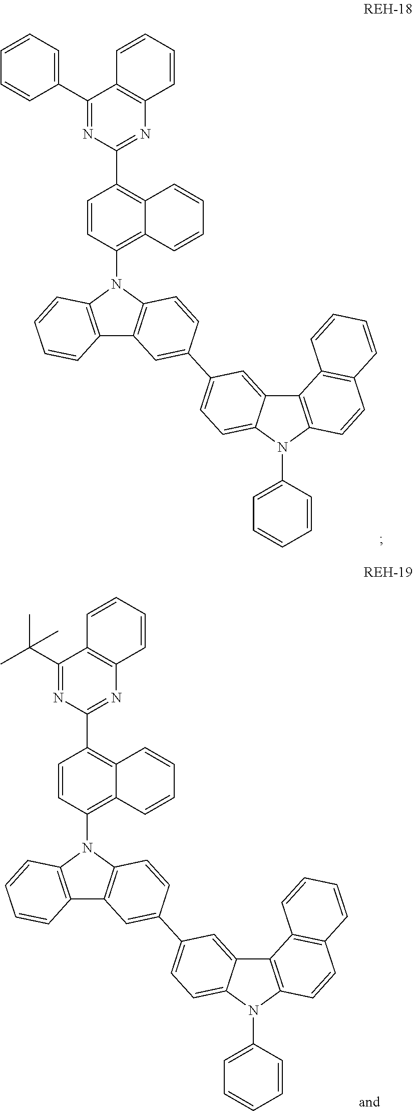 [SMILES: c1ccc(-c2nc(-c3ccc(-n4c5ccccc5c5cc(-c6ccc7c(c6)c6c8ccccc8ccc6n7-c6ccccc6)ccc54)c4ccccc34)nc3ccccc23)cc1 ; CC(C)(C)c1nc(-c2ccc(-n3c4ccccc4c4cc(-c5ccc6c(c5)c5c7ccccc7ccc5n6-c5ccccc5)ccc43)c3ccccc23)nc2ccccc12]

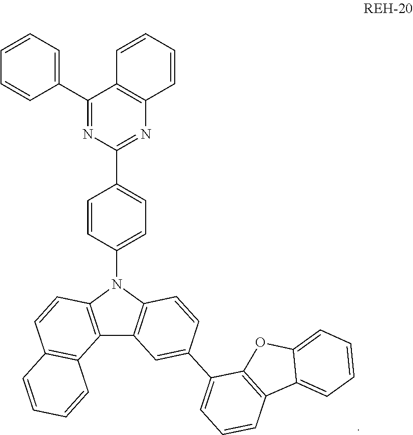 [SMILES: c1ccc(-c2nc(-c3ccc(-n4c5ccc(-c6cccc7c6oc6ccccc67)cc5c5c6ccccc6ccc54)cc3)nc3ccccc23)cc1]

In addition, in the organic light-emitting diode 100, the organic layer 130 disposed between the first electrode 110 and the second electrode 120 may be formed by sequentially stacking a hole injection layer 140 (HIL), a hole transport layer 150, (HTL), alight emission layer 160 (EML), an electron transport layer 170 (ETL) and an electron injection layer 180 (EIL) on the first electrode 110. The second electrode 120 may be formed or disposed on the electron injection layer 180, and a protective layer (not shown) may be formed or disposed thereon.

Further, although not shown in FIG. 1, a hole transport auxiliary layer may be further added between the hole transport layer 150 and the light-emissive layer 160. The hole transport auxiliary layer may contain a compound having good hole transport properties, and may reduce a difference between HOMO energy levels of the hole transport layer 150 and the light-emissive layer 160 so as to adjust the hole injection properties. Thus, accumulation of holes at an interface between the hole transport auxiliary layer and the light-emissive layer 160 may be reduced, thereby reducing a quenching phenomenon in which excitons disappear at the interface due to polarons. Accordingly, deterioration of the element may be reduced and the element may be stabilized, thereby improving efficiency and lifespan thereof.

The first electrode 110 may act as a positive electrode, and may be made of or include ITO, IZO, tin-oxide, or zinc-oxide as a conductive material having a relatively large work function value. However, the present disclosure is not limited thereto.

The second electrode 120 may act as a negative electrode, and may include Al, Mg, Ca, or Ag as a conductive material having a relatively small work function value, or an alloy or combination thereof. However, the present disclosure is not limited thereto.

The hole injection layer 140 may be positioned between the first electrode 110 and the hole transport layer 150. The hole injection layer 140 may have a function of improving interface characteristics between the first electrode 110 and the hole transport layer 150, and may be selected from a material having appropriate conductivity. The hole injection layer 140 may include a compound selected from the group consisting of MTDATA, CuPc, TCTA, HATCN, TDAPB, PEDOT/PSS, and N1,N1′-([1,1′-biphenyl]-4,4′-diyl)bis(N1,N4,N4)-triphenylbenzene-1,4-diamine). In some embodiments, the hole injection layer 140 may include N1,N1′-([1,1′-biphenyl]-4,4′-diyl)bis(N1,N4,N4-triphenylbenzene-1,4-diamine). However, the present disclosure is not limited thereto.

The hole transport layer 150 may be positioned adjacent to the light-emissive layer and between the first electrode 110 and the light-emissive layer 160. A material of the hole transport layer 150 may include a compound selected from the group consisting of TPD, NPB, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, etc. In some embodiments, the material of the hole transport layer 150 may include NPB. However, the present disclosure is not limited thereto.

According to an example embodiment of the present disclosure, the light-emissive layer 160 may be formed by doping the mixture of the host materials 160″ and 160′″ with the organometallic compound represented by the Chemical Formula 1 as the dopant 160′ in order to improve luminous efficiency of the diode 100. The dopant 160′ may be used as a green or red light-emitting material. In some embodiments of the present disclosure, the dopant 160′ may be used as a red phosphorescent material.

According to an example embodiment of the present disclosure, a doping concentration of the dopant 160′ may be adjusted to be within a range of 1 to 30% by weight based on a total weight of the mixture of the two host materials 160″ and 160′″. However, the disclosure is not limited thereto. For example, the doping concentration may be in a range of 2 to 20 wt %, for example, 3 to 15 wt %, for example, 5 to 10 wt %, for example, 3 to 8 wt %, for example, 2 to 7 wt %, for example, 5 to 7 wt %, or for example, 5 to 6 wt %.

According to an example embodiment of the present disclosure, the mixing ratio of the two types of hosts 160″ and 160′″ is not particularly limited. The host 160″ which is the compound represented by the Chemical Formula 2 has hole transport properties. The host 160′″ which is the compound represented by the Chemical Formula 3 has electron transport characteristics. Thus, the mixture of the two kinds of hosts can achieve the advantage of increasing the lifespan and efficiency characteristics of the element. The mixing ratio of the two types of hosts may be appropriately adjusted. Therefore, the mixing ratio of the two hosts, that is, the compound represented by the Chemical Formula 2 and the compound represented by the Chemical Formula 3 is not particularly limited. The mixing ratio (based on a weight) of the compound represented by the Chemical Formula 2 and the compound represented by the Chemical Formula 3 may be, for example, in a range of 1:9 to 9:1, for example, may be 2:8, for example, may be 3:7, for example, may be 4:6, for example, may be 5:5, for example, may be 6:4, for example, may be 7:3, for example, may be 8:2.

Further, the electron transport layer 170 and the electron injection layer 180 may be sequentially stacked between the light-emissive layer 160 and the second electrode 120. A material of the electron transport layer 170 may exhibit high electron mobility such that electrons may be stably supplied to the light-emissive layer under smooth electron transport.

For example, the material of the electron transport layer 170 may be known in the art and may include a compound selected from the group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4-oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzothiazole, and 2-(4-(9,10-di(naphthalen-2-yl)anthracen-2-yl)phenyl)-1-phenyl-1H-benzo[d]imidazole. In some embodiments, the material of the electron transport layer 170 may include 2-(4-(9,10-di(naphthalen-2-yl)anthracen-2-yl)phenyl)-1-phenyl-1H-benzo[d]imidazole. However, the present disclosure is not limited thereto.

The electron injection layer 180 may facilitate electron injection. A material of the electron injection layer may be known in the art and may include a compound selected from the group consisting of Alq3 (tris(8-hydroxyquinolino)aluminum), PBD, TAZ, spiro-PBD, BAlq, SAlq, etc. However, the present disclosure is not limited thereto. Alternatively, the electron injection layer 180 may be made of or include a metal compound. The metal compound may include, for example, one or more selected from the group consisting of Liq, LiF, NaF, KF, RbF, CsF, FrF, BeF₂, MgF₂, CaF₂, SrF₂, BaF₂ and RaF₂. However, the present disclosure is not limited thereto.

The organic light-emitting diode according to the present disclosure may be embodied as a white light-emitting diode having a tandem structure. The tandem organic light-emitting diode according to example embodiments of the present disclosure may include a structure in which adjacent two or more light-emitting stacks are connected to each other via a charge generation layer (CGL). The organic light-emitting diode may include at least two light-emitting stacks disposed on a substrate, and the light-emissive layer disposed between the first and second electrodes to emit light in a specific wavelength band. Each of the at least two light-emitting stacks may include first and second electrodes facing each other. The plurality of light-emitting stacks may emit light of same or different colors. In addition, one or more light-emissive layers may be included in one light-emitting stack, and the one or more light-emissive layers may emit light of same or different colors.

In example embodiments, the light-emissive layer included in at least one of the plurality of light-emitting stacks may contain the organometallic compound represented by the Chemical Formula 1 according to the present disclosure as the dopant. Adjacent light-emitting stacks in the tandem structure may be connected to each other via the charge generation layer CGL including an N-type charge generation layer and a P-type charge generation layer.

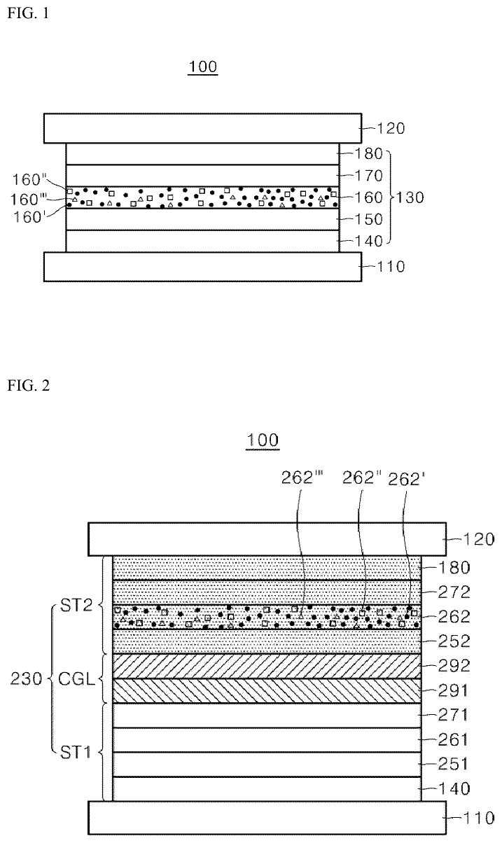

FIG. 2 is a schematic cross-sectional view illustrating an organic light-emitting diode having a tandem structure including two light-emitting stacks according to an example embodiment of the present disclosure.

As illustrated in FIG. 2, an organic light-emitting diode 100 according to the present disclosure include a first electrode 110 and a second electrode 120 facing each other, and an organic layer 230 positioned between the first electrode 110 and the second electrode 120. The organic layer 230 may be positioned between the first electrode 110 and the second electrode 120 and may include a first light-emitting stack ST1 including a first light-emissive layer 261, a second light-emitting stack ST2 positioned between the first light-emitting stack ST1 and the second electrode 120 and including a second light-emissive layer 262, and the charge generation layer CGL positioned between the first and second light-emitting stacks ST1 and ST2. The charge generation layer CGL may include an N-type charge generation layer 291 and a P-type charge generation layer 292. At least one of the first light-emissive layer 261 and the second light-emissive layer 262 may contain the organometallic compound represented by the Chemical Formula 1 according to the present disclosure as the dopants 262′. For example, as illustrated in FIG. 2, the second light-emitting layer 262 of the second light-emitting stack ST2 may include a compound 262′ represented by the Chemical Formula 1 as a dopant, a compound 262″ represented by the Chemical Formula 2 as a hole transporting host, and a compound 262′″ represented by the Chemical Formula 3 as an electron transporting host. Although not shown in FIG. 2, each of the first and second light-emitting stacks ST1 and ST2 may further include an additional light-emissive layer in addition to each of the first light-emitting layer 261 and the second light-emitting layer 262. The descriptions as set forth above with respect to the hole transport layer 150 of FIG. 1 may be applied in the same or similar manner to each of the first hole transport layer 251 and the second hole transport layer 252 of FIG. 2. Moreover, the descriptions as set forth above with respect to the electron transport layer 170 of FIG. 1 may be applied in the same or similar manner to each of the first electron transport layer 271 and the second electron transport layer 272 of FIG. 2.

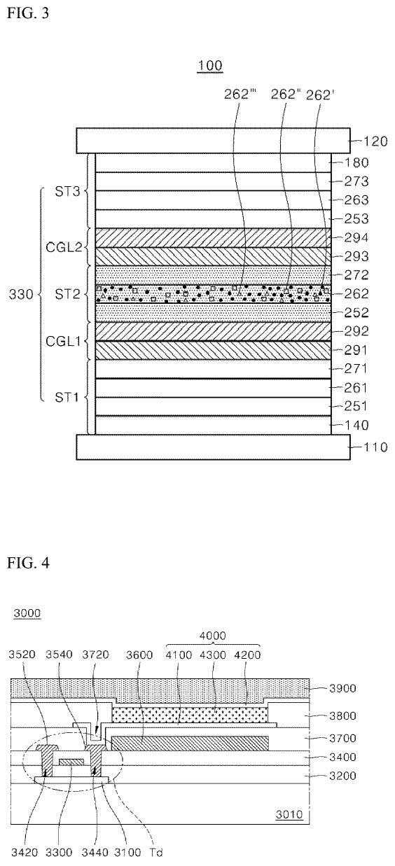

FIG. 3 is a cross-sectional view schematically illustrating an organic light-emitting diode having a tandem structure having three light-emitting stacks according to an example embodiment of the present disclosure.

As illustrated in FIG. 3, the organic light-emitting diode 100 according to the present disclosure include the first electrode 110 and the second electrode 120 facing each other, and an organic layer 330 positioned between the first electrode 110 and the second electrode 120. The organic layer 330 may be positioned between the first electrode 110 and the second electrode 120 and may include the first light-emitting stack ST1 including the first light-emissive layer 261, the second light-emitting stack ST2 including the second light-emissive layer 262, a third light-emitting stack ST3 including a third light-emissive layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 may include a N-type charge generation layers 291 and a P-type charge generation layer 292. The second charge generation layer CGL2 may include a N-type charge generation layers 293 and a P-type charge generation layer 294. At least one of the first light-emissive layer 261, the second light-emissive layer 262, and the third light-emissive layer 263 may contain the organometallic compound represented by the Chemical Formula 1 according to the present disclosure as the dopants. For example, as illustrated in FIG. 3, the second light-emitting layer 262 of the second light-emitting stack ST2 may include the compound 262′ represented by the Chemical Formula 1 as a dopant, the compound 262″ represented by the Chemical Formula 2 as a hole transporting host, and the compound 262′″ represented by the Chemical Formula 3 as an electron transporting host. Although not shown in FIG. 3, each of the first, second and third light-emitting stacks ST1, ST2 and ST3 may further include an additional light-emissive layer, in addition to each of the first light-emissive layer 261, the second light-emissive layer 262 and the third light-emissive layer 263. The descriptions as set forth above with respect to the hole transport layer 150 of FIG. 1 may be applied in the same or similar manner to each of the first hole transport layer 251, the second hole transport layer 252, and the third hole transport layer 253 of FIG. 3. Moreover, the descriptions as set forth above with respect to the electron transport layer 170 of FIG. 1 may be applied in the same or similar manner to each of the first electron transport layer 271, the second electron transport layer 272, and the third electron transport layer 273 of FIG. 3.

Furthermore, an organic light-emitting diode according to an embodiment of the present disclosure may include a tandem structure in which four or more light-emitting stacks and three or more charge generating layers are disposed between the first electrode and the second electrode.

The organic light-emitting diode according to the present disclosure may be used as a light-emitting element of each of an organic light-emitting display device and a lighting device. FIG. 4 is a cross-sectional view schematically illustrating an organic light-emitting display device including an organic light-emitting diode according to an example embodiment of the present disclosure. In an example embodiment, FIG. 4 illustrates an organic light-emitting display device including the organic light-emitting diode according to some example embodiments of the present disclosure as a light-emitting element thereof.

As illustrated in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not shown explicitly in FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed or disposed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 may be formed or disposed on the substrate 3010 and may be made of or include an oxide semiconductor material or polycrystalline silicon. When the semiconductor layer 3100 is made of or include an oxide semiconductor material, a light-shielding pattern (not shown) may be formed or disposed under the semiconductor layer 3100. The light-shielding pattern may prevent or reduce light from being incident into the semiconductor layer 3100 to prevent the semiconductor layer 3100 from being deteriorated due to the light. Alternatively, the semiconductor layer 3100 may be made of or include polycrystalline silicon. In some example embodiments, both edges of the semiconductor layer 3100 may be doped with impurities.

The gate insulating layer 3200 made of or include an insulating material is formed or disposed over an entirety of a surface of the substrate 3010 and on the semiconductor layer 3100. The gate insulating layer 3200 may be made of or include an inorganic insulating material such as silicon oxide or silicon nitride.

The gate electrode 3300 made of or include a conductive material such as a metal is formed or disposed on the gate insulating layer 3200 and corresponds to a center of the semiconductor layer 3100. The gate electrode 3300 is connected to the switching thin film transistor.

The interlayer insulating layer 3400 made of or include an insulating material is formed or disposed over the entirety of the surface of the substrate 3010 and on the gate electrode 3300. The interlayer insulating layer 3400 may be made of or include an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of or include a conductive material such as metal are formed or disposed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line (not shown).

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td may have an inverted staggered structure in which the gate electrode is disposed under the semiconductor layer while the source electrode and the drain electrode are disposed above the semiconductor layer. In some example embodiments, the semiconductor layer may be made of or include amorphous silicon. In an example embodiment, the switching thin-film transistor (not shown) may have substantially the same structure as that of the driving thin-film transistor (Td).

In an example embodiment, the organic light-emitting display device 3000 may include a color filter 3600 absorbing the light generated from the electroluminescent element (light-emitting diode) 4000. For example, the color filter 3600 may absorb red (R), green (G), blue (B), and white (W) light. In some example embodiments, red, green, and blue color filter patterns that absorb light may be formed or disposed separately in different pixel areas. Each of these color filter patterns may be disposed to overlap each organic layer 4300 of the organic light-emitting diode 4000 to emit light of a wavelength band corresponding to each color filter. Adopting the color filter 3600 may allow the organic light-emitting display device 3000 to realize full-color.

For example, when the organic light-emitting display device 3000 is of a bottom emission type, the color filter 3600 absorbing light may be positioned on a portion of the interlayer insulating layer 3400 corresponding to the organic light-emitting diode 4000. In some example embodiments, when the organic light-emitting display device 3000 is of a top emission type, the color filter may be positioned on top of the organic light-emitting diode 4000, that is, on top of a second electrode 4200. For example, the color filter 3600 may be formed to have a thickness of 2 to 5 μm.

In an example embodiment, a planarization layer 3700 having a drain contact hole 3720 defined therein exposing the drain electrode 3540 of the driving thin-film transistor Td is formed or disposed to cover the driving thin-film transistor Td.

On the planarization layer 3700, each first electrode 4100 connected to the drain electrode 3540 of the driving thin-film transistor Td via the drain contact hole 3720 is formed or disposed individually in each pixel area.

The first electrode 4100 may act as a positive electrode (anode), and may be made of or include a conductive material having a relatively large work function value. For example, the first electrode 4100 may be made of or include a transparent conductive material such as ITO, IZO or ZnO.

In an example embodiment, when the organic light-emitting display device 3000 is of a top-emission type, a reflective electrode or a reflective layer may be further formed or disposed under the first electrode 4100. For example, the reflective electrode or the reflective layer may be made of or include one of aluminum (Al), silver (Ag), nickel (Ni), and an aluminum-palladium-copper (APC) alloy.

A bank layer 3800 covering an edge of the first electrode 4100 is formed or disposed on the planarization layer 3700. The bank layer 3800 exposes a center of the first electrode 4100 corresponding to the pixel area.

An organic layer 4300 is formed or disposed on the first electrode 4100. Optionally, the organic light-emitting diode 4000 may have a tandem structure. Regarding the tandem structure, reference may be made to FIG. 2 to FIG. 3, which illustrate some example embodiments of the present disclosure, and the above descriptions thereof.

The second electrode 4200 is formed or disposed on the substrate 3010 on which the organic layer 4300 has been formed or disposed. The second electrode 4200 is disposed over the entirety of the surface of the display area and is made of or include a conductive material having a relatively small work function value and may be used as a negative electrode (a cathode). For example, the second electrode 4200 may be made of or include one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed or disposed on the second electrode 4200 to prevent or reduce external moisture from penetrating into the organic light-emitting diode 4000. Although not shown explicitly in FIG. 4, the encapsulation film 3900 may have a triple-layer structure in which a first inorganic layer, an organic layer, and an inorganic layer are sequentially stacked. However, the present disclosure is not limited thereto.

Hereinafter, Present Examples of the present disclosure will be described. The present disclosure is not limited thereto.

### Present Example 1

An ITO substrate was washed with UV ozone before use and then loaded into an evaporation system. The substrate was then transferred into a vacuum deposition chamber for deposition of all other layers on top of the substrate. The following materials were deposited via evaporation from a heated boat under a vacuum of about 10⁻⁷ Torr to form the respective layers having the thicknesses indicated below:
(a) hole injection layer (HIL): 100 Å, HATCN
(b) hole transport layer (HTL): 700 Å, HTL
(c) light-emissive layer (EML): 300 Å, host (RHH:REH 1:1)/dopant (10%)
(e) electron transport layer (ETL): 300 Å, Alq₃
(f) electron injection layer (EIL): 10 Å, LiF
(h) Cathode: 1000 Å, Al (aluminum)

The light-emissive layer was formed by mixing RHH and REH with each other at a weight ratio of 1:1 to produce a mixture as a host, and doping the mixture with 10% by weight of the dopant relative to 100% by weight of the mixture. The host materials (RHH, REH) and the dopant materials in Present Examples are shown in following Tables 1 to 8.

An organic electric field light-emitting diode was formed by depositing HIL/HTL/EML/ETL/EIL/Cathode on the ITO in this order, and then was transferred from the deposition chamber to a drying box. An encapsulation layer was formed thereon using an UV curable epoxy and a moisture getter. The manufactured organic light-emitting diode had an emission area of 9 mm².

The materials used in Present Example 1 are as follows:

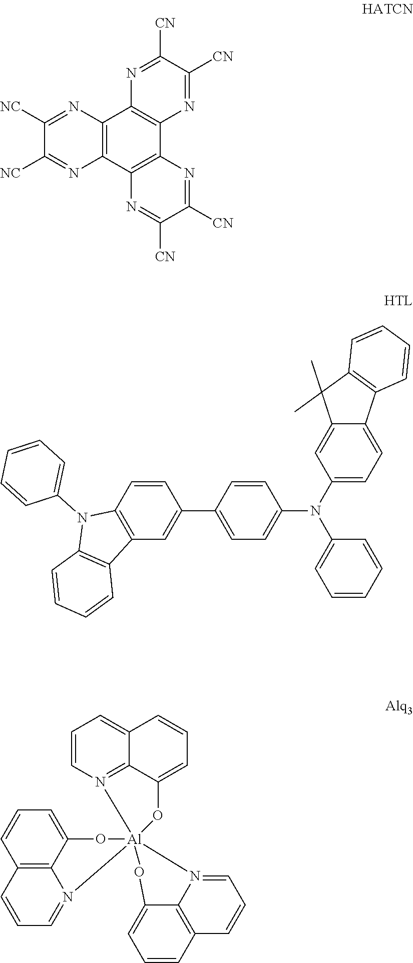

### Comparative Examples 1 to 4 and Present Examples 2 to 144

An organic light-emitting diode of each of Comparative Examples 1 to 4 and Present Examples 2 to 144 was fabricated in the same manner as in Present Example 1, except that the dopant materials and the host materials listed in Tables 1 to 8 were used. However, in each of Comparative Examples 1 to 4, only CBP having a following structure was used as a host material:

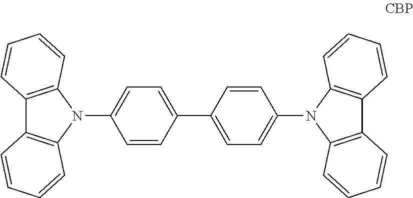 [SMILES: c1ccc2c(c1)c1ccccc1n2-c1ccc(-c2ccc(-n3c4ccccc4c4ccccc43)cc2)cc1]

### Experimental Example

The organic light-emitting diode manufactured in each of Present Examples 1 to 144 and Comparative Examples 1 to 4 was connected to an external power source, and the diode characteristics were evaluated at room temperature using a constant current source (KEITHLEY) and a photometer PR 650.

Specifically, operation voltage (V) and external quantum efficiency (EQE; %) were measured at a current density of 10 mA/cm², and lifetime characteristics (LT95, relative value) was measured at 40° C. and at a current density of 40 mA/cm², and then were calculated as relative values to those of a corresponding one of Comparative Examples 1 to 4, and the results are shown in the following Tables 1 to 8.

LT95 lifetime refers to a time it takes for the display element to lose 5% of its initial brightness. LT95 may be the customer specification the most difficult to meet. Whether or not image burn-in occurs on the display may be determined based on the LT95.

TABLE 1

| | | | | Oper- | EQE | LT95 |
|---|---|---|---|---|---|---|
| | | | | ation | (%, | (%, |
| | Light-emissive layer | | | voltage | relative | relative |
| | Dopant | Host | | (V) | value) | value) |
| Comparative | RD-1 | CBP | | 4.30 | 100 | 100 |
| Example 1 | | | | | | |
| Present | RD-1 | RHH-1 | REH-1 | 4.15 | 120 | 140 |
| Example 1 | | | | | | |
| Present | RD-1 | RHH-1 | REH-2 | 4.14 | 122 | 138 |
| Example 2 | | | | | | |
| Present | RD-1 | RHH-1 | REH-3 | 4.10 | 115 | 125 |
| Example 3 | | | | | | |
| Present | RD-1 | RHH-1 | REH-4 | 4.09 | 114 | 125 |
| Example 4 | | | | | | |
| Present | RD-1 | RHH-1 | REH-5 | 4.11 | 114 | 125 |
| Example 5 | | | | | | |
| Present | RD-1 | RHH-1 | REH-6 | 4.10 | 115 | 128 |
| Example 6 | | | | | | |
| Present | RD-1 | RHH-2 | REH-1 | 4.13 | 118 | 138 |
| Example 7 | | | | | | |
| Present | RD-1 | RHH-2 | REH-2 | 4.12 | 120 | 135 |
| Example 8 | | | | | | |
| Present | RD-1 | RHH-2 | REH-3 | 4.09 | 113 | 125 |
| Example 9 | | | | | | |
| Present | RD-1 | RHH-2 | REH-4 | 4.10 | 112 | 126 |
| Example 10 | | | | | | |
| Present | RD-1 | RHH-2 | REH-5 | 4.10 | 111 | 127 |
| Example 11 | | | | | | |
| Present | RD-1 | RHH-2 | REH-6 | 4.11 | 114 | 125 |
| Example 12 | | | | | | |
| Present | RD-1 | RHH-3 | REH-1 | 4.15 | 120 | 135 |
| Example 13 | | | | | | |
| Present | RD-1 | RHH-3 | REH-2 | 4.13 | 120 | 130 |
| Example 14 | | | | | | |
| Present | RD-1 | RHH-3 | REH-3 | 4.10 | 115 | 125 |
| Example 15 | | | | | | |
| Present | RD-1 | RHH-3 | REH-4 | 4.11 | 112 | 125 |
| Example 16 | | | | | | |
| Present | RD-1 | RHH-3 | REH-5 | 4.10 | 110 | 127 |
| Example 17 | | | | | | |
| Present | RD-1 | RHH-3 | REH-6 | 4.10 | 115 | 125 |
| Example 18 | | | | | | |

TABLE 2

| | | | | Oper- | EQE | LT95 |
|---|---|---|---|---|---|---|
| | | | | ation | (%, | (%, |
| | Light-emissive layer | | | voltage | relative | relative |
| | Dopant | Host | | (V) | value) | value) |
| Comparative | RD-1 | CBP | | 4.30 | 100 | 100 |
| Example 1 | | | | | | |
| Present | RD-1 | RHH-4 | REH-1 | 4.20 | 120 | 145 |
| Example 19 | | | | | | |
| Present | RD-1 | RHH-4 | REH-2 | 4.18 | 120 | 130 |
| Example 20 | | | | | | |
| Present | RD-1 | RHH-4 | REH-3 | 4.15 | 118 | 130 |
| Example 21 | | | | | | |
| Present | RD-1 | RHH-4 | REH-4 | 4.15 | 115 | 125 |
| Example 22 | | | | | | |
| Present | RD-1 | RHH-4 | REH-5 | 4.10 | 115 | 130 |
| Example 23 | | | | | | |
| Present | RD-1 | RHH-4 | REH-6 | 4.12 | 115 | 128 |
| Example 24 | | | | | | |
| Present | RD-1 | RHH-5 | REH-1 | 4.14 | 118 | 125 |
| Example 25 | | | | | | |
| Present | RD-1 | RHH-5 | REH-2 | 4.15 | 115 | 120 |
| Example 26 | | | | | | |
| Present | RD-1 | RHH-5 | REH-3 | 4.13 | 114 | 115 |
| Example 27 | | | | | | |
| Present | RD-1 | RHH-5 | REH-4 | 4.12 | 113 | 115 |
| Example 28 | | | | | | |
| Present | RD-1 | RHH-5 | REH-5 | 4.11 | 112 | 117 |
| Example 29 | | | | | | |
| Present | RD-1 | RHH-5 | REH-6 | 4.11 | 114 | 115 |
| Example 30 | | | | | | |
| Present | RD-1 | RHH-6 | REH-1 | 4.15 | 110 | 125 |
| Example 31 | | | | | | |
| Present | RD-1 | RHH-6 | REH-2 | 4.16 | 110 | 120 |
| Example 32 | | | | | | |
| Present | RD-1 | RHH-6 | REH-3 | 4.18 | 108 | 110 |
| Example 33 | | | | | | |
| Present | RD-1 | RHH-6 | REH-4 | 4.15 | 109 | 115 |
| Example 34 | | | | | | |
| Present | RD-1 | RHH-6 | REH-5 | 4.14 | 110 | 120 |
| Example 35 | | | | | | |
| Present | RD-1 | RHH-6 | REH-6 | 4.13 | 111 | 118 |
| Example 36 | | | | | | |

TABLE 3

| | | | | Oper- | EQE | LT95 |
|---|---|---|---|---|---|---|
| | | | | ation | (%, | (%, |
| | Light-emissive layer | | | voltage | relative | relative |
| | Dopant | Host | | (V) | value) | value) |
| Comparative | RD-2 | CBP | | 4.32 | 100 | 100 |
| Example 2 | | | | | | |
| Present | RD-2 | RHH-1 | REH-1 | 4.22 | 110 | |
| Example 37 | | | | | | |
| Present | RD-2 | RHH-1 | REH-2 | 4.20 | 111 | 120 |
| Example 38 | | | | | | |
| Present | RD-2 | RHH-1 | REH-3 | 4.18 | 108 | 120 |
| Example 39 | | | | | | |
| Present | RD-2 | RHH-1 | REH-4 | 4.19 | 110 | 115 |
| Example 40 | | | | | | |
| Present | RD-2 | RHH-1 | REH-5 | 4.15 | 111 | 120 |
| Example 41 | | | | | | |
| Present | RD-2 | RHH-1 | REH-6 | 4.15 | 110 | 120 |
| Example 42 | | | | | | |
| Present | RD-2 | RHH-2 | REH-1 | 4.15 | 115 | 118 |
| Example 43 | | | | | | |
| Present | RD-2 | RHH-2 | REH-2 | 4.17 | 114 | 115 |
| Example 44 | | | | | | |
| Present | RD-2 | RHH-2 | REH-3 | 4.14 | 110 | 115 |
| Example 45 | | | | | | |
| Present | RD-2 | RHH-2 | REH-4 | 4.15 | 110 | 116 |
| Example 46 | | | | | | |
| Present | RD-2 | RHH-2 | REH-5 | 4.15 | 108 | 117 |
| Example 47 | | | | | | |
| Present | RD-2 | RHH-2 | REH-6 | 4.14 | 110 | 115 |
| Example 48 | | | | | | |
| Present | RD-2 | RHH-3 | REH-1 | 4.15 | 110 | 125 |
| Example 49 | | | | | | |
| Present | RD-2 | RHH-3 | REH-2 | 4.17 | 112 | 120 |
| Example 50 | | | | | | |
| Present | RD-2 | RHH-3 | REH-3 | 4.20 | 113 | 115 |
| Example 51 | | | | | | |
| Present | RD-2 | RHH-3 | REH-4 | 4.15 | 111 | 115 |
| Example 52 | | | | | | |
| Present | RD-2 | RHH-3 | REH-5 | 4.18 | 110 | 117 |
| Example 53 | | | | | | |
| Present | RD-2 | RHH-3 | REH-6 | 4.18 | 110 | 115 |
| Example 54 | | | | | | |

TABLE 4

| | | | | Oper- | EQE | LT95 |
|---|---|---|---|---|---|---|
| | | | | ation | (%, | (%, |
| | Light-emissive layer | | | voltage | relative | relative |
| | Dopant | Host | | (V) | value) | value) |
| Comparative | RD-2 | CBP | | 4.32 | 100 | 100 |
| Example 2 | | | | | | |
| Present | RD-2 | RHH-4 | REH-1 | 4.22 | 115 | 125 |
| Example 55 | | | | | | |
| Present | RD-2 | RHH-4 | REH-2 | 4.20 | 113 | 120 |
| Example 56 | | | | | | |
| Present | RD-2 | RHH-4 | REH-3 | 4.18 | 112 | 110 |
| Example 57 | | | | | | |
| Present | RD-2 | RHH-4 | REH-4 | 4.19 | 114 | 115 |
| Example 58 | | | | | | |
| Present | RD-2 | RHH-4 | REH-5 | 4.15 | 114 | 110 |
| Example 59 | | | | | | |
| Present | RD-2 | RHH-4 | REH-6 | 4.18 | 117 | 118 |
| Example 60 | | | | | | |
| Present | RD-2 | RHH-5 | REH-1 | 4.15 | 115 | 120 |
| Example 61 | | | | | | |
| Present | RD-2 | RHH-5 | REH-2 | 4.16 | 112 | 115 |
| Example 62 | | | | | | |
| Present | RD-2 | RHH-5 | REH-3 | 4.15 | 111 | 110 |
| Example 63 | | | | | | |
| Present | RD-2 | RHH-5 | REH-4 | 4.14 | 110 | 114 |
| Example 64 | | | | | | |
| Present | RD-2 | RHH-5 | REH-5 | 4.14 | 109 | 115 |
| Example 65 | | | | | | |
| Present | RD-2 | RHH-5 | REH-6 | 4.14 | 111 | 110 |
| Example 66 | | | | | | |
| Present | RD-2 | RHH-6 | REH-1 | 4.18 | 106 | 118 |
| Example 67 | | | | | | |
| Present | RD-2 | RHH-6 | REH-2 | 4.19 | 106 | 116 |
| Example 68 | | | | | | |
| Present | RD-2 | RHH-6 | REH-3 | 4.20 | 110 | 114 |
| Example 69 | | | | | | |
| Present | RD-2 | RHH-6 | REH-4 | 4.17 | 108 | 115 |
| Example 70 | | | | | | |
| Present | RD-2 | RHH-6 | REH-5 | 4.18 | 107 | 115 |
| Example 71 | | | | | | |
| Present | RD-2 | RHH-6 | REH-6 | 4.16 | 106 | 114 |
| Example 72 | | | | | | |

TABLE 5

| | | | | Oper- | EQE | LT95 |
|---|---|---|---|---|---|---|
| | | | | ation | (%, | (%, |
| | Light-emissive layer | | | voltage | relative | relative |
| | Dopant | Host | | (V) | value) | value) |
| Comparative | RD-3 | CBP | | 4.29 | 100 | 100 |
| Example 3 | | | | | | |
| Present | RD-3 | RHH-1 | REH-1 | 4.20 | 110 | 120 |
| Example 73 | | | | | | |
| Present | RD-3 | RHH-1 | REH-2 | 4.19 | 112 | 118 |
| Example 74 | | | | | | |
| Present | RD-3 | RHH-1 | REH-3 | 4.15 | 105 | 110 |
| Example 75 | | | | | | |
| Present | RD-3 | RHH-1 | REH-4 | 4.14 | 106 | 110 |
| Example 76 | | | | | | |
| Present | RD-3 | RHH-1 | REH-5 | 4.16 | 108 | 115 |
| Example 77 | | | | | | |
| Present | RD-3 | RHH-1 | REH-6 | 4.15 | 110 | 118 |
| Example 78 | | | | | | |
| Present | RD-3 | RHH-2 | REH-1 | 4.17 | 108 | 118 |
| Example 79 | | | | | | |
| Present | RD-3 | RHH-2 | REH-2 | 4.15 | 110 | 115 |
| Example 80 | | | | | | |
| Present | RD-3 | RHH-2 | REH-3 | 4.14 | 105 | 115 |
| Example 81 | | | | | | |
| Present | RD-3 | RHH-2 | REH-4 | 4.15 | 108 | 116 |
| Example 82 | | | | | | |
| Present | RD-3 | RHH-2 | REH-5 | 4.16 | 106 | 117 |
| Example 83 | | | | | | |
| Present | RD-3 | RHH-2 | REH-6 | 4.17 | 108 | 115 |
| Example 84 | | | | | | |
| Present | RD-3 | RHH-3 | REH-1 | 4.20 | 110 | 115 |
| Example 85 | | | | | | |
| Present | RD-3 | RHH-3 | REH-2 | 4.18 | 110 | 110 |
| Example 86 | | | | | | |
| Present | RD-3 | RHH-3 | REH-3 | 4.15 | 105 | 120 |
| Example 87 | | | | | | |
| Present | RD-3 | RHH-3 | REH-4 | 4.16 | 106 | 120 |
| Example 88 | | | | | | |
| Present | RD-3 | RHH-3 | REH-5 | 4.15 | 108 | 117 |
| Example 89 | | | | | | |
| Present | RD-3 | RHH-3 | REH-6 | 4.15 | 110 | 115 |
| Example 90 | | | | | | |

TABLE 6

| | | | | Oper- | EQE | LT95 |
|---|---|---|---|---|---|---|
| | | | | ation | (%, | (%, |
| | Light-emissive layer | | | voltage | relative | relative |
| | Dopant | Host | | (V) | value) | value) |
| Comparative | RD-3 | CBP | | 4.29 | 100 | 100 |
| Example 3 | | | | | | |
| Present | RD-3 | RHH-4 | REH-1 | 4.19 | 110 | 125 |
| Example 91 | | | | | | |
| Present | RD-3 | RHH-4 | REH-2 | 4.15 | 115 | 115 |
| Example 92 | | | | | | |
| Present | RD-3 | RHH-4 | REH-3 | 4.18 | 120 | 120 |
| Example 93 | | | | | | |
| Present | RD-3 | RHH-4 | REH-4 | 4.16 | 110 | 115 |
| Example 94 | | | | | | |
| Present | RD-3 | RHH-4 | REH-5 | 4.15 | 110 | 110 |
| Example 95 | | | | | | |
| Present | RD-3 | RHH-4 | REH-6 | 4.17 | 116 | 118 |
| Example 96 | | | | | | |
| Present | RD-3 | RHH-5 | REH-1 | 4.18 | 111 | 120 |
| Example 97 | | | | | | |
| Present | RD-3 | RHH-5 | REH-2 | 4.17 | 112 | 118 |
| Example 98 | | | | | | |
| Present | RD-3 | RHH-5 | REH-3 | 4.17 | 110 | 116 |
| Example 99 | | | | | | |
| Present | RD-3 | RHH-5 | REH-4 | 4.15 | 115 | 118 |
| Example 100 | | | | | | |
| Present | RD-3 | RHH-5 | REH-5 | 4.14 | 110 | 115 |
| Example 101 | | | | | | |
| Present | RD-3 | RHH-5 | REH-6 | 4.16 | 112 | 118 |
| Example 102 | | | | | | |
| Present | RD-3 | RHH-6 | REH-1 | 4.18 | 115 | 120 |
| Example 103 | | | | | | |
| Present | RD-3 | RHH-6 | REH-2 | 4.17 | 114 | 118 |
| Example 104 | | | | | | |
| Present | RD-3 | RHH-6 | REH-3 | 4.18 | 112 | 112 |
| Example 105 | | | | | | |
| Present | RD-3 | RHH-6 | REH-4 | 4.17 | 111 | 114 |
| Example 106 | | | | | | |
| Present | RD-3 | RHH-6 | REH-5 | 4.16 | 113 | 115 |
| Example 107 | | | | | | |
| Present | RD-3 | RHH-6 | REH-6 | 4.15 | 110 | 116 |
| Example 108 | | | | | | |

TABLE 7

| | | | | Oper- | EQE | LT95 |
|---|---|---|---|---|---|---|
| | | | | ation | (%, | (%, |
| | Light-emissive layer | | | voltage | relative | relative |
| | Dopant | Host | | (V) | value) | value) |
| Comparative | RD-4 | CBP | | 4.28 | 100 | 100 |
| Example 4 | | | | | | |
| Present | RD-4 | RHH-1 | REH-1 | 4.18 | 109 | 119 |
| Example 109 | | | | | | |
| Present | RD-4 | RHH-1 | REH-2 | 4.15 | 111 | 117 |
| Example 110 | | | | | | |
| Present | RD-4 | RHH-1 | REH-3 | 4.18 | 106 | 111 |
| Example 111 | | | | | | |
| Present | RD-4 | RHH-1 | REH-4 | 4.15 | 105 | 111 |
| Example 112 | | | | | | |
| Present | RD-4 | RHH-1 | REH-5 | 4.15 | 107 | 114 |
| Example 113 | | | | | | |
| Present | RD-4 | RHH-1 | REH-6 | 4.18 | 109 | 117 |
| Example 114 | | | | | | |
| Present | RD-4 | RHH-2 | REH-1 | 4.20 | 107 | 116 |
| Example 115 | | | | | | |
| Present | RD-4 | RHH-2 | REH-2 | 4.18 | 109 | 113 |
| Example 116 | | | | | | |
| Present | RD-4 | RHH-2 | REH-3 | 4.17 | 107 | 114 |
| Example 117 | | | | | | |
| Present | RD-4 | RHH-2 | REH-4 | 4.18 | 108 | 115 |
| Example 118 | | | | | | |
| Present | RD-4 | RHH-2 | REH-5 | 4.19 | 107 | 115 |
| Example 119 | | | | | | |
| Present | RD-4 | RHH-2 | REH-6 | 4.20 | 107 | 113 |
| Example 120 | | | | | | |
| Present | RD-4 | RHH-3 | REH-1 | 4.19 | 109 | 114 |
| Example 121 | | | | | | |
| Present | RD-4 | RHH-3 | REH-2 | 4.17 | 109 | 111 |
| Example 122 | | | | | | |
| Present | RD-4 | RHH-3 | REH-3 | 4.14 | 106 | 118 |
| Example 123 | | | | | | |
| Present | RD-4 | RHH-3 | REH-4 | 4.15 | 105 | 115 |
| Example 124 | | | | | | |
| Present | RD-4 | RHH-3 | REH-5 | 4.16 | 107 | 118 |
| Example 125 | | | | | | |
| Present | RD-4 | RHH-3 | REH-6 | 4.15 | 109 | 116 |
| Example 126 | | | | | | |

TABLE 8

| | | | | Oper- | EQE | LT95 |
|---|---|---|---|---|---|---|
| | | | | ation | (%, | (%, |
| | Light-emissive layer | | | voltage | relative | relative |
| | Dopant | Host | | (V) | value) | value) |
| Comparative | RD-4 | CBP | | 4.28 | 100 | 100 |
| Example 4 | | | | | | |
| Present | RD-4 | RHH-4 | REH-1 | 4.18 | 111 | 115 |
| Example 127 | | | | | | |
| Present | RD-4 | RHH-4 | REH-2 | 4.16 | 113 | 114 |
| Example 128 | | | | | | |
| Present | RD-4 | RHH-4 | REH-3 | 4.17 | 118 | 113 |
| Example 129 | | | | | | |
| Present | RD-4 | RHH-4 | REH-4 | 4.15 | 112 | 112 |
| Example 130 | | | | | | |
| Present | RD-4 | RHH-4 | REH-5 | 4.16 | 113 | 113 |
| Example 131 | | | | | | |
| Present | RD-4 | RHH-4 | REH-6 | 4.16 | 115 | 114 |
| Example 132 | | | | | | |
| Present | RD-4 | RHH-5 | REH-1 | 4.19 | 110 | 115 |
| Example 133 | | | | | | |
| Present | RD-4 | RHH-5 | REH-2 | 4.18 | 111 | 114 |
| Example 134 | | | | | | |
| Present | RD-4 | RHH-5 | REH-3 | 4.18 | 109 | 116 |
| Example 135 | | | | | | |
| Present | RD-4 | RHH-5 | REH-4 | 4.16 | 113 | 115 |
| Example 136 | | | | | | |
| Present | RD-4 | RHH-5 | REH-5 | 4.15 | 111 | 113 |
| Example 137 | | | | | | |
| Present | RD-4 | RHH-5 | REH-6 | 4.17 | 111 | 116 |
| Example 138 | | | | | | |
| Present | RD-4 | RHH-6 | REH-1 | 4.19 | 114 | 116 |
| Example 139 | | | | | | |
| Present | RD-4 | RHH-6 | REH-2 | 4.18 | 113 | 113 |
| Example 140 | | | | | | |
| Present | RD-4 | RHH-6 | REH-3 | 4.17 | 113 | 112 |
| Example 141 | | | | | | |
| Present | RD-4 | RHH-6 | REH-4 | 4.18 | 112 | 113 |
| Example 142 | | | | | | |
| Present | RD-4 | RHH-6 | REH-5 | 4.17 | 112 | 111 |
| Example 143 | | | | | | |
| Present | RD-4 | RHH-6 | REH-6 | 4.16 | 111 | 114 |
| Example 144 | | | | | | |

The results in Table 1 to Table 8 show that the organic light-emitting diode of each of Present Examples 1 to 144 in which the organometallic compound satisfying the structure represented by the Chemical Formula 1 of the present disclosure is used as the dopant in the light-emissive layer, and a mixture of the compound represented by the Chemical Formula 2 and the compound represented by the Chemical Formula 3 is used as the host in the light-emissive layer has lowered operation voltage, and improved external quantum efficiency (EQE) and lifetime (LT95), compared to the organic light-emitting diode of each of Comparative Examples 1 to 4 in which a single material is used as the host of the light-emissive layer.

Example embodiments of the present disclosure can also be described as follows:

An organic light-emitting device according to an example embodiment of the present disclosure may include: a first electrode; a second electrode facing the first electrode; and an organic layer disposed between the first electrode and the second electrode, the organic layer including a light-emissive layer that includes: a dopant material including an organometallic compound represented by Chemical Formula 1; and a host material including a compound represented by Chemical Formula 2 and a compound represented by Chemical Formula 3:

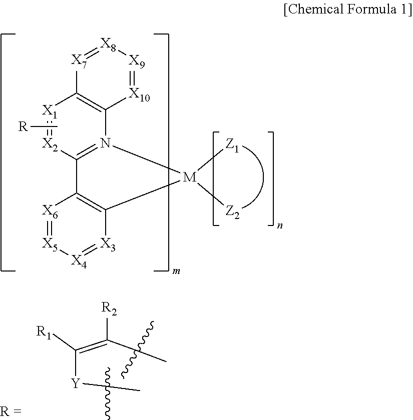

wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
in R, each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C3-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO, and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ may be optionally fused with each other to form a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,

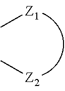

represents a bidentate ligand,
m is an integer of 1, 2 or 3, n is an integer of 0, 1 or 2, and m+n is an oxidation number of the metal (M),

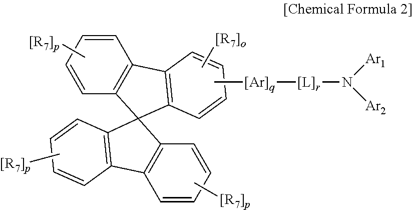

wherein in the Chemical Formula 2,
Ar independently represents a substituted or unsubstituted aromatic ring group selected from the group consisting of benzene, naphthalene, phenanthrene, fluorene, spirobifluorene, dibenzofuran and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, a linker L represents one selected from the group consisting of a substituted or unsubstituted C6-C30 arylene group, a substituted or unsubstituted C3-C30 heteroarylene group, and a substituted or unsubstituted C7-C20 arylalkylene group,

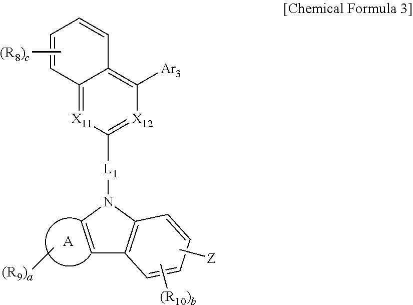

wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ may be optionally substituted with at least one of deuterium and a halogen atom,
Z represents one selected from the group consisting of the following structures:

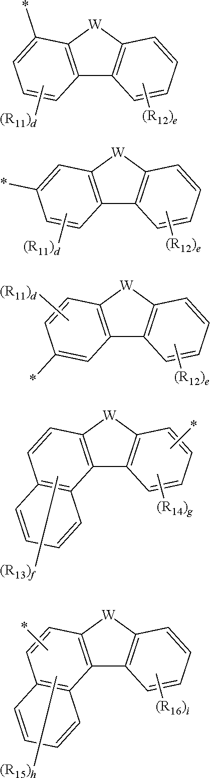

W represents one selected from the group consisting of O, S, NR₁₇, CR₁₇R₁₈ and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

In some embodiments of the present disclosure, in the Chemical Formula 1, n may be 2.

In some embodiments of the present disclosure, Y in the Chemical Formula 1 may represent one selected from the group consisting of O, S and CR₃R₄.

In some embodiments of the present disclosure, the organometallic compound represented by the Chemical Formula 1 may include at least one selected from the group consisting of compound RD-1 to compound RD-20.

In some embodiments of the present disclosure, in the Chemical Formula 2, each of Ar₁ and Ar₂ may independently represent one selected from the group consisting of benzene, naphthalene, phenanthrene, fluorene, dibenzofuran, dibenzothiophene, and spirobifluorene, and at least one hydrogen of each of Ar₁ and Ar₂ may be optionally substituted with one or more selected from the group consisting of deuterium, a halogen atom, a C1-C10 alkyl group, a cyano group, and a silyl group.

In some embodiments of the present disclosure, the compound represented by the Chemical Formula 2 may include at least one selected from the group consisting of compound RHH-1 to compound RHH-20.

In some embodiments of the present disclosure, in the Chemical Formula 3, each of X₁₁ and X₁₂ may represent N.

In some embodiments of the present disclosure, the compound represented by the Chemical Formula 3 may include at least one selected from the group consisting of compound REH-1 to compound REH-20.

In some embodiments of the present disclosure, the organic layer may further include at least one selected from the group consisting of a hole injection layer, a hole transport layer, an electron transport layer, and an electron injection layer.

An organic light-emitting device according to an example embodiment of the present disclosure may include: a first electrode; a second electrode facing the first electrode; a first light-emitting stack; and a second light-emitting stack, wherein the first and second light-emitting stacks are disposed between the first electrode and the second electrode, wherein each of the first light-emitting stack and the second light-emitting stack includes at least one light-emissive layer including a red phosphorescent light-emissive layer that includes: a dopant material including an organometallic compound represented by Chemical Formula 1; and a host material including a compound represented by Chemical Formula 2 and a compound represented by Chemical Formula 3:

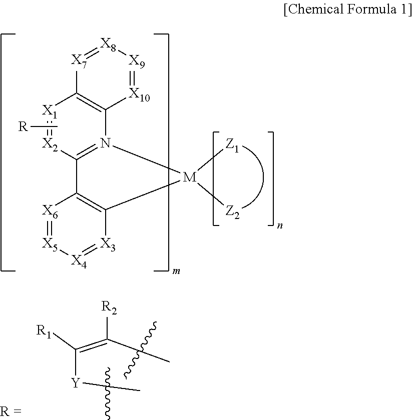

wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
in R, each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C3-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO, and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ are optionally fused with each other to form a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,

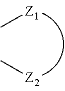

represents a bidentate ligand,
m is an integer of 1, 2 or 3, n is an integer of 0, 1 or 2, and m+n is an oxidation number of the metal (M),

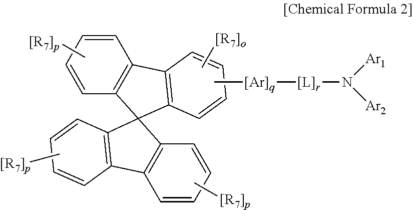

wherein in the Chemical Formula 2,
Ar independently represents a substituted or unsubstituted aromatic ring group selected from the group consisting of benzene, naphthalene, phenanthrene, fluorene, spirobifluorene, dibenzofuran, and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, a linker L represents one selected from the group consisting of a substituted or unsubstituted C6-C30 arylene group, a substituted or unsubstituted C3-C30 heteroarylene group, and a substituted or unsubstituted C7-C20 arylalkylene group,

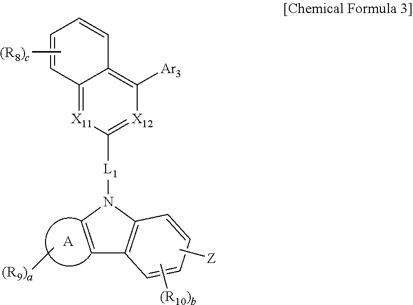

wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ is optionally substituted with at least one of deuterium and a halogen atom,
Z represents one selected from the group consisting of the following structures:

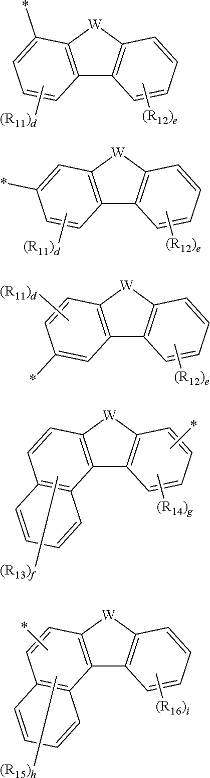

W represents one selected from the group consisting of O, S, NR₁₇, CR₁₇R₁₈ and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

In some embodiments of the present disclosure, the organometallic compound represented by the Chemical Formula 1 may include at least one selected from the group consisting of compound RD-1 to compound RD-20.

In some embodiments of the present disclosure, the compound represented by the Chemical Formula 2 may include at least one selected from the group consisting of compound RHH-1 to compound RHH-20.

In some embodiments of the present disclosure, the compound represented by the Chemical Formula 3 may include at least one selected from the group consisting of compound REH-1 to compound REH-20.

An organic light-emitting device according to an example embodiment of the present disclosure may include a first electrode; a second electrode facing the first electrode; a first light-emitting stack; a second light-emitting stack; and a third light-emitting stack, wherein the first, second, and third light-emitting stacks are disposed between the first electrode and the second electrode, wherein each of the first light-emitting stack, the second light-emitting stack, and the third light-emitting stack includes at least one red phosphorescent light-emissive layer that includes: a dopant material including an organometallic compound represented by Chemical Formula 1; and a host material including a compound represented by Chemical Formula 2 and a compound represented by Chemical Formula 3:

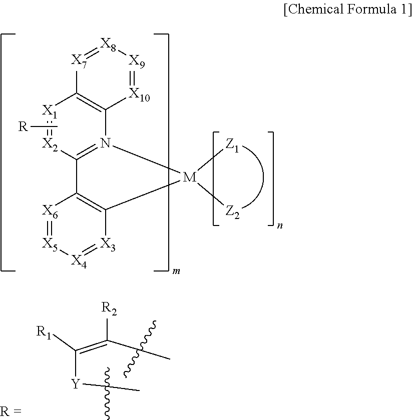

wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C3-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO, and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ optionally fused with each other to form a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,

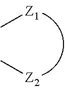

represents a bidentate ligand,
m is an integer of 1, 2 or 3, n is an integer of 0, 1 or 2, and m+n is an oxidation number of the metal (M),

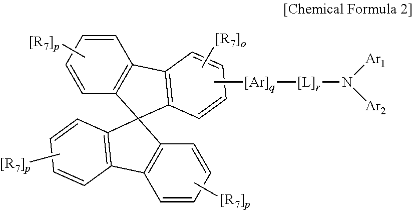

wherein in the Chemical Formula 2,
Ar independently represents a substituted or unsubstituted aromatic ring group selected from the group consisting of benzene, naphthalene, phenanthrene, fluorene, spirobifluorene, dibenzofuran, and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, a linker L represents one selected from the group consisting of a substituted or unsubstituted C6-C30 arylene group, a substituted or unsubstituted C3-C30 heteroarylene group, and a substituted or unsubstituted C7-C20 arylalkylene group,

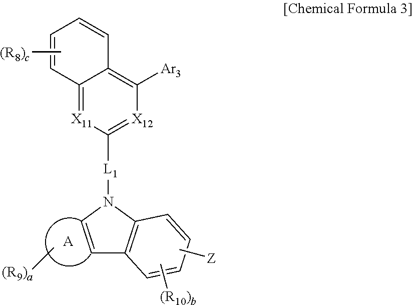

wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ is optionally substituted with at least one of deuterium and a halogen atom
Z represents one selected from the group consisting of following structures:

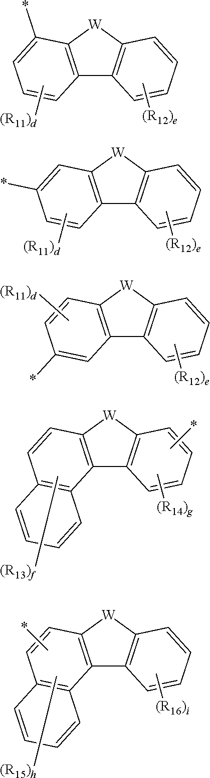

W represents one selected from the group consisting of O, S, NR₁₇, CR₁₇R₁₈ and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

In some embodiments of the present disclosure, the organometallic compound represented by the Chemical Formula 1 may include at least one selected from the group consisting of following compound RD-1 to compound RD-20.

In some embodiments of the present disclosure, the compound represented by the Chemical Formula 2 may include at least one selected from the group consisting of following compound RHH-1 to compound RHH-20.

In some embodiments of the present disclosure, the compound represented by the Chemical Formula 3 may include at least one selected from the group consisting of following compound REH-1 to compound REH-20.

An organic light-emitting display device according to an example embodiment of the present disclosure may include: a substrate; a driving element disposed on the substrate; and an organic light-emitting diode disposed on the substrate and connected to the driving element, wherein the organic light-emitting diode may include the organic light-emitting device according to any of the example embodiments of the present disclosure.

Although example embodiments of the present disclosure have been described in detail with reference to the accompanying drawings, the present disclosure is not limited thereto and may be embodied in many different forms without departing from the technical concept of the present disclosure. Therefore, example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

It will be apparent to those skilled in the art that various modifications and variations can be made in the present disclosure without departing from the technical idea or scope of the disclosure. Thus, it is intended that embodiments of the present disclosure cover the modifications and variations of the disclosure provided they come within the scope of the appended claims and their equivalents.

1. An organic light-emitting device comprising:
a first electrode;
a second electrode facing the first electrode; and
an organic layer disposed between the first electrode and the second electrode, the organic layer including a light-emissive layer that includes:
a dopant material including an organometallic compound represented by Chemical Formula 1; and
a host material including a compound represented by Chemical Formula 2 and a compound represented by Chemical Formula 3: 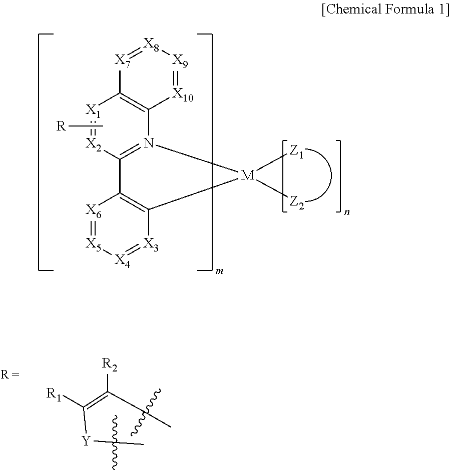
wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
in R, each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C3-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO, and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ are optionally fused with each other to form a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group, 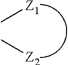
represents a bidentate ligand,
m is an integer of 1, 2 or 3, n is an integer of 0, 1 or 2, and m+n is an oxidation number of the metal (M), 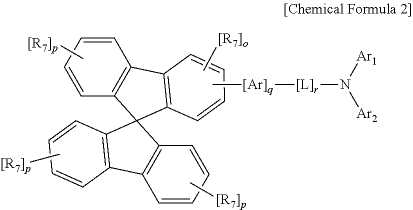
wherein in the Chemical Formula 2,
Ar independently represents a substituted or unsubstituted aromatic ring group selected from the group consisting of benzene, naphthalene, phenanthrene, fluorene, spirobifluorene, dibenzofuran, and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, a linker L represents one selected from the group consisting of a substituted or unsubstituted C6-C30 arylene group, a substituted or unsubstituted C3-C30 heteroarylene group, and a substituted or unsubstituted C7-C20 arylalkylene group, 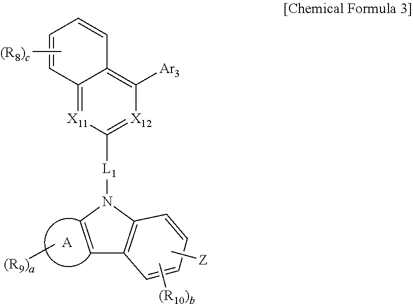
wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ is optionally substituted with at least one of deuterium and a halogen atom,
Z represents one selected from the group consisting of the following structures: 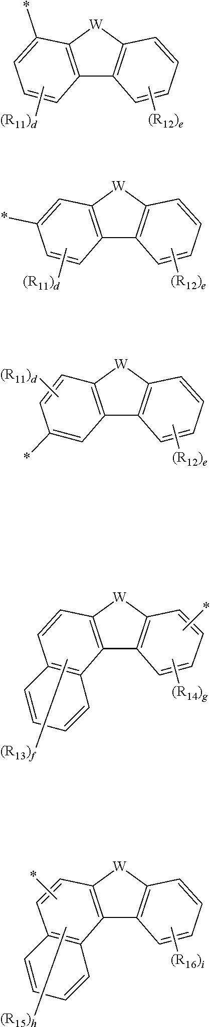
W represents one selected from the group consisting of O, S, NR₁₇, CR₁₇R₁₈ and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

2. The organic light-emitting device of claim 1, wherein in the Chemical Formula 1, n is 2.

3. The organic light-emitting device of claim 1, wherein Y in the Chemical Formula 1 represents one selected from the group consisting of O, S and CR₃R₄.

4. The organic light-emitting device of claim 1, wherein the organometallic compound represented by the Chemical Formula 1 includes at least one selected from the group consisting of compound RD-1 to compound RD-20:

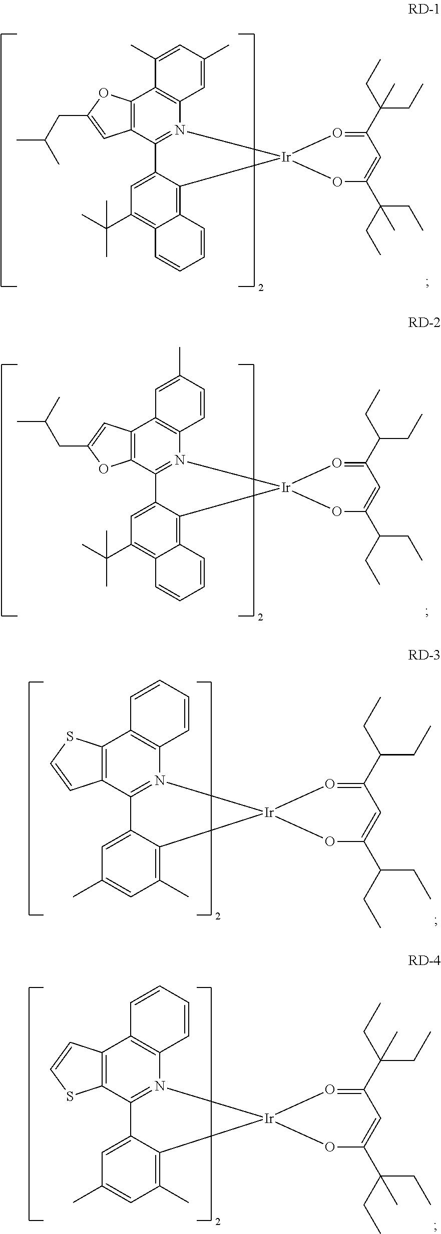

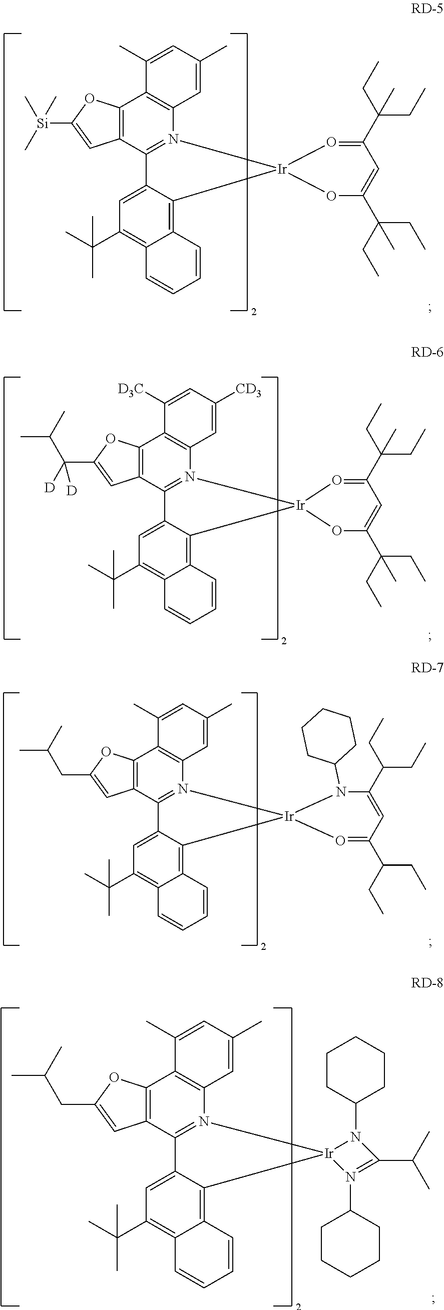

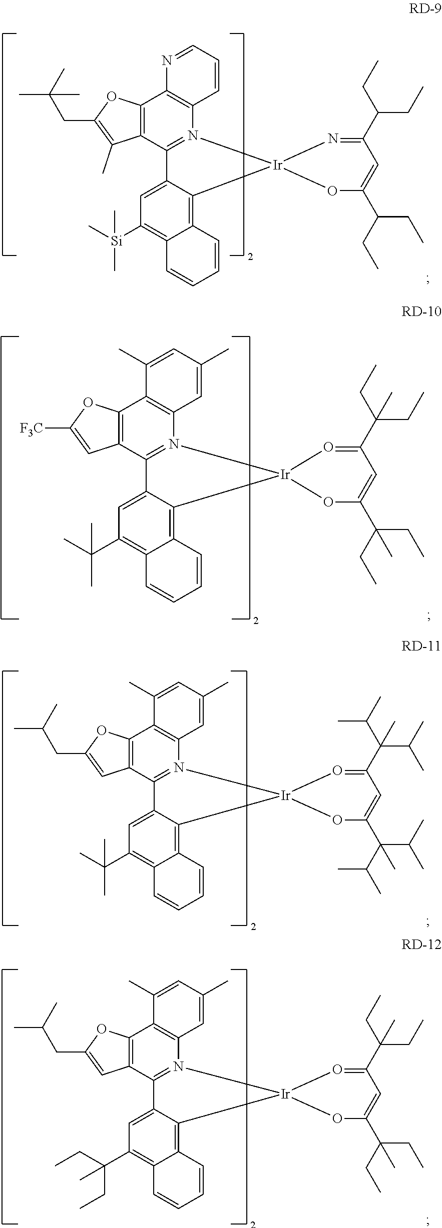

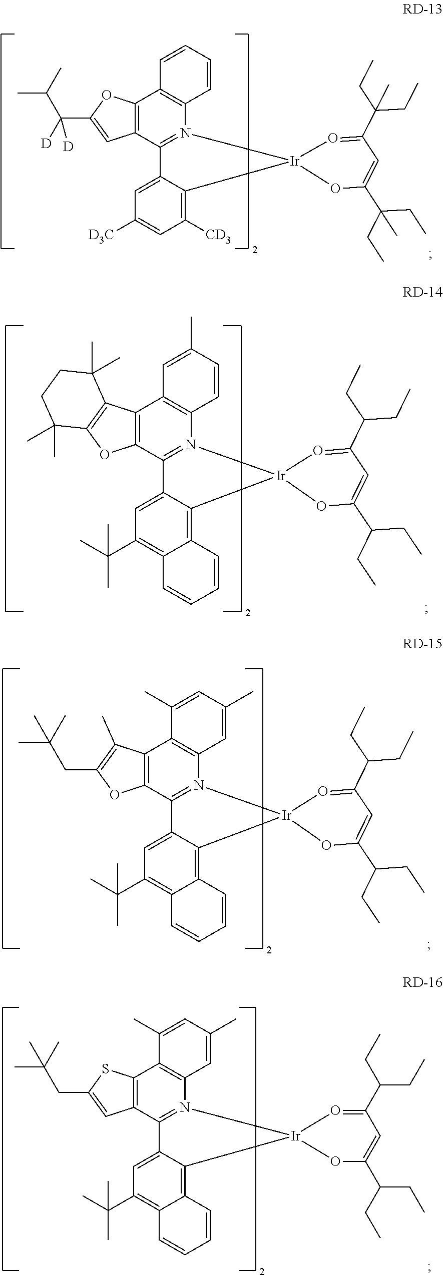

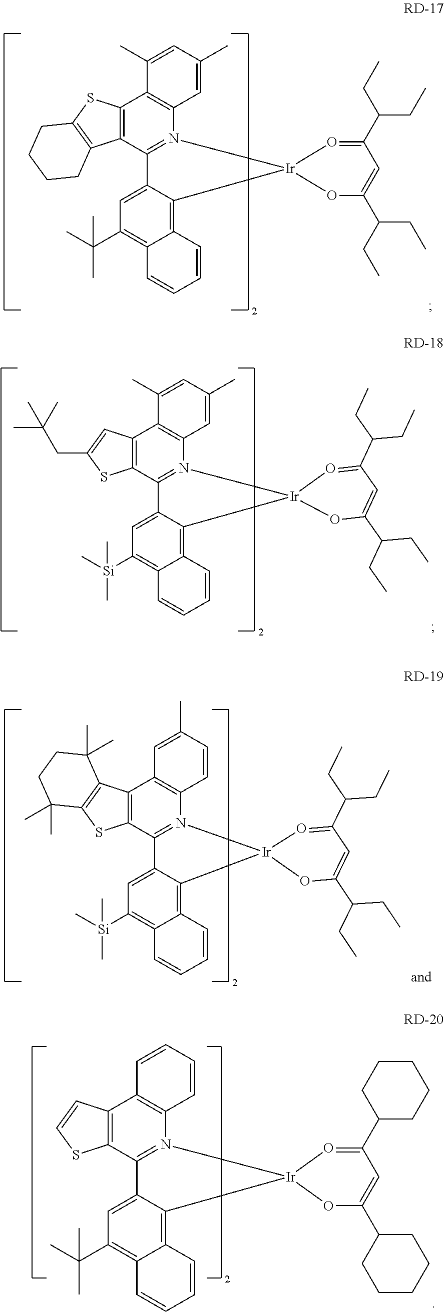

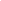

5. The organic light-emitting device of claim 1, wherein in the Chemical Formula 2, each of Ar₁ and Ar₂ independently represents one selected from the group consisting of benzene, naphthalene, phenanthrene, fluorene, dibenzofuran, dibenzothiophene, and spirobifluorene, and
wherein at least one hydrogen of each of Ar₁ and Ar₂ is optionally substituted with one or more selected from the group consisting of deuterium, a halogen atom, a C1-C10 alkyl group, a cyano group, and a silyl group.

6. The organic light-emitting device of claim 1, wherein the compound represented by the Chemical Formula 2 includes at least one selected from the group consisting of compound RHH-1 to compound RHH-20:

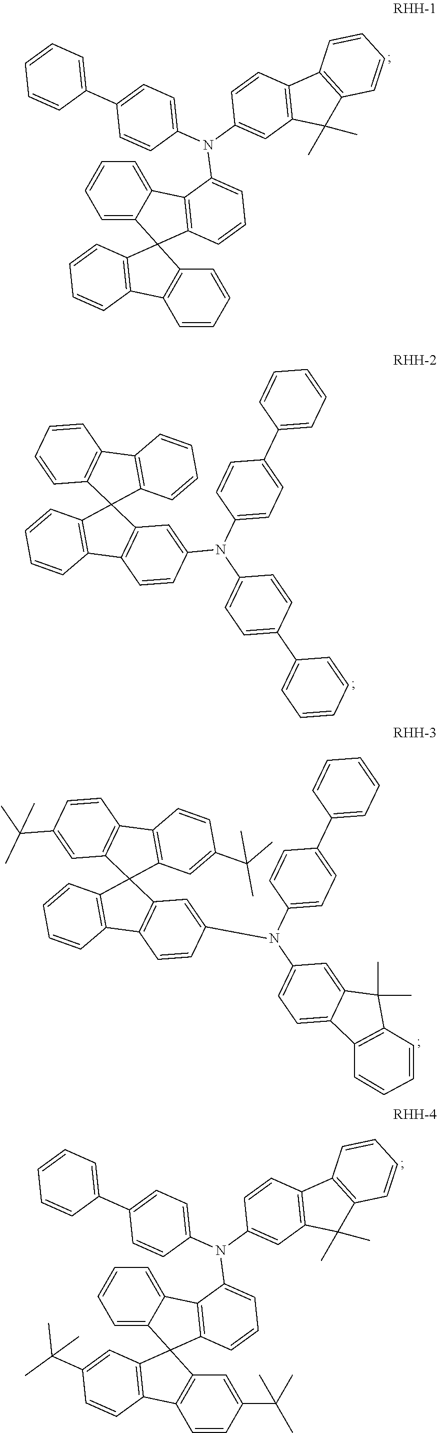

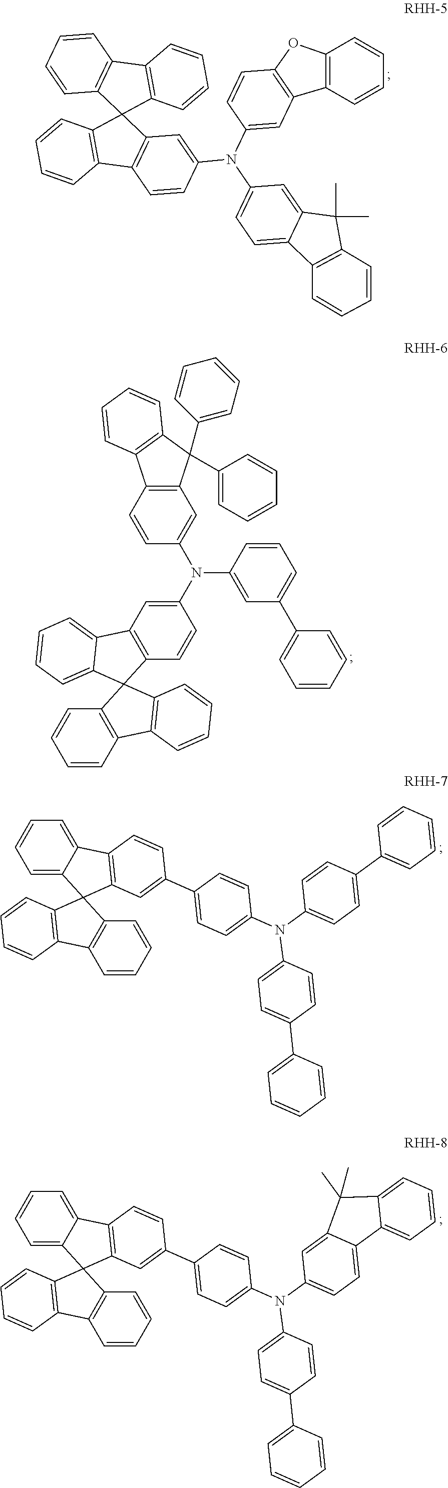 [SMILES: CC1(C)c2ccccc2-c2ccc(N(c3ccc4c(c3)C3(c5ccccc5-c5ccccc53)c3ccccc3-4)c3ccc4oc5ccccc5c4c3)cc21 ; c1ccc(-c2cccc(N(c3ccc4c(c3)-c3ccccc3C43c4ccccc4-c4ccccc43)c3ccc4c(c3)C(c3ccccc3)(c3ccccc3)c3ccccc3-4)c2)cc1 ; c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

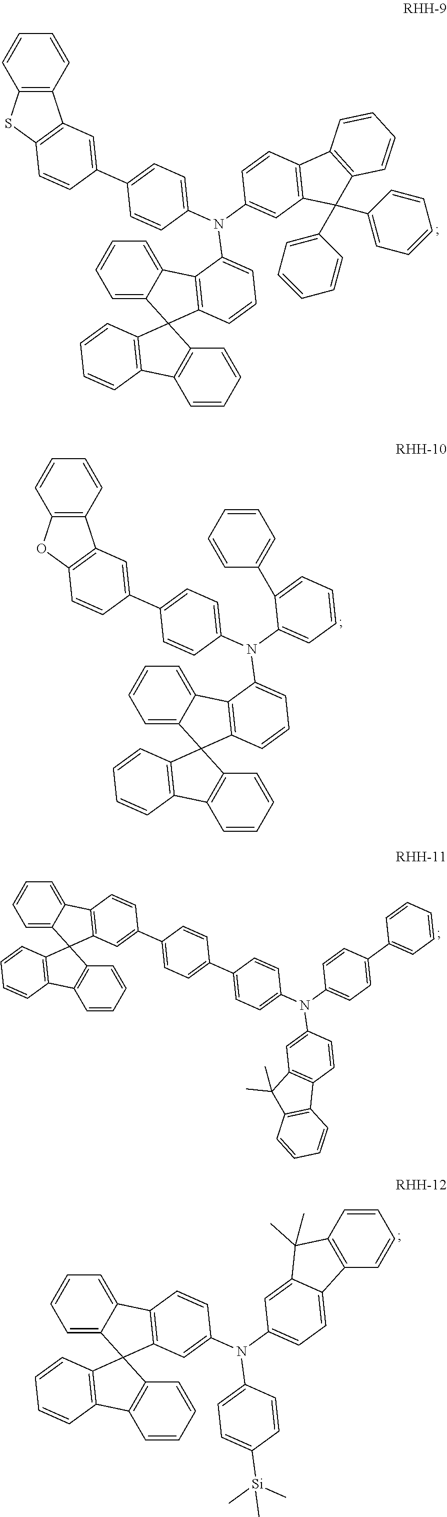 [SMILES: c1ccc(C2(c3ccccc3)c3ccccc3-c3ccc(N(c4ccc(-c5ccc6sc7ccccc7c6c5)cc4)c4cccc5c4-c4ccccc4C54c5ccccc5-c5ccccc54)cc32)cc1 ; c1ccc(-c2ccccc2N(c2ccc(-c3ccc4oc5ccccc5c4c3)cc2)c2cccc3c2-c2ccccc2C32c3ccccc3-c3ccccc32)cc1 ; CC1(C)c2ccccc2-c2ccc(N(c3ccc(-c4ccccc4)cc3)c3ccc(-c4ccc(-c5ccc6c(c5)C5(c7ccccc7-c7ccccc75)c5ccccc5-6)cc4)cc3)cc21 ; CC1(C)c2ccccc2-c2ccc(N(c3ccc([Si](C)(C)C)cc3)c3ccc4c(c3)C3(c5ccccc5-c5ccccc53)c3ccccc3-4)cc21]

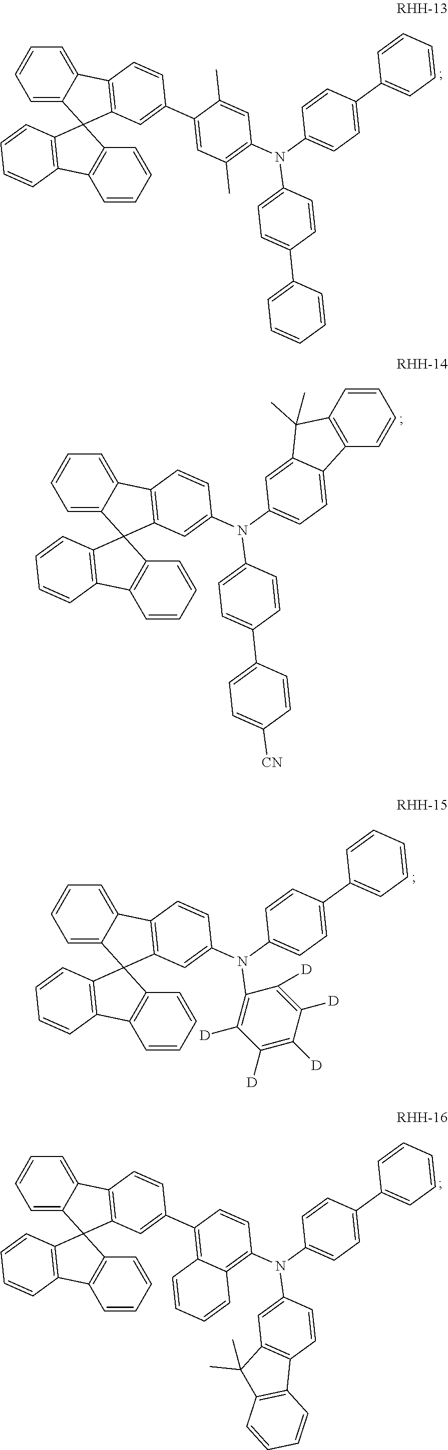 [SMILES: Cc1cc(N(c2ccc(-c3ccccc3)cc2)c2ccc(-c3ccccc3)cc2)c(C)cc1-c1ccc2c(c1)C1(c3ccccc3-c3ccccc31)c1ccccc1-2 ; CC1(C)c2ccccc2-c2ccc(N(c3ccc(-c4ccc(C#N)cc4)cc3)c3ccc4c(c3)C3(c5ccccc5-c5ccccc53)c3ccccc3-4)cc21 ; [2H]c1c([2H])c([2H])c(N(c2ccc(-c3ccccc3)cc2)c2ccc3c(c2)C2(c4ccccc4-c4ccccc42)c2ccccc2-3)c([2H])c1[2H] ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)c4ccccc34)cc21]

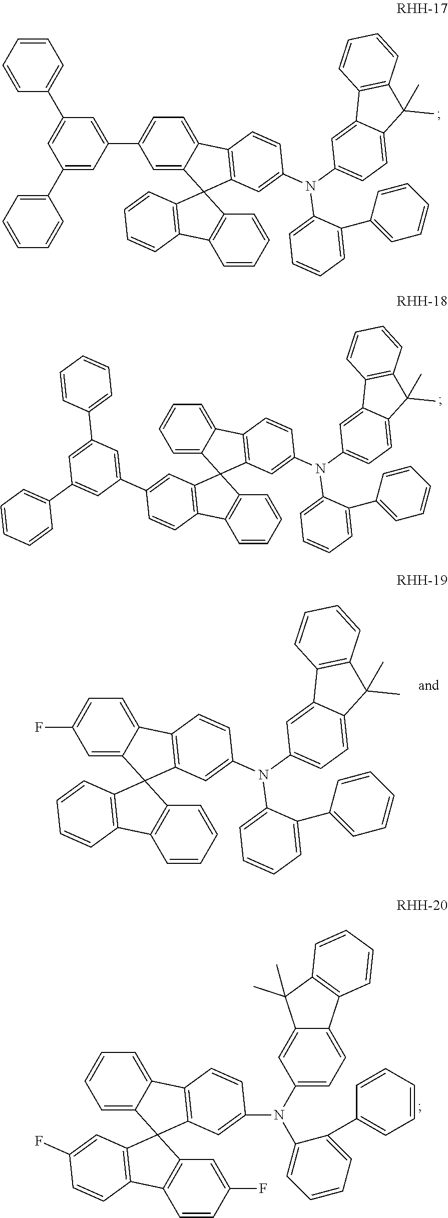 [SMILES: CC1(C)c2ccccc2-c2cc(N(c3ccc4c(c3)C3(c5ccccc5-c5ccccc53)c3cc(-c5cc(-c6ccccc6)cc(-c6ccccc6)c5)ccc3-4)c3ccccc3-c3ccccc3)ccc21 ; CC1(C)c2ccccc2-c2cc(N(c3ccc4c(c3)C3(c5ccccc5-c5ccc(-c6cc(-c7ccccc7)cc(-c7ccccc7)c6)cc53)c3ccccc3-4)c3ccccc3-c3ccccc3)ccc21 ; CC1(C)c2ccccc2-c2cc(N(c3ccc4c(c3)C3(c5ccccc5-c5ccccc53)c3cc(F)ccc3-4)c3ccccc3-c3ccccc3)ccc21 ; CC1(C)c2ccccc2-c2ccc(N(c3ccc4c(c3)C3(c5ccccc5-4)c4cc(F)ccc4-c4ccc(F)cc43)c3ccccc3-c3ccccc3)cc21]

7. The organic light-emitting device of claim 1, wherein in the Chemical Formula 3, each of X₁₁ and X₁₂ represents N.

8. The organic light-emitting device of claim 1, wherein the compound represented by the Chemical Formula 3 includes at least one selected from the group consisting of following compound REH-1 to compound REH-20:

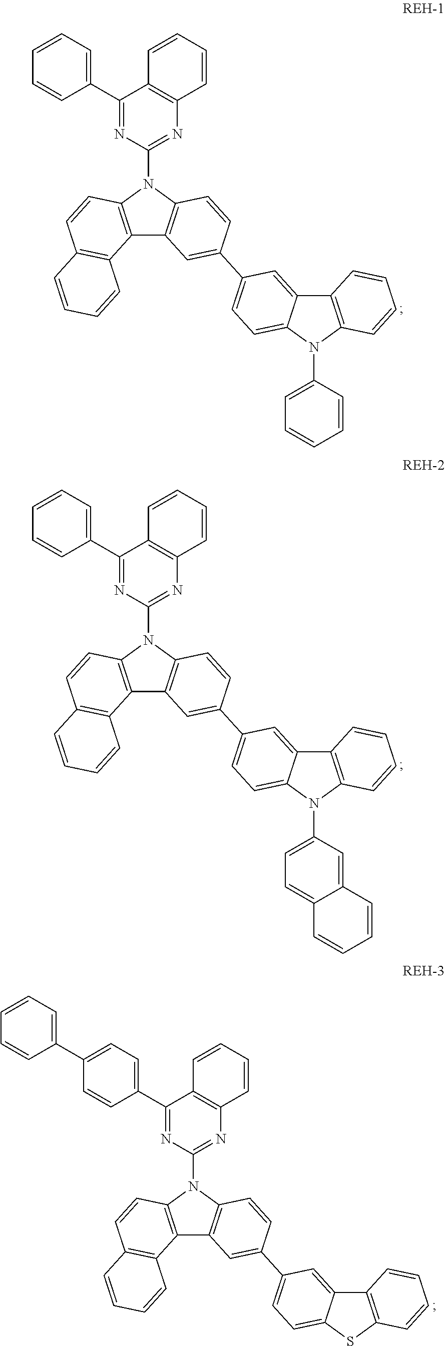 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2nc(-n3c4ccc(-c5ccc6c(c5)c5ccccc5n6-c5ccc6ccccc6c5)cc4c4c5ccccc5ccc43)nc3ccccc23)cc1 ; c1ccc(-c2ccc(-c3nc(-n4c5ccc(-c6ccc7sc8ccccc8c7c6)cc5c5c6ccccc6ccc54)nc4ccccc34)cc2)cc1]

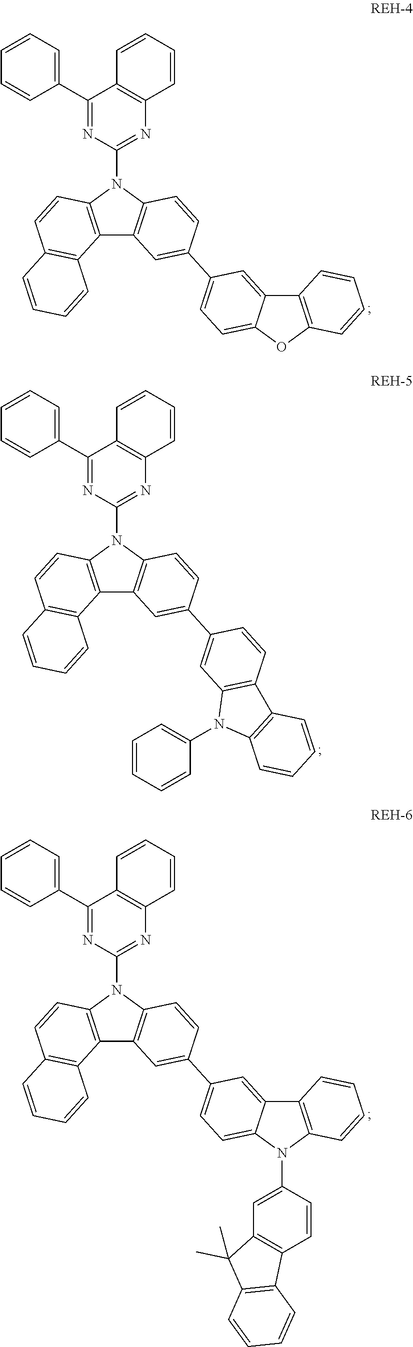 [SMILES: c1ccc(-c2nc(-n3c4ccc(-c5ccc6oc7ccccc7c6c5)cc4c4c5ccccc5ccc43)nc3ccccc23)cc1 ; c1ccc(-c2nc(-n3c4ccc(-c5ccc6c7ccccc7n(-c7ccccc7)c6c5)cc4c4c5ccccc5ccc43)nc3ccccc23)cc1 ; CC1(C)c2ccccc2-c2ccc(-n3c4ccccc4c4cc(-c5ccc6c(c5)c5c7ccccc7ccc5n6-c5nc(-c6ccccc6)c6ccccc6n5)ccc43)cc21]

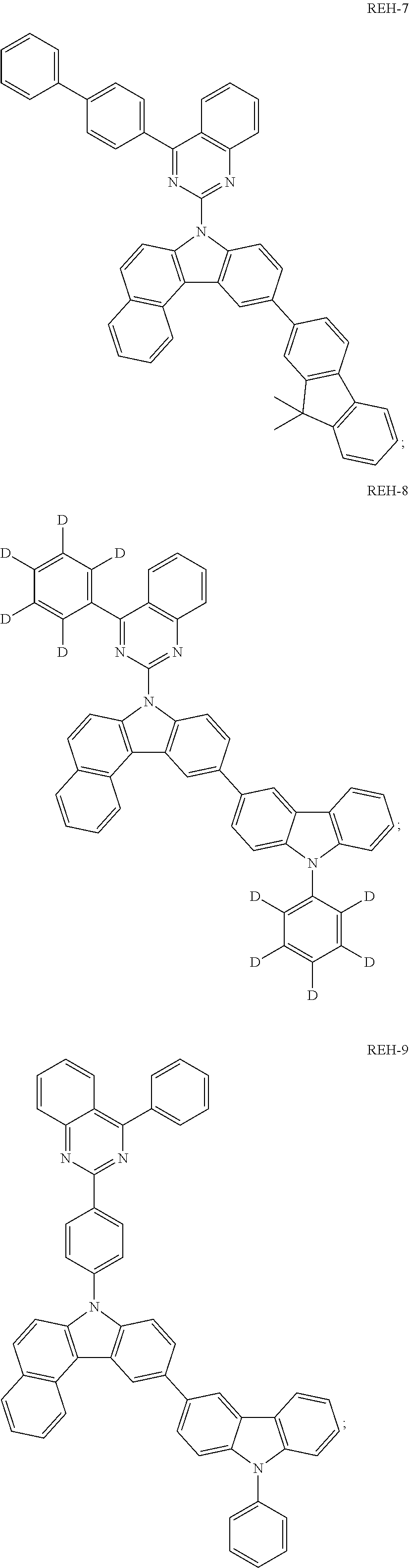 [SMILES: CC1(C)c2ccccc2-c2ccc(-c3ccc4c(c3)c3c5ccccc5ccc3n4-c3nc(-c4ccc(-c5ccccc5)cc4)c4ccccc4n3)cc21 ; [2H]c1c([2H])c([2H])c(-c2nc(-n3c4ccc(-c5ccc6c(c5)c5ccccc5n6-c5c([2H])c([2H])c([2H])c([2H])c5[2H])cc4c4c5ccccc5ccc43)nc3ccccc23)c([2H])c1[2H] ; c1ccc(-c2nc(-c3ccc(-n4c5ccc(-c6ccc7c(c6)c6ccccc6n7-c6ccccc6)cc5c5c6ccccc6ccc54)cc3)nc3ccccc23)cc1]

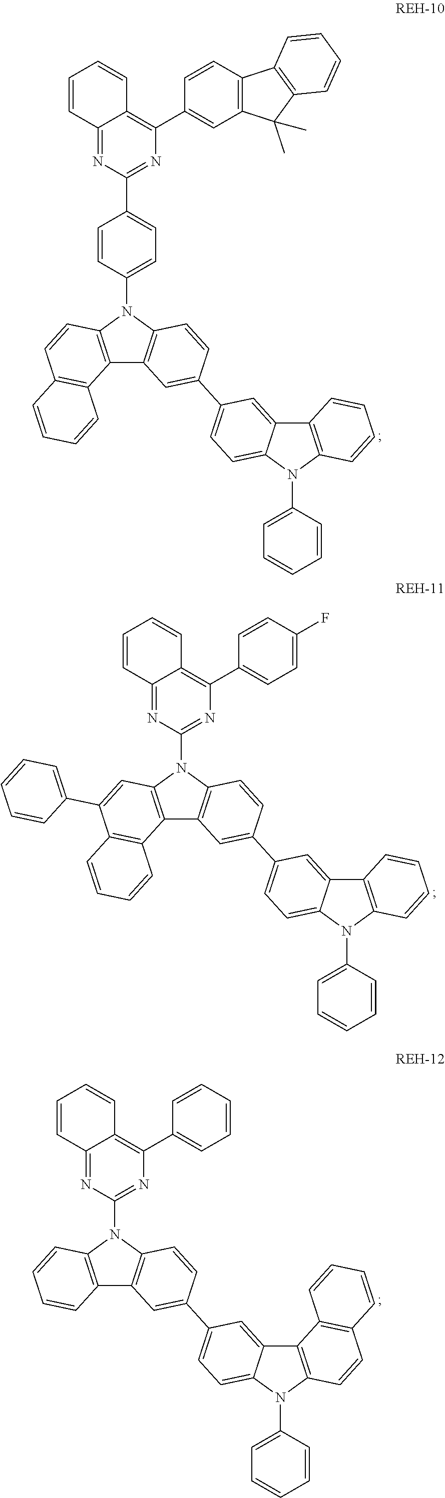 [SMILES: CC1(C)c2ccccc2-c2ccc(-c3nc(-c4ccc(-n5c6ccc(-c7ccc8c(c7)c7ccccc7n8-c7ccccc7)cc6c6c7ccccc7ccc65)cc4)nc4ccccc34)cc21 ; Fc1ccc(-c2nc(-n3c4ccc(-c5ccc6c(c5)c5ccccc5n6-c5ccccc5)cc4c4c5ccccc5c(-c5ccccc5)cc43)nc3ccccc23)cc1 ; c1ccc(-c2nc(-n3c4ccccc4c4cc(-c5ccc6c(c5)c5c7ccccc7ccc5n6-c5ccccc5)ccc43)nc3ccccc23)cc1]

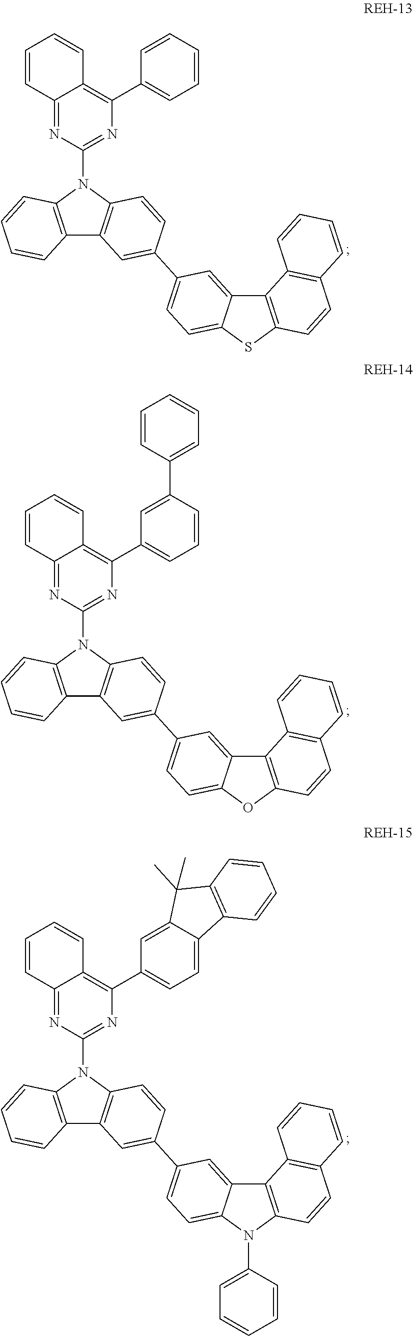 [SMILES: c1ccc(-c2nc(-n3c4ccccc4c4cc(-c5ccc6sc7ccc8ccccc8c7c6c5)ccc43)nc3ccccc23)cc1 ; c1ccc(-c2cccc(-c3nc(-n4c5ccccc5c5cc(-c6ccc7oc8ccc9ccccc9c8c7c6)ccc54)nc4ccccc34)c2)cc1 ; CC1(C)c2ccccc2-c2ccc(-c3nc(-n4c5ccccc5c5cc(-c6ccc7c(c6)c6c8ccccc8ccc6n7-c6ccccc6)ccc54)nc4ccccc34)cc21]

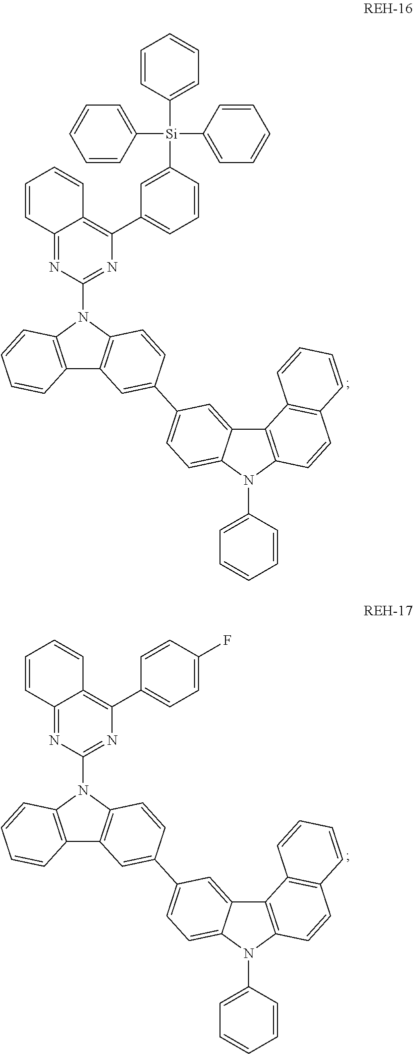 [SMILES: c1ccc(-n2c3ccc(-c4ccc5c(c4)c4ccccc4n5-c4nc(-c5cccc([Si](c6ccccc6)(c6ccccc6)c6ccccc6)c5)c5ccccc5n4)cc3c3c4ccccc4ccc32)cc1 ; Fc1ccc(-c2nc(-n3c4ccccc4c4cc(-c5ccc6c(c5)c5c7ccccc7ccc5n6-c5ccccc5)ccc43)nc3ccccc23)cc1]

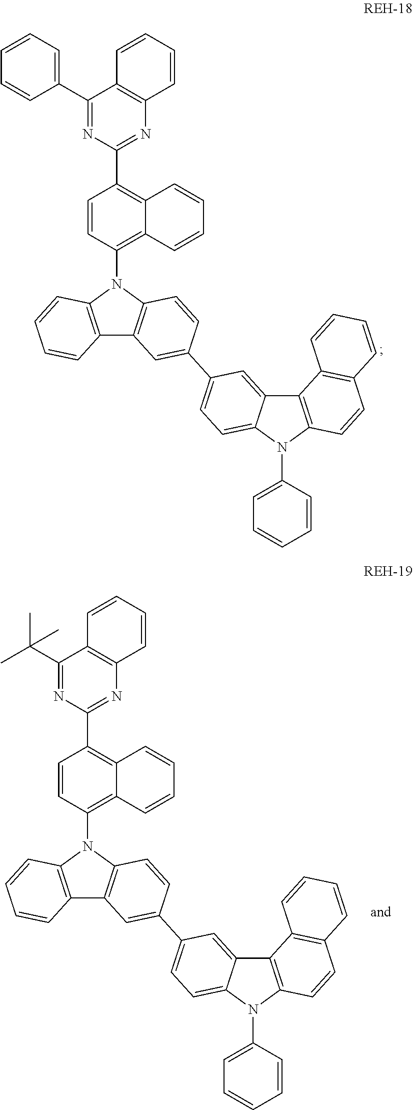 [SMILES: c1ccc(-c2nc(-c3ccc(-n4c5ccccc5c5cc(-c6ccc7c(c6)c6c8ccccc8ccc6n7-c6ccccc6)ccc54)c4ccccc34)nc3ccccc23)cc1 ; CC(C)(C)c1nc(-c2ccc(-n3c4ccccc4c4cc(-c5ccc6c(c5)c5c7ccccc7ccc5n6-c5ccccc5)ccc43)c3ccccc23)nc2ccccc12]

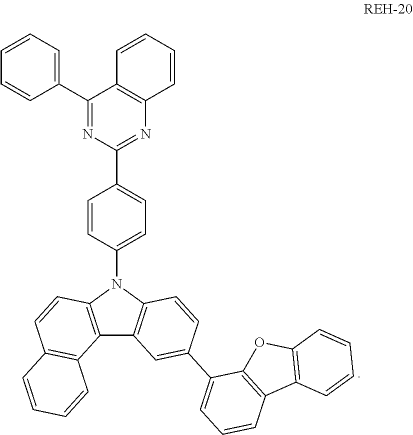 [SMILES: c1ccc(-c2nc(-c3ccc(-n4c5ccc(-c6cccc7c6oc6ccccc67)cc5c5c6ccccc6ccc54)cc3)nc3ccccc23)cc1]

9. The organic light-emitting device of claim 1, wherein the organic layer further includes at least one selected from the group consisting of a hole injection layer, a hole transport layer, an electron transport layer, and an electron injection layer.

10. An organic light-emitting device comprising:
a first electrode;
a second electrode facing the first electrode;
a first light-emitting stack; and
a second light-emitting stack,
wherein the first and second light-emitting stacks are disposed between the first electrode and the second electrode,
wherein each of the first light-emitting stack and the second light-emitting stack includes at least one light-emissive layer including a red phosphorescent light-emissive layer that includes:
a dopant material including an organometallic compound represented by Chemical Formula 1; and
a host material including a compound represented by Chemical Formula 2 and a compound represented by Chemical Formula 3: 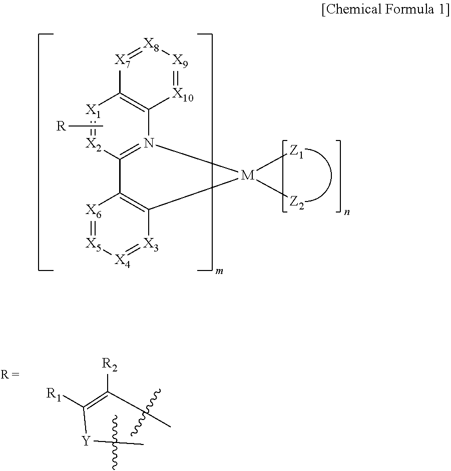
wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
in R, each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C3-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO, and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ are optionally fused with each other to form a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group, 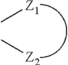
represents a bidentate ligand,
m is an integer of 1, 2 or 3, n is an integer of 0, 1 or 2, and m+n is an oxidation number of the metal (M), 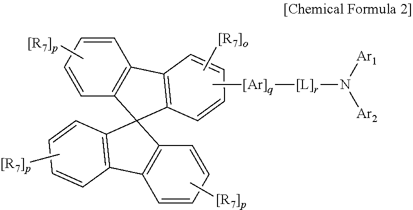
wherein in the Chemical Formula 2,
Ar independently represents a substituted or unsubstituted aromatic ring group selected from the group consisting of benzene, naphthalene, phenanthrene, fluorene, spirobifluorene, dibenzofuran, and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, linker L represents one selected from the group consisting of a substituted or unsubstituted C6-C30 arylene group, a substituted or unsubstituted C3-C30 heteroarylene group, and a substituted or unsubstituted C7-C20 arylalkylene group, 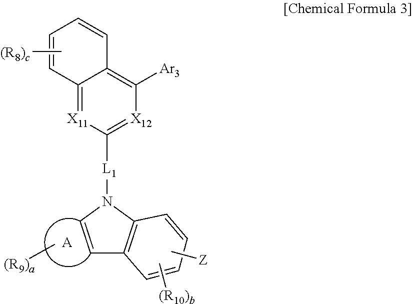
wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ is optionally substituted with at least one of deuterium and a halogen atom,
Z represents one selected from the group consisting of the following structures: 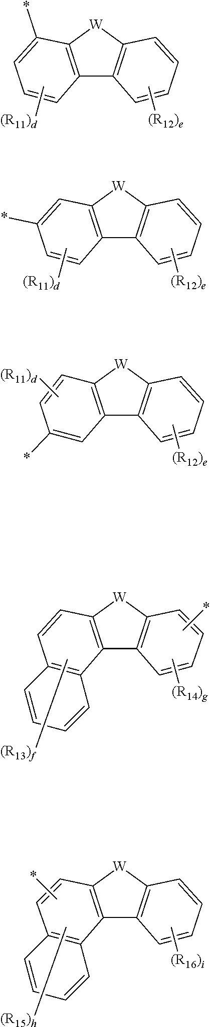
W represents one selected from the group consisting of O, S, NR₁₇, CR₁₇R₁₈ and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

11. The organic light-emitting device of claim 10, wherein the organometallic compound represented by the Chemical Formula 1 includes at least one selected from the group consisting of compound RD-1 to compound RD-20:

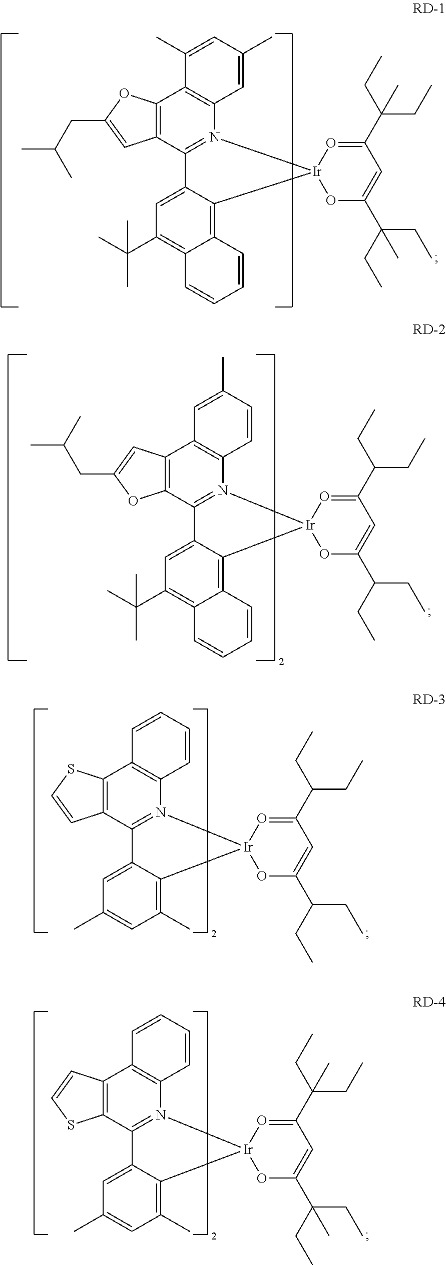

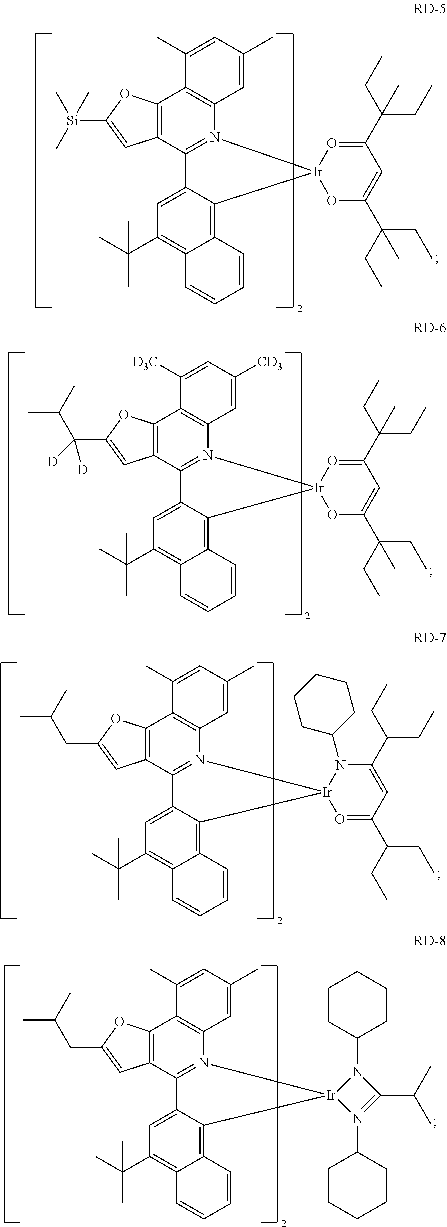

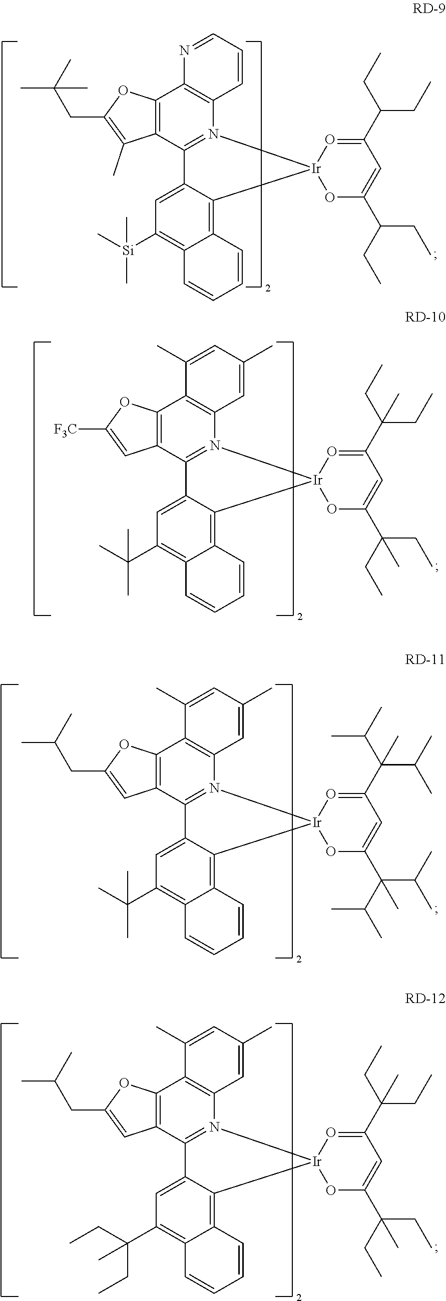

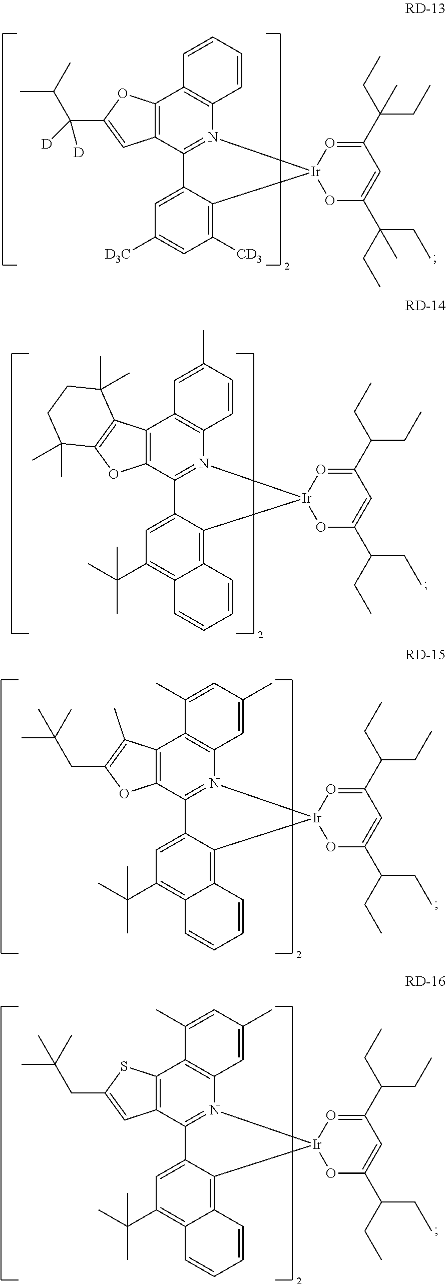

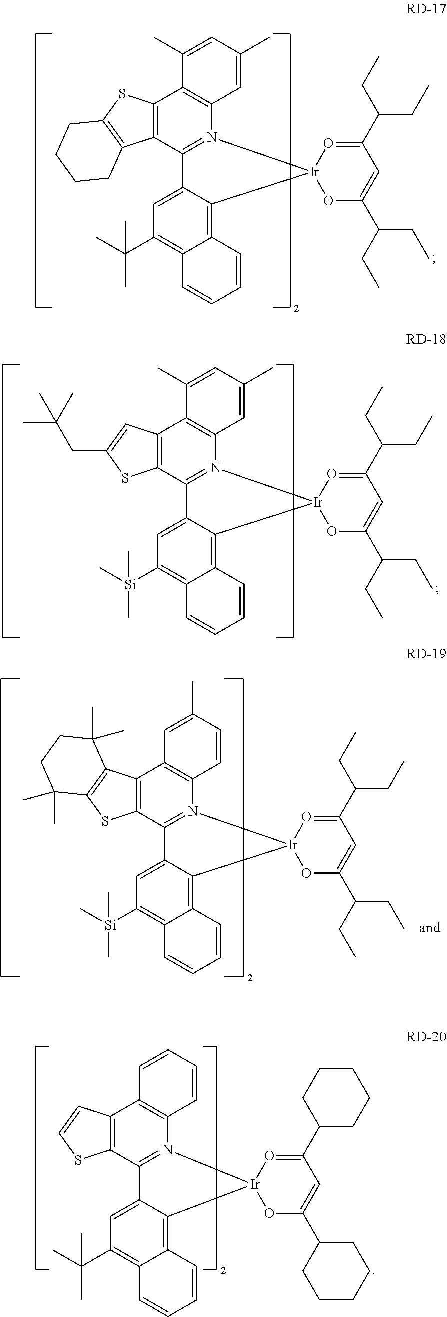

12. The organic light-emitting device of claim 10, wherein the compound represented by the Chemical Formula 2 includes at least one selected from the group consisting of compound RHH-1 to compound RHH-20:

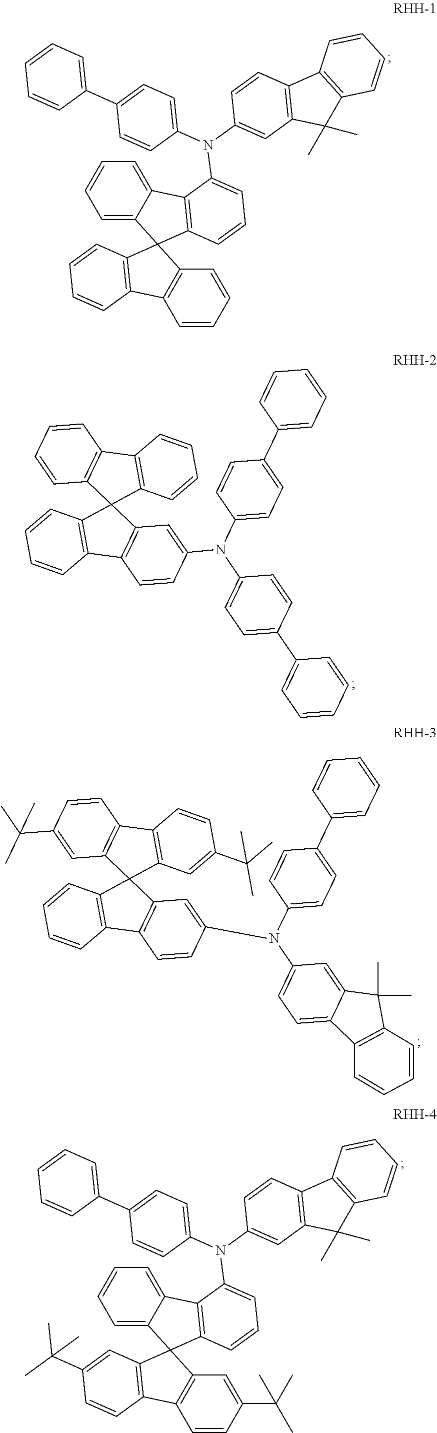

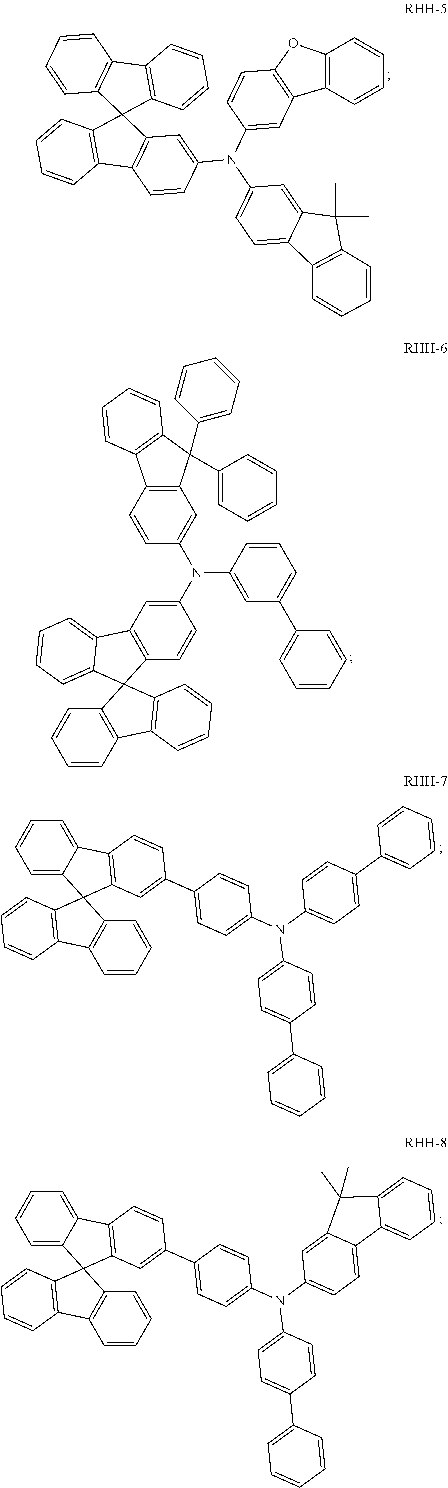 [SMILES: CC1(C)c2ccccc2-c2ccc(N(c3ccc4c(c3)C3(c5ccccc5-c5ccccc53)c3ccccc3-4)c3ccc4oc5ccccc5c4c3)cc21 ; c1ccc(-c2cccc(N(c3ccc4c(c3)-c3ccccc3C43c4ccccc4-c4ccccc43)c3ccc4c(c3)C(c3ccccc3)(c3ccccc3)c3ccccc3-4)c2)cc1 ; c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

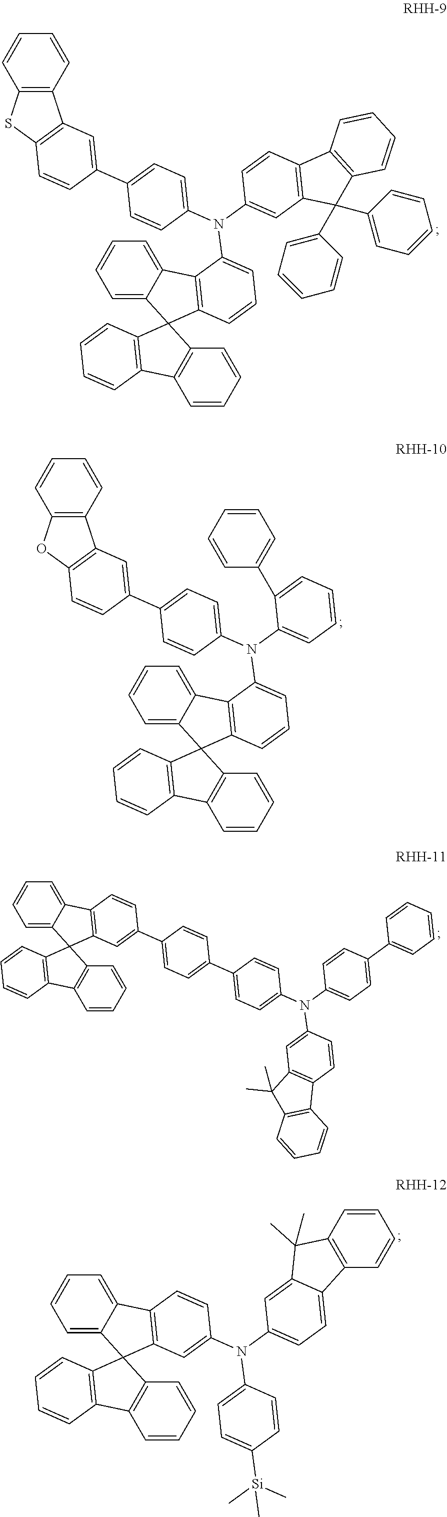 [SMILES: c1ccc(C2(c3ccccc3)c3ccccc3-c3ccc(N(c4ccc(-c5ccc6sc7ccccc7c6c5)cc4)c4cccc5c4-c4ccccc4C54c5ccccc5-c5ccccc54)cc32)cc1 ; c1ccc(-c2ccccc2N(c2ccc(-c3ccc4oc5ccccc5c4c3)cc2)c2cccc3c2-c2ccccc2C32c3ccccc3-c3ccccc32)cc1 ; CC1(C)c2ccccc2-c2ccc(N(c3ccc(-c4ccccc4)cc3)c3ccc(-c4ccc(-c5ccc6c(c5)C5(c7ccccc7-c7ccccc75)c5ccccc5-6)cc4)cc3)cc21 ; CC1(C)c2ccccc2-c2ccc(N(c3ccc([Si](C)(C)C)cc3)c3ccc4c(c3)C3(c5ccccc5-c5ccccc53)c3ccccc3-4)cc21]

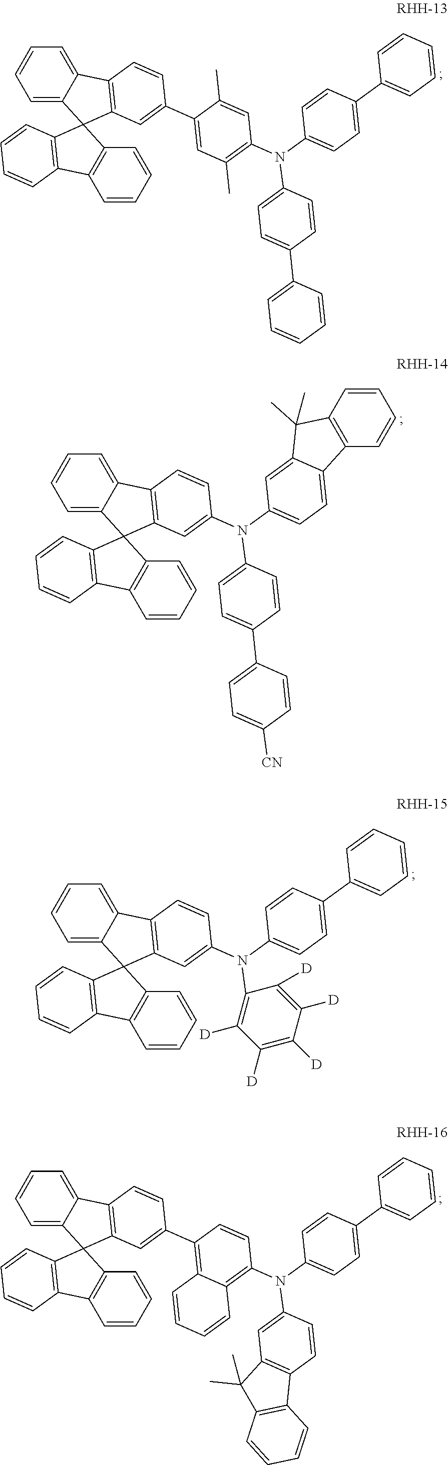 [SMILES: Cc1cc(N(c2ccc(-c3ccccc3)cc2)c2ccc(-c3ccccc3)cc2)c(C)cc1-c1ccc2c(c1)C1(c3ccccc3-c3ccccc31)c1ccccc1-2 ; CC1(C)c2ccccc2-c2ccc(N(c3ccc(-c4ccc(C#N)cc4)cc3)c3ccc4c(c3)C3(c5ccccc5-c5ccccc53)c3ccccc3-4)cc21 ; [2H]c1c([2H])c([2H])c(N(c2ccc(-c3ccccc3)cc2)c2ccc3c(c2)C2(c4ccccc4-c4ccccc42)c2ccccc2-3)c([2H])c1[2H] ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)c4ccccc34)cc21]

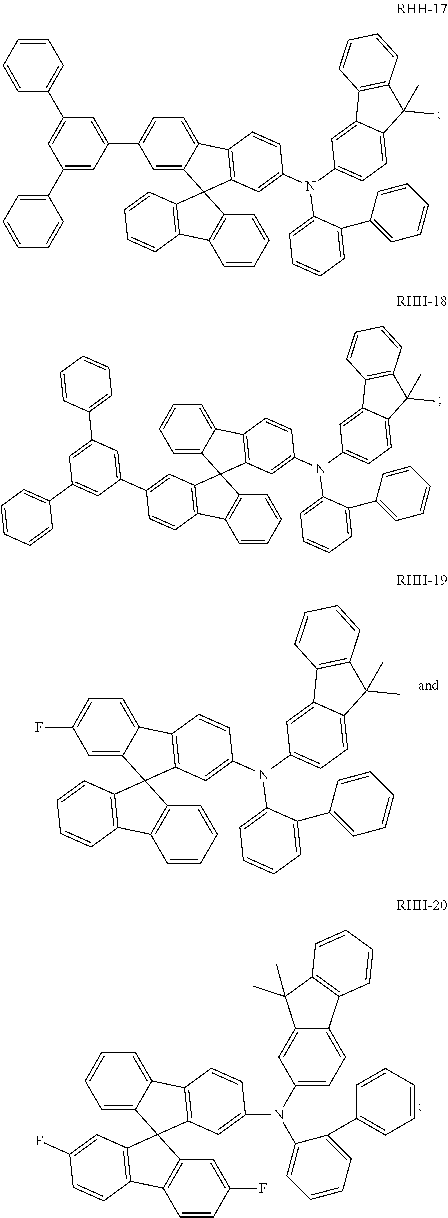 [SMILES: CC1(C)c2ccccc2-c2cc(N(c3ccc4c(c3)C3(c5ccccc5-c5ccccc53)c3cc(-c5cc(-c6ccccc6)cc(-c6ccccc6)c5)ccc3-4)c3ccccc3-c3ccccc3)ccc21 ; CC1(C)c2ccccc2-c2cc(N(c3ccc4c(c3)C3(c5ccccc5-c5ccc(-c6cc(-c7ccccc7)cc(-c7ccccc7)c6)cc53)c3ccccc3-4)c3ccccc3-c3ccccc3)ccc21 ; CC1(C)c2ccccc2-c2cc(N(c3ccc4c(c3)C3(c5ccccc5-c5ccccc53)c3cc(F)ccc3-4)c3ccccc3-c3ccccc3)ccc21 ; CC1(C)c2ccccc2-c2ccc(N(c3ccc4c(c3)C3(c5ccccc5-4)c4cc(F)ccc4-c4ccc(F)cc43)c3ccccc3-c3ccccc3)cc21]

13. The organic light-emitting device of claim 10, wherein the compound represented by the Chemical Formula 3 includes at least one selected from the group consisting of compound REH-1 to compound REH-20:

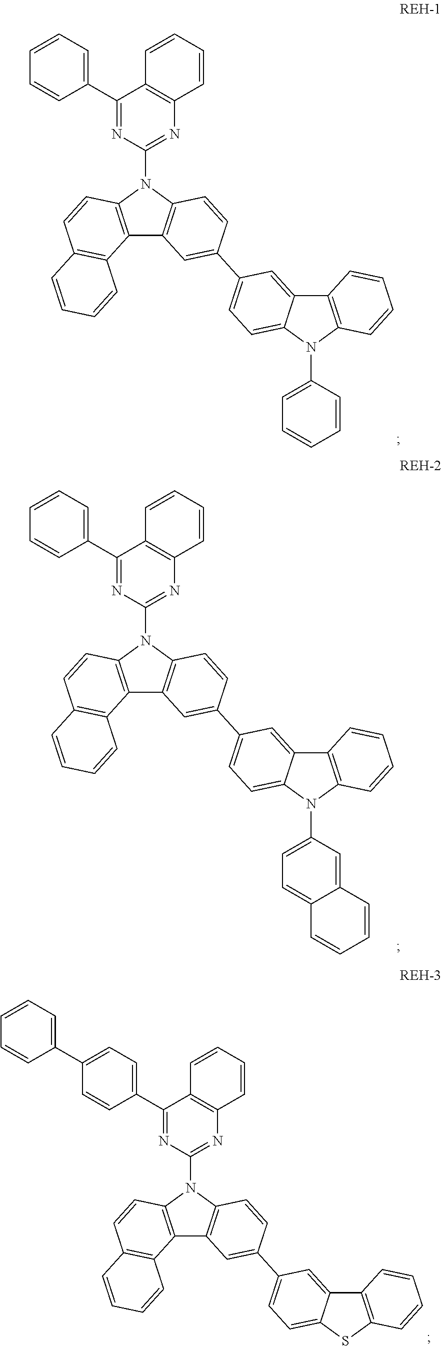 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2nc(-n3c4ccc(-c5ccc6c(c5)c5ccccc5n6-c5ccc6ccccc6c5)cc4c4c5ccccc5ccc43)nc3ccccc23)cc1 ; c1ccc(-c2ccc(-c3nc(-n4c5ccc(-c6ccc7sc8ccccc8c7c6)cc5c5c6ccccc6ccc54)nc4ccccc34)cc2)cc1]

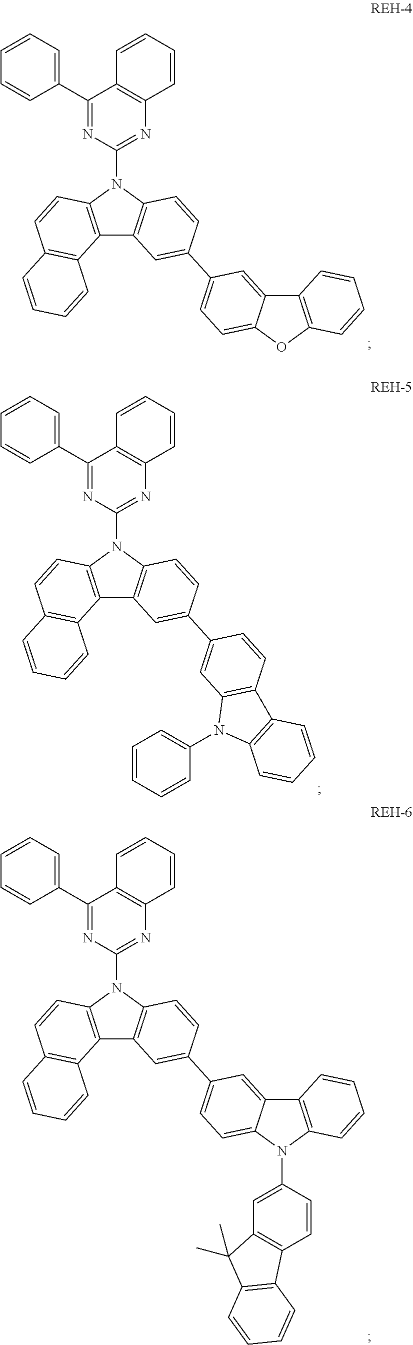

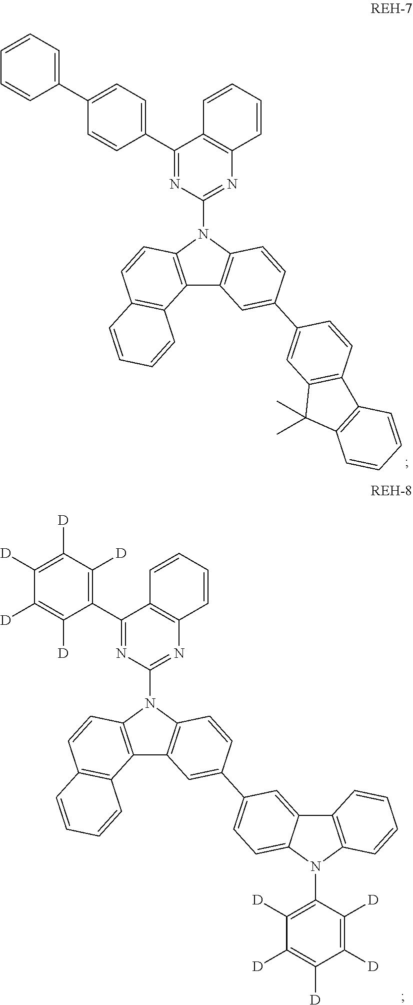 [SMILES: CC1(C)c2ccccc2-c2ccc(-c3ccc4c(c3)c3c5ccccc5ccc3n4-c3nc(-c4ccc(-c5ccccc5)cc4)c4ccccc4n3)cc21 ; [2H]c1c([2H])c([2H])c(-c2nc(-n3c4ccc(-c5ccc6c(c5)c5ccccc5n6-c5c([2H])c([2H])c([2H])c([2H])c5[2H])cc4c4c5ccccc5ccc43)nc3ccccc23)c([2H])c1[2H]]

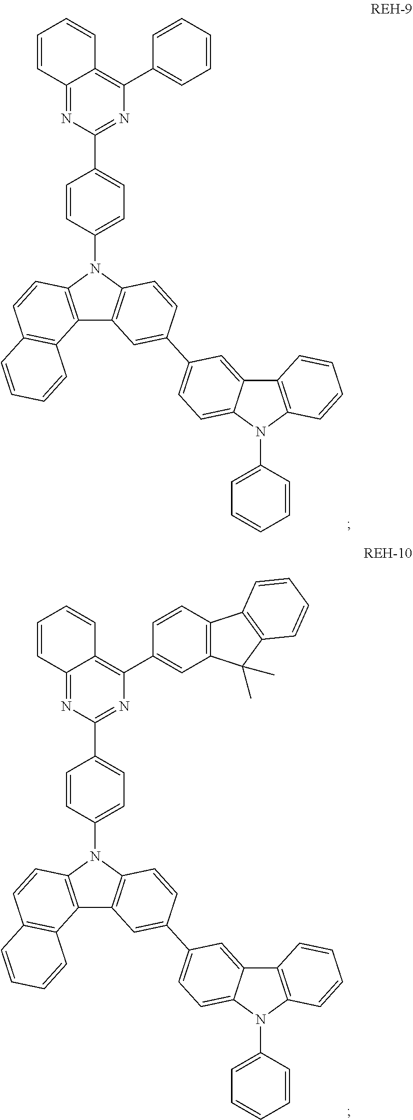 [SMILES: c1ccc(-c2nc(-c3ccc(-n4c5ccc(-c6ccc7c(c6)c6ccccc6n7-c6ccccc6)cc5c5c6ccccc6ccc54)cc3)nc3ccccc23)cc1 ; CC1(C)c2ccccc2-c2ccc(-c3nc(-c4ccc(-n5c6ccc(-c7ccc8c(c7)c7ccccc7n8-c7ccccc7)cc6c6c7ccccc7ccc65)cc4)nc4ccccc34)cc21]

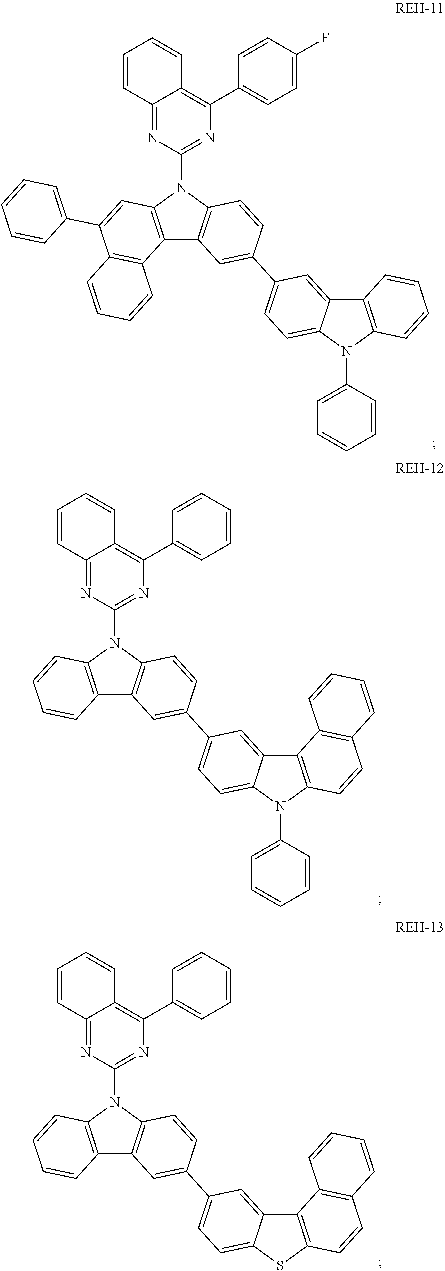 [SMILES: Fc1ccc(-c2nc(-n3c4ccc(-c5ccc6c(c5)c5ccccc5n6-c5ccccc5)cc4c4c5ccccc5c(-c5ccccc5)cc43)nc3ccccc23)cc1 ; c1ccc(-c2nc(-n3c4ccccc4c4cc(-c5ccc6c(c5)c5c7ccccc7ccc5n6-c5ccccc5)ccc43)nc3ccccc23)cc1 ; c1ccc(-c2nc(-n3c4ccccc4c4cc(-c5ccc6sc7ccc8ccccc8c7c6c5)ccc43)nc3ccccc23)cc1]

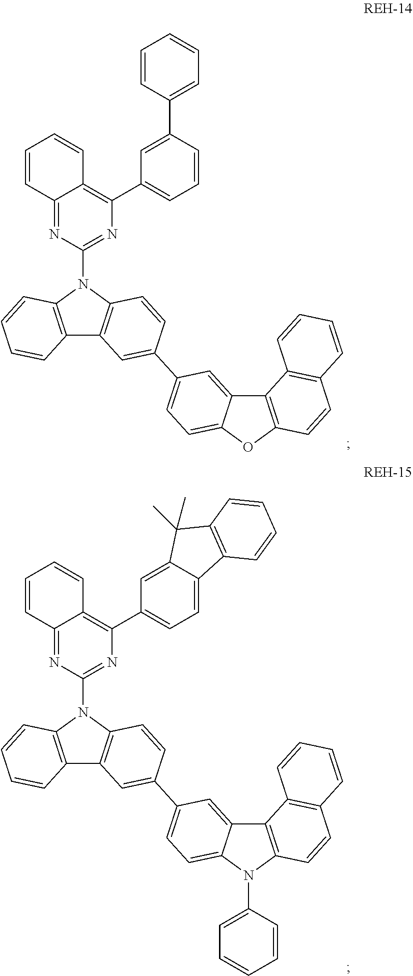 [SMILES: c1ccc(-c2cccc(-c3nc(-n4c5ccccc5c5cc(-c6ccc7oc8ccc9ccccc9c8c7c6)ccc54)nc4ccccc34)c2)cc1 ; CC1(C)c2ccccc2-c2ccc(-c3nc(-n4c5ccccc5c5cc(-c6ccc7c(c6)c6c8ccccc8ccc6n7-c6ccccc6)ccc54)nc4ccccc34)cc21]

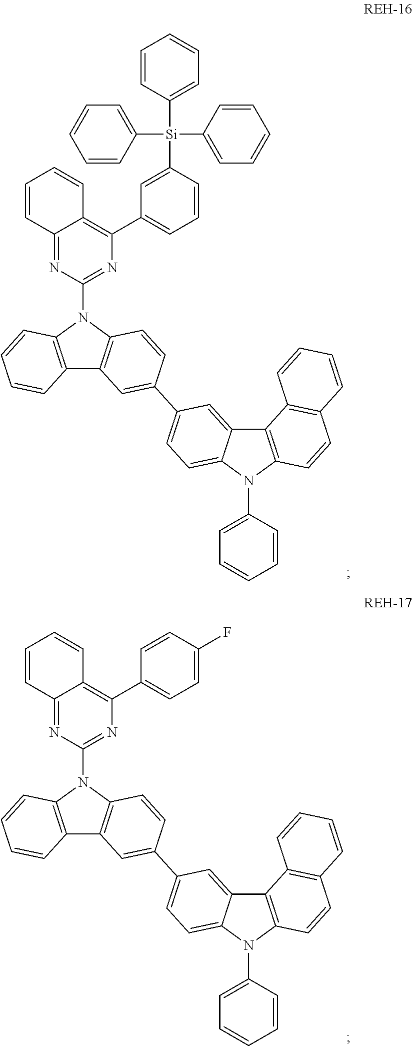 [SMILES: c1ccc(-n2c3ccc(-c4ccc5c(c4)c4ccccc4n5-c4nc(-c5cccc([Si](c6ccccc6)(c6ccccc6)c6ccccc6)c5)c5ccccc5n4)cc3c3c4ccccc4ccc32)cc1 ; Fc1ccc(-c2nc(-n3c4ccccc4c4cc(-c5ccc6c(c5)c5c7ccccc7ccc5n6-c5ccccc5)ccc43)nc3ccccc23)cc1]

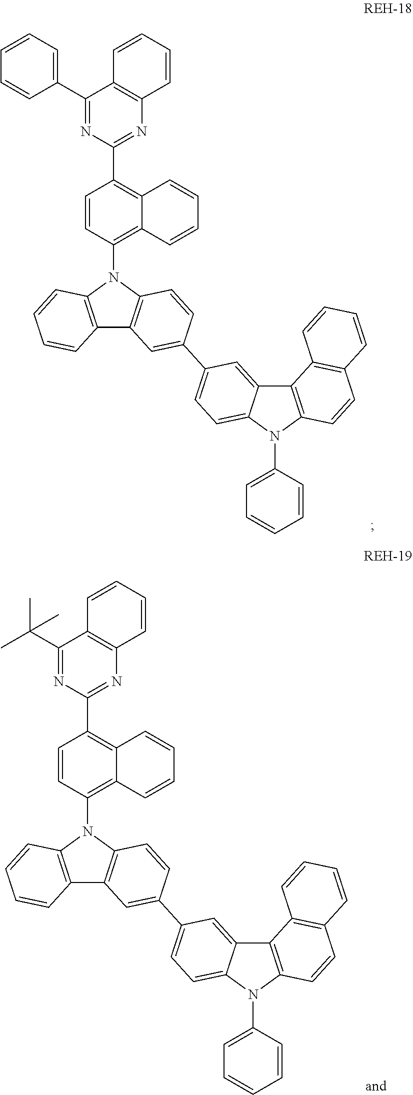 [SMILES: c1ccc(-c2nc(-c3ccc(-n4c5ccccc5c5cc(-c6ccc7c(c6)c6c8ccccc8ccc6n7-c6ccccc6)ccc54)c4ccccc34)nc3ccccc23)cc1 ; CC(C)(C)c1nc(-c2ccc(-n3c4ccccc4c4cc(-c5ccc6c(c5)c5c7ccccc7ccc5n6-c5ccccc5)ccc43)c3ccccc23)nc2ccccc12]

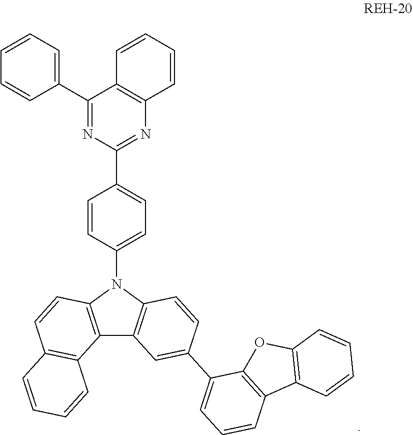 [SMILES: c1ccc(-c2nc(-c3ccc(-n4c5ccc(-c6cccc7c6oc6ccccc67)cc5c5c6ccccc6ccc54)cc3)nc3ccccc23)cc1]

14. An organic light-emitting device comprising:
a first electrode;
a second electrode facing the first electrode;
a first light-emitting stack;
a second light-emitting stack; and
a third light-emitting stack, wherein the first, second, and third light-emitting stacks are disposed between the first electrode and the second electrode,
wherein each of the first light-emitting stack, the second light-emitting stack, and the third light-emitting stack includes at least one red phosphorescent light-emissive layer that includes:
a dopant material including an organometallic compound represented by Chemical Formula 1; and
a host material including a compound represented by Chemical Formula 2 and a compound represented by Chemical Formula 3: 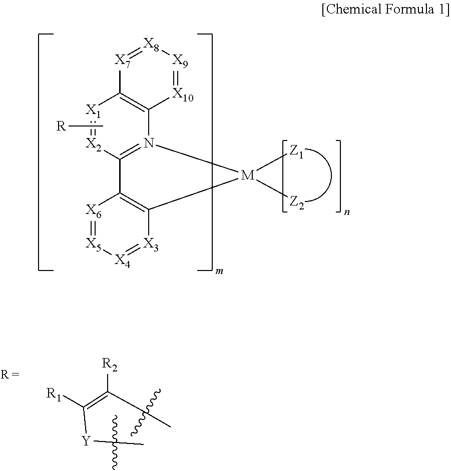
wherein in the Chemical Formula 1,
M represents a central coordination metal, and includes one selected from the group consisting of molybdenum (Mo), tungsten (W), rhenium (Re), ruthenium (Ru), osmium (Os), rhodium (Rh), iridium (Ir), palladium (Pd), platinum (Pt), and gold (Au),
R represents a structure connected to X₁ and X₂ to form a fused ring,
X₁ and X₂ each independently represents C,
each of R₁ and R₂ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
R₁ and R₂ optionally together form a C5-C6 carbon ring, a C3-C6 heterocyclic ring or C7-C10 arylalkyl group,
Y represents one selected from the group consisting of BR₃, CR₃R₄, C═O, CNR₃, SiR₃R₄, NR₃, PR₃, AsR₃, SbR₃, P(O)R₃, P(S)R₃, P(Se)R₃, As(O)R₃, As(S)R₃, As(Se)R₃, Sb(O)R₃, Sb(S)R₃, Sb(Se)R₃, O, S, Se, Te, SO, SO₂, SeO, SeO₂, TeO, and TeO₂,
each of R₃ and R₄ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of X₃ to X₆ independently represents one selected from CR₅ and nitrogen (N),
adjacent substituents among X₃ to X₆ optionally fused with each other to form a C5-C6 carbon ring or a C3-C6 heterocyclic ring,
each of X₇ to X₁₀ independently represents one selected from CR₆ and nitrogen (N),
each of R₅ and R₆ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group, 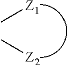
represents a bidentate ligand,
m is an integer of 1, 2 or 3, n is an integer of 0, 1 or 2, and m+n is an oxidation number of the metal (M), 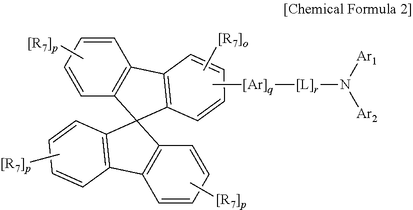
wherein in the Chemical Formula 2,
Ar independently represents a substituted or unsubstituted aromatic ring group selected from the group consisting of benzene, naphthalene, phenanthrene, fluorene, spirobifluorene, dibenzofuran, and dibenzothiophene,
each of Ar₁ and Ar₂ independently represents a substituted or unsubstituted C6-C60 aryl group or a substituted or unsubstituted C3-C60 heteroaryl group,
each R₇ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
o is an integer of 0, 1, 2 or 3, each p is independently an integer of 0, 1, 2, 3 or 4, q is an integer of 0, 1 or 2, and r is an integer of 0 or 1,
when r is 1, a linker L represents one selected from the group consisting of a substituted or unsubstituted C6-C30 arylene group, a substituted or unsubstituted C3-C30 heteroarylene group, and a substituted or unsubstituted C7-C20 arylalkylene group, 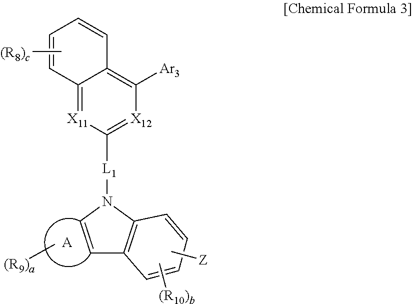
wherein in the Chemical Formula 3,
an A ring represents a substituted or unsubstituted C6-C30 aryl group,
each of X₁₁ and X₁₂ independently represents N or CR′,
L₁ represents one selected from the group consisting of a single bond, a substituted or unsubstituted C6-C30 arylene group, a substituted or unsubstituted C2-C30 heteroarylene group, and a substituted or unsubstituted C3-C30 cycloalkylene group,
Ar₃ represents one selected from the group consisting of hydrogen, deuterium, halogen, a substituted or unsubstituted C1-C30 alkyl group, a substituted or unsubstituted C6-C30 aryl group, a substituted or unsubstituted C2-C30 heteroaryl group, a substituted or unsubstituted C6-C30 silylalkyl group, and a substituted or unsubstituted C6-C30 silylaryl group,
at least one hydrogen of each of the alkyl group, the aryl group, the heteroaryl group, the silylalkyl group or the silylaryl group selected as Ar₃ is optionally substituted with at least one of deuterium and a halogen atom,
Z represents one selected from the group consisting of following structures: 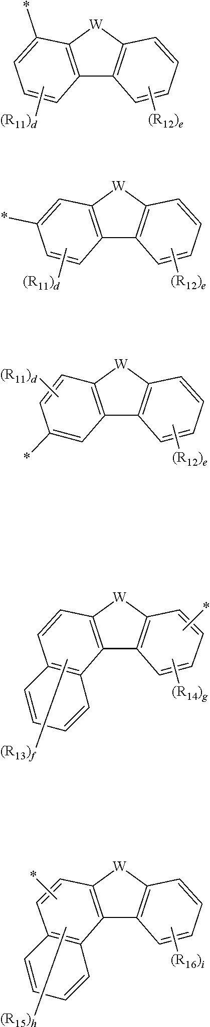
W represents one selected from the group consisting of O, S, NR₁₇, CR₁₇R₁₈, and SiR₁₇R₁₈,
each of R₈ to R₁₈ and R′ independently represents one selected from the group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C2-C20 alkenyl group, a substituted or unsubstituted C3-C20 cycloalkenyl group, a substituted or unsubstituted C2-C20 heteroalkenyl group, a substituted or unsubstituted C2-C20 alkynyl group, a substituted or unsubstituted C6-C30 aryl group, a substituted or unsubstituted C3-C30 heteroaryl group, a substituted or unsubstituted C1-C20 alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group,
each of a, c, e and i independently is an integer of 1, 2, 3 or 4, each of b, d, and g independently is an integer of 1, 2 or 3, f is an integer of 1, 2, 3, 4, 5 or 6, and h is an integer of 1, 2, 3, 4 or 5.

15. The organic light-emitting device of claim 14, wherein the organometallic compound represented by the Chemical Formula 1 includes at least one selected from the group consisting of following compound RD-1 to compound RD-20:

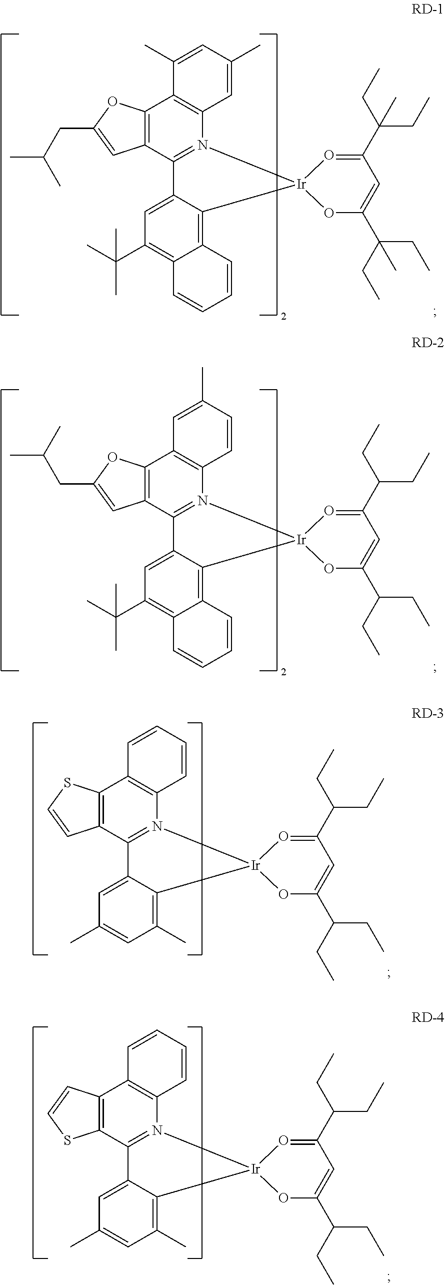

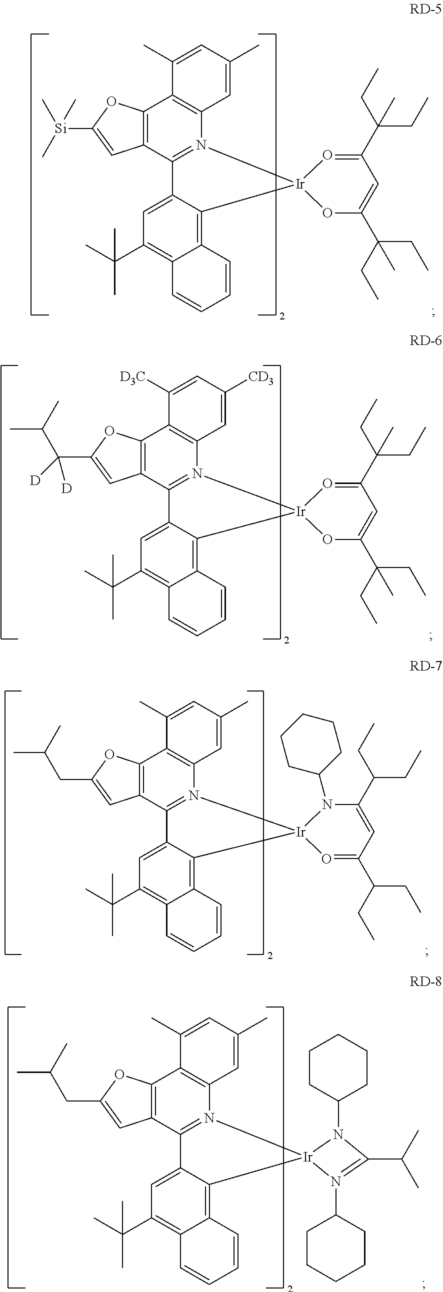

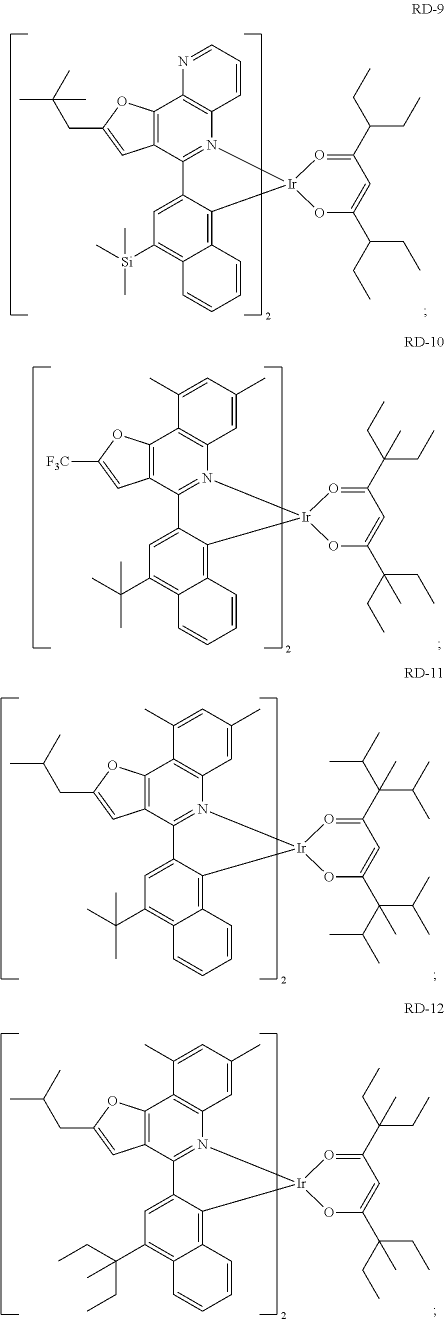

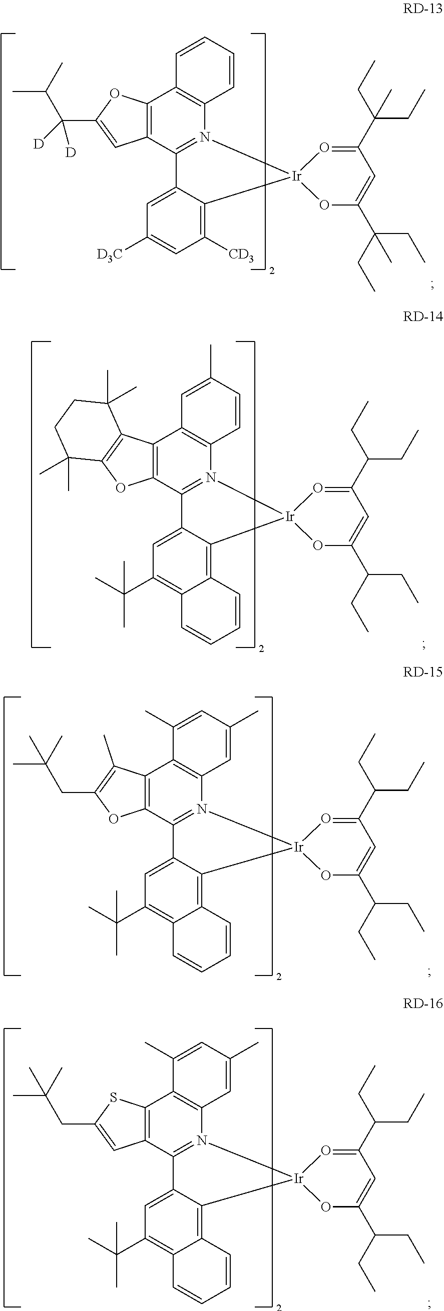

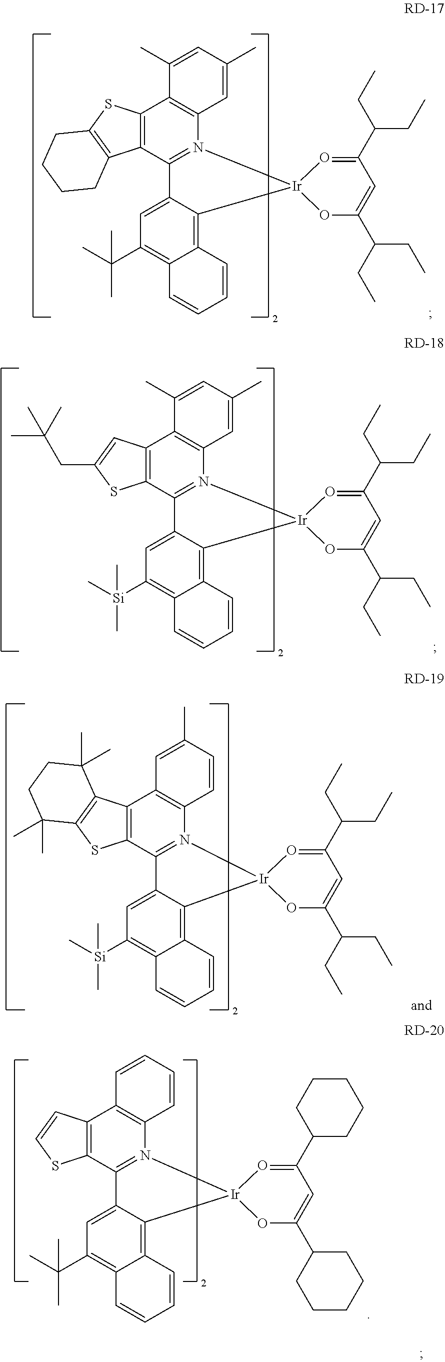

16. The organic light-emitting device of claim 14, wherein the compound represented by the Chemical Formula 2 includes at least one selected from the group consisting of following compound RHH-1 to compound RHH-20:

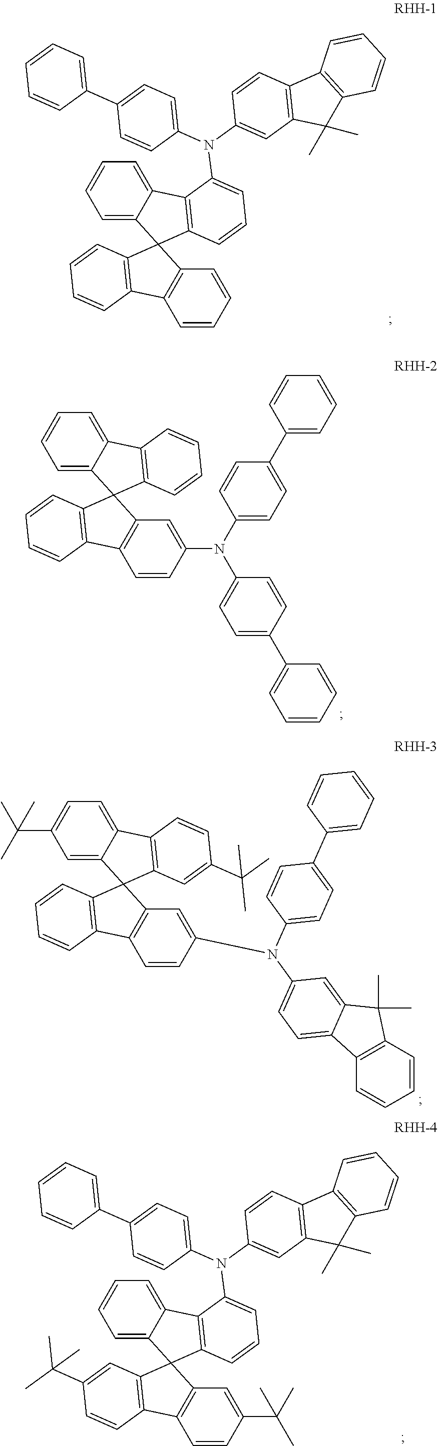

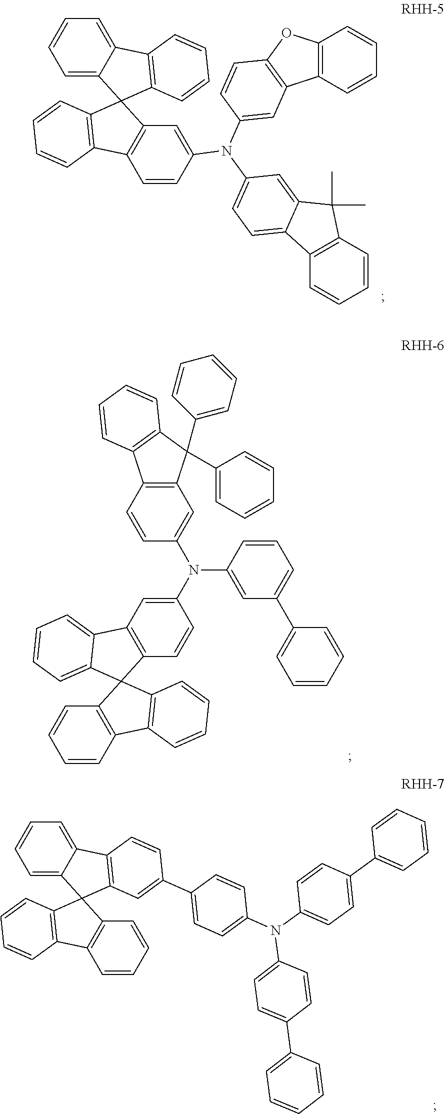 [SMILES: CC1(C)c2ccccc2-c2ccc(N(c3ccc4c(c3)C3(c5ccccc5-c5ccccc53)c3ccccc3-4)c3ccc4oc5ccccc5c4c3)cc21 ; c1ccc(-c2cccc(N(c3ccc4c(c3)-c3ccccc3C43c4ccccc4-c4ccccc43)c3ccc4c(c3)C(c3ccccc3)(c3ccccc3)c3ccccc3-4)c2)cc1 ; c1ccc(-c2ccc(N(c3ccc(-c4ccccc4)cc3)c3ccc(-c4ccc5c(c4)C4(c6ccccc6-c6ccccc64)c4ccccc4-5)cc3)cc2)cc1]

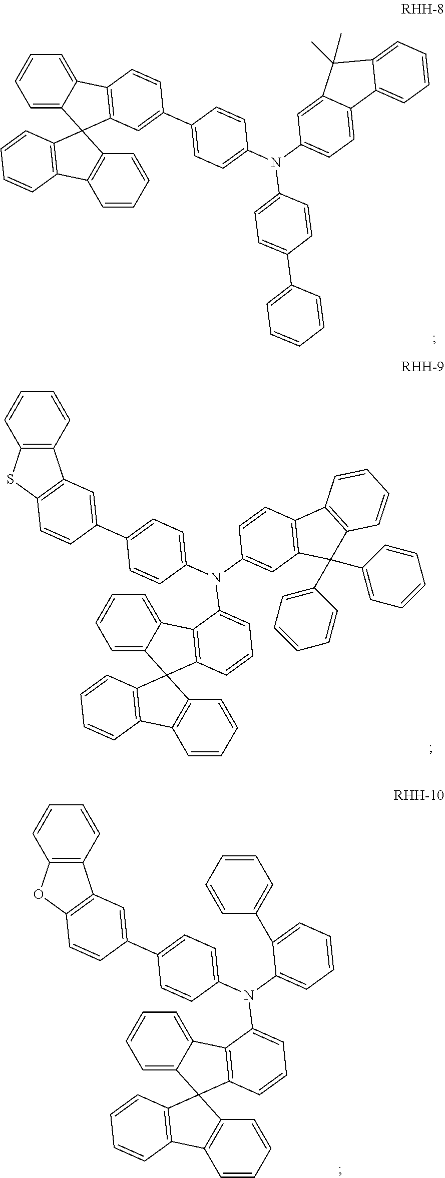 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21 ; c1ccc(C2(c3ccccc3)c3ccccc3-c3ccc(N(c4ccc(-c5ccc6sc7ccccc7c6c5)cc4)c4cccc5c4-c4ccccc4C54c5ccccc5-c5ccccc54)cc32)cc1 ; c1ccc(-c2ccccc2N(c2ccc(-c3ccc4oc5ccccc5c4c3)cc2)c2cccc3c2-c2ccccc2C32c3ccccc3-c3ccccc32)cc1]

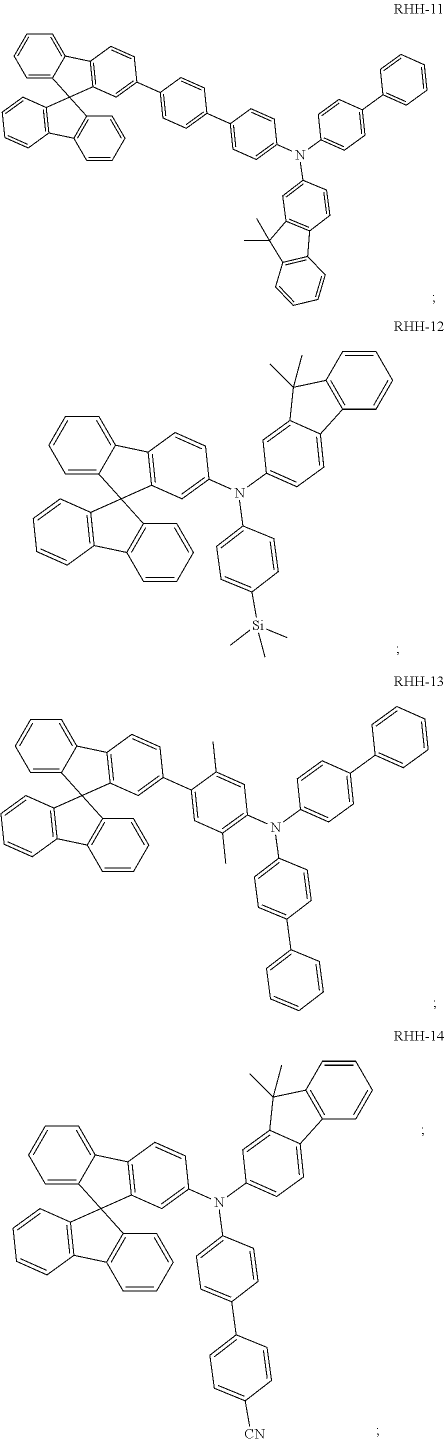 [SMILES: CC1(C)c2ccccc2-c2ccc(N(c3ccc(-c4ccccc4)cc3)c3ccc(-c4ccc(-c5ccc6c(c5)C5(c7ccccc7-c7ccccc75)c5ccccc5-6)cc4)cc3)cc21 ; CC1(C)c2ccccc2-c2ccc(N(c3ccc([Si](C)(C)C)cc3)c3ccc4c(c3)C3(c5ccccc5-c5ccccc53)c3ccccc3-4)cc21 ; Cc1cc(N(c2ccc(-c3ccccc3)cc2)c2ccc(-c3ccccc3)cc2)c(C)cc1-c1ccc2c(c1)C1(c3ccccc3-c3ccccc31)c1ccccc1-2 ; CC1(C)c2ccccc2-c2ccc(N(c3ccc(-c4ccc(C#N)cc4)cc3)c3ccc4c(c3)C3(c5ccccc5-c5ccccc53)c3ccccc3-4)cc21]

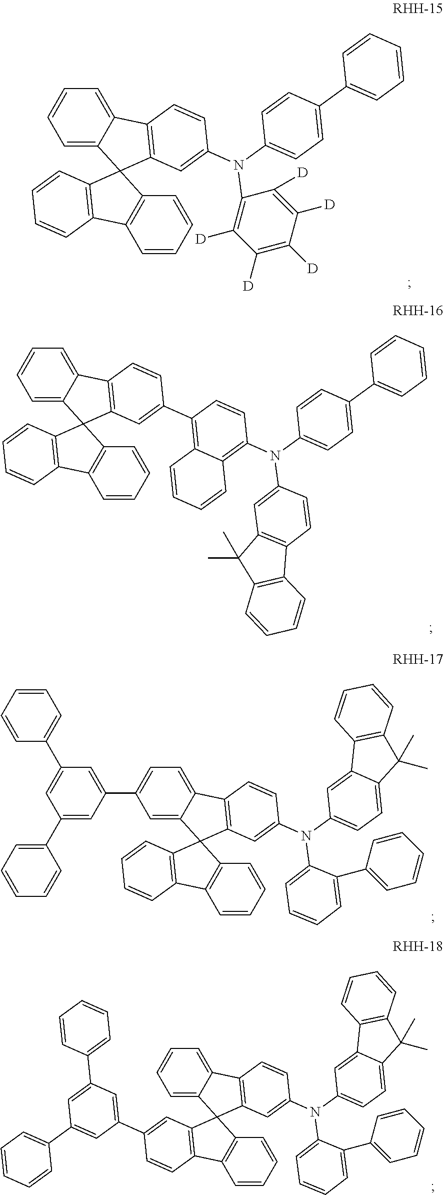 [SMILES: [2H]c1c([2H])c([2H])c(N(c2ccc(-c3ccccc3)cc2)c2ccc3c(c2)C2(c4ccccc4-c4ccccc42)c2ccccc2-3)c([2H])c1[2H] ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)c4ccccc34)cc21 ; CC1(C)c2ccccc2-c2cc(N(c3ccc4c(c3)C3(c5ccccc5-c5ccccc53)c3cc(-c5cc(-c6ccccc6)cc(-c6ccccc6)c5)ccc3-4)c3ccccc3-c3ccccc3)ccc21 ; CC1(C)c2ccccc2-c2cc(N(c3ccc4c(c3)C3(c5ccccc5-c5ccc(-c6cc(-c7ccccc7)cc(-c7ccccc7)c6)cc53)c3ccccc3-4)c3ccccc3-c3ccccc3)ccc21]

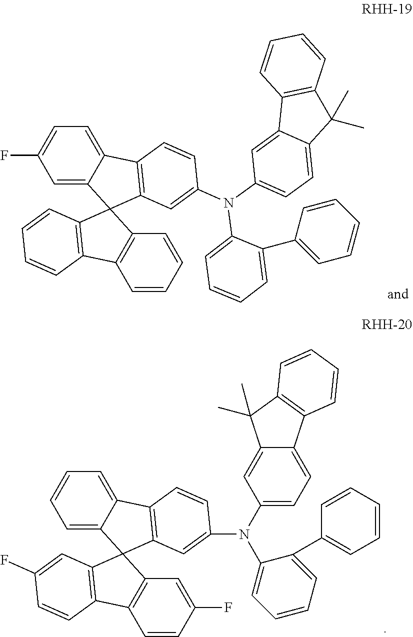 [SMILES: CC1(C)c2ccccc2-c2cc(N(c3ccc4c(c3)C3(c5ccccc5-c5ccccc53)c3cc(F)ccc3-4)c3ccccc3-c3ccccc3)ccc21 ; CC1(C)c2ccccc2-c2ccc(N(c3ccc4c(c3)C3(c5ccccc5-4)c4cc(F)ccc4-c4ccc(F)cc43)c3ccccc3-c3ccccc3)cc21]

17. The organic light-emitting device of claim 14, wherein the compound represented by the Chemical Formula 3 includes at least one selected from the group consisting of following compound REH-1 to compound REH-20:

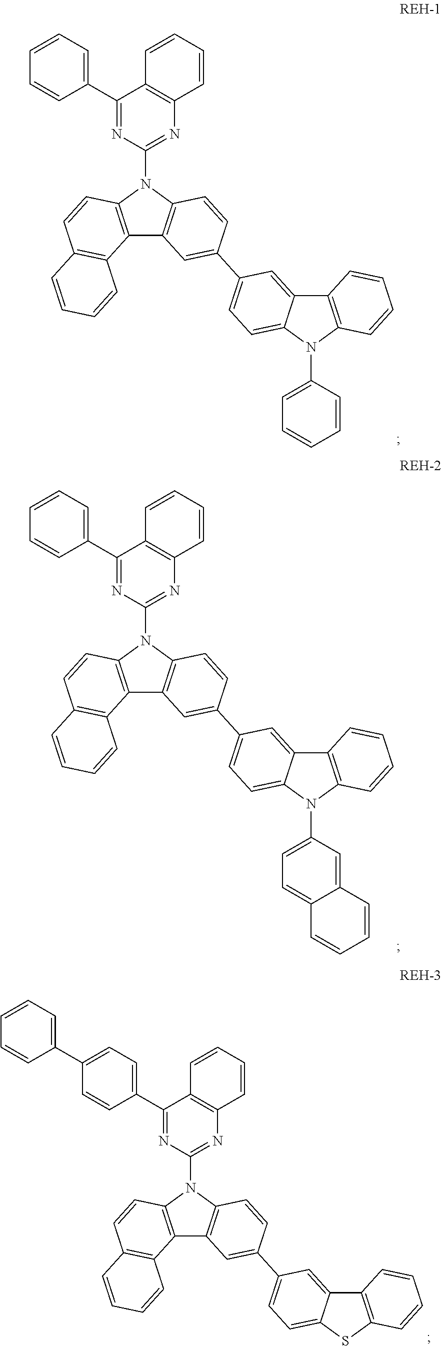 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2nc(-n3c4ccc(-c5ccc6c(c5)c5ccccc5n6-c5ccc6ccccc6c5)cc4c4c5ccccc5ccc43)nc3ccccc23)cc1 ; c1ccc(-c2ccc(-c3nc(-n4c5ccc(-c6ccc7sc8ccccc8c7c6)cc5c5c6ccccc6ccc54)nc4ccccc34)cc2)cc1]

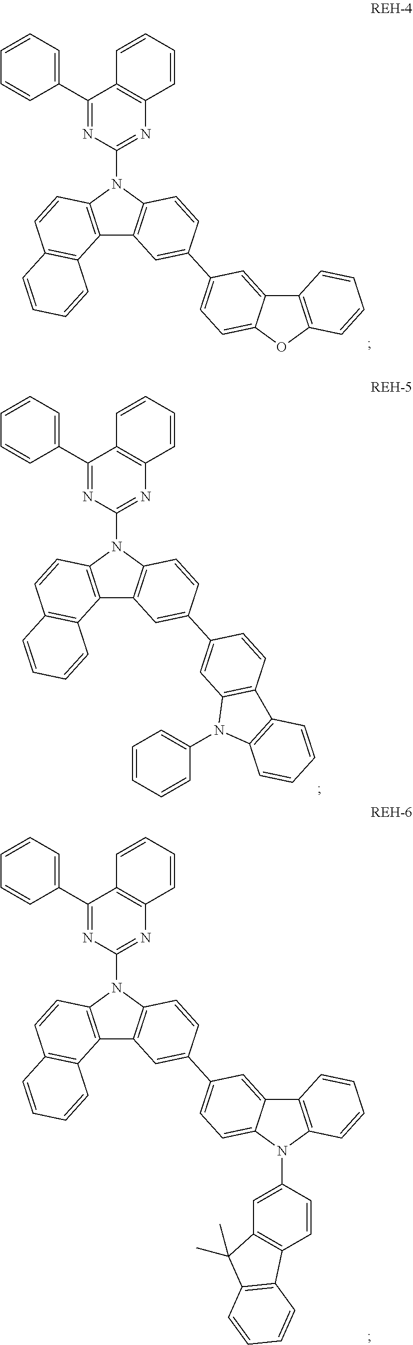

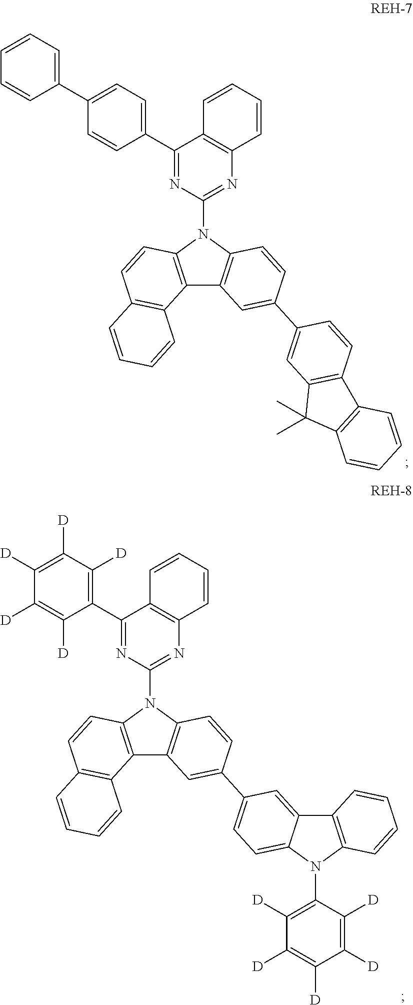 [SMILES: CC1(C)c2ccccc2-c2ccc(-c3ccc4c(c3)c3c5ccccc5ccc3n4-c3nc(-c4ccc(-c5ccccc5)cc4)c4ccccc4n3)cc21 ; [2H]c1c([2H])c([2H])c(-c2nc(-n3c4ccc(-c5ccc6c(c5)c5ccccc5n6-c5c([2H])c([2H])c([2H])c([2H])c5[2H])cc4c4c5ccccc5ccc43)nc3ccccc23)c([2H])c1[2H]]

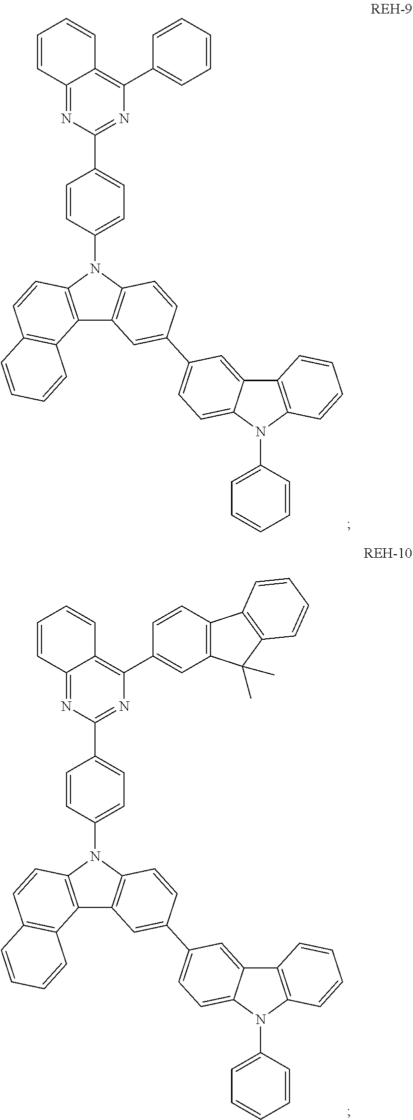 [SMILES: c1ccc(-c2nc(-c3ccc(-n4c5ccc(-c6ccc7c(c6)c6ccccc6n7-c6ccccc6)cc5c5c6ccccc6ccc54)cc3)nc3ccccc23)cc1 ; CC1(C)c2ccccc2-c2ccc(-c3nc(-c4ccc(-n5c6ccc(-c7ccc8c(c7)c7ccccc7n8-c7ccccc7)cc6c6c7ccccc7ccc65)cc4)nc4ccccc34)cc21]

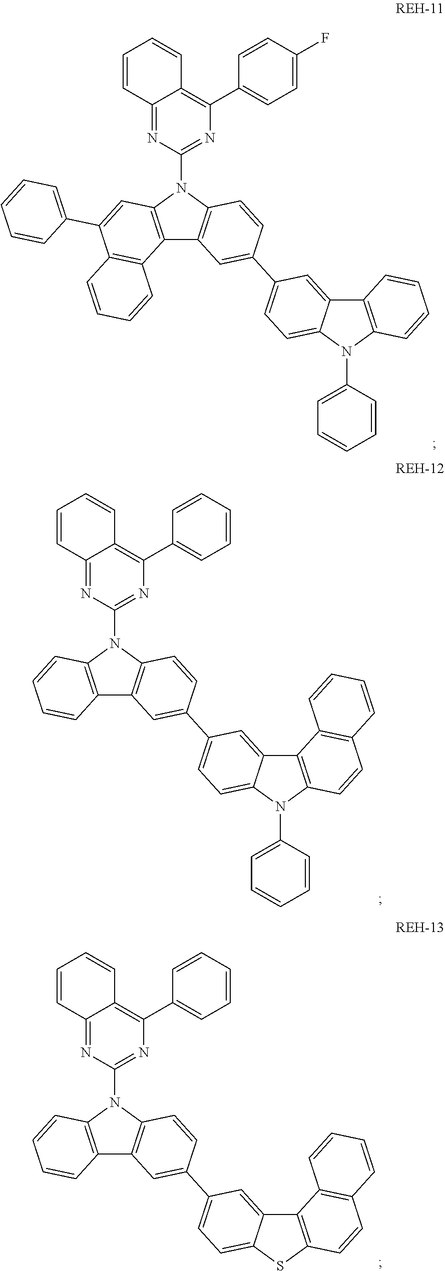 [SMILES: Fc1ccc(-c2nc(-n3c4ccc(-c5ccc6c(c5)c5ccccc5n6-c5ccccc5)cc4c4c5ccccc5c(-c5ccccc5)cc43)nc3ccccc23)cc1 ; c1ccc(-c2nc(-n3c4ccccc4c4cc(-c5ccc6c(c5)c5c7ccccc7ccc5n6-c5ccccc5)ccc43)nc3ccccc23)cc1 ; c1ccc(-c2nc(-n3c4ccccc4c4cc(-c5ccc6sc7ccc8ccccc8c7c6c5)ccc43)nc3ccccc23)cc1]

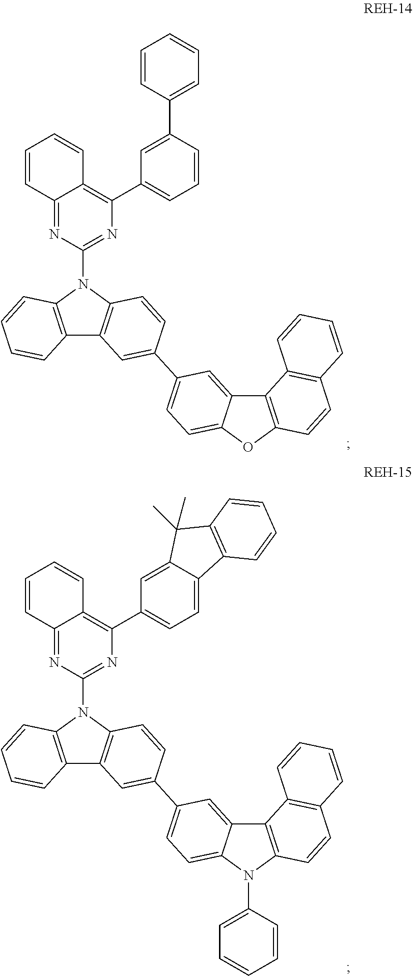 [SMILES: c1ccc(-c2cccc(-c3nc(-n4c5ccccc5c5cc(-c6ccc7oc8ccc9ccccc9c8c7c6)ccc54)nc4ccccc34)c2)cc1 ; CC1(C)c2ccccc2-c2ccc(-c3nc(-n4c5ccccc5c5cc(-c6ccc7c(c6)c6c8ccccc8ccc6n7-c6ccccc6)ccc54)nc4ccccc34)cc21]

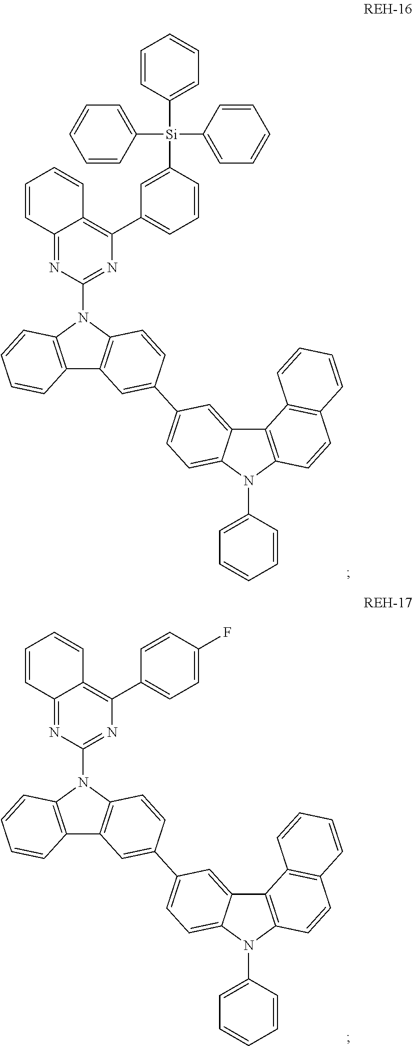 [SMILES: c1ccc(-n2c3ccc(-c4ccc5c(c4)c4ccccc4n5-c4nc(-c5cccc([Si](c6ccccc6)(c6ccccc6)c6ccccc6)c5)c5ccccc5n4)cc3c3c4ccccc4ccc32)cc1 ; Fc1ccc(-c2nc(-n3c4ccccc4c4cc(-c5ccc6c(c5)c5c7ccccc7ccc5n6-c5ccccc5)ccc43)nc3ccccc23)cc1]

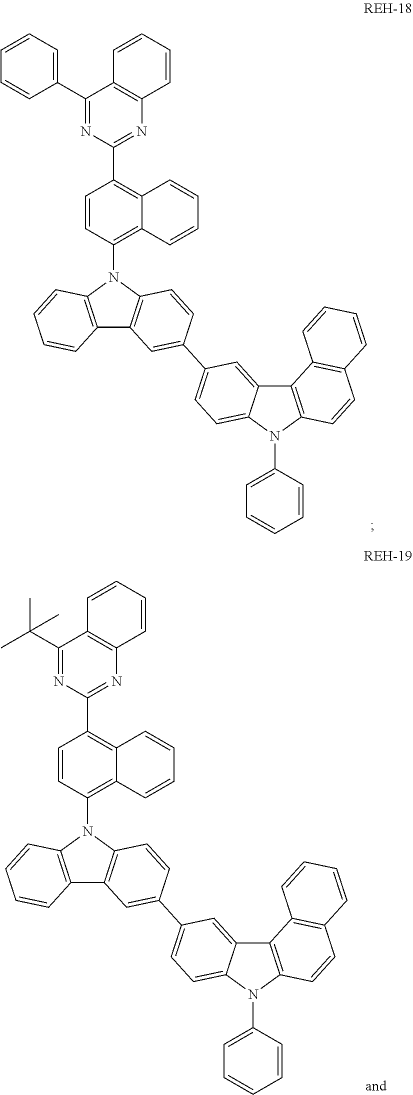 [SMILES: c1ccc(-c2nc(-c3ccc(-n4c5ccccc5c5cc(-c6ccc7c(c6)c6c8ccccc8ccc6n7-c6ccccc6)ccc54)c4ccccc34)nc3ccccc23)cc1 ; CC(C)(C)c1nc(-c2ccc(-n3c4ccccc4c4cc(-c5ccc6c(c5)c5c7ccccc7ccc5n6-c5ccccc5)ccc43)c3ccccc23)nc2ccccc12]

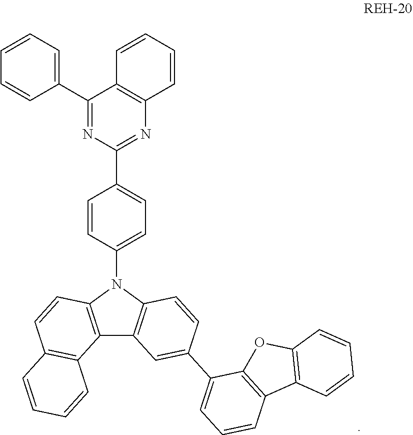 [SMILES: c1ccc(-c2nc(-c3ccc(-n4c5ccc(-c6cccc7c6oc6ccccc67)cc5c5c6ccccc6ccc54)cc3)nc3ccccc23)cc1]

18. An organic light-emitting display device comprising:
a substrate;
a driving element disposed on the substrate; and
an organic light-emitting diode disposed on the substrate and connected to the driving element, wherein the organic light-emitting diode includes the organic light-emitting device of claim 1.
